(19) United States
(12) Patent Application Publication
(10) Pub. No.: US 2023/0120139 A1
(43) Pub. Date: Apr. 20, 2023

(54) ACTINIC RAY-SENSITIVE OR RADIATION-SENSITIVE RESIN COMPOSITION, ACTINIC RAY-SENSITIVE OR RADIATION-SENSITIVE FILM, PATTERN FORMING METHOD, AND METHOD FOR MANUFACTURING ELECTRONIC DEVICE

(71) Applicant: FUJIFILM Corporation, Tokyo (JP)

(72) Inventors: Taro MIYOSHI, Haibara-gun (JP); Eiji Fukuzaki, Haibara-gun (JP); Shuhei Yamaguchi, Haibara-gun (JP)

(73) Assignee: FUJIFILM Corporation, Tokyo (JP)

(21) Appl. No.: 17/987,122

(22) Filed: Nov. 15, 2022

Related U.S. Application Data
(63) Continuation of application No. PCT/JP2020/018510, filed on May 14, 2021.

(30) Foreign Application Priority Data
May 29, 2020 (JP) 2020-094645

(51) Int. Cl. G03F 7/004; G03F 7/039; G03F 7/038; C08F 212/14; C08F 220/30; C08F 220/18

(52) U.S. Cl. CPC G03F 7/0045; G03F 7/039; G03F 7/038; C08F 212/24; C08F 220/301; C08F 212/22; C08F 220/1805

(57) ABSTRACT

An actinic ray-sensitive or radiation-sensitive resin composition containing: a resin (A) of which polarity increases by an action of an acid, the resin (A) having a repeating unit represented by General Formula (A1) as defined herein; and a compound (B) that generates an acid upon irradiation with actinic rays or radiation.

### CROSS REFERENCE TO RELATED APPLICATION

This is a continuation of International Application No. PCT/JP2021/018510 filed on May 14, 2021, and claims priority from Japanese Patent Application No. 2020-094645 filed on May 29, 2020, the entire disclosures of which are incorporated herein by reference.

### BACKGROUND OF THE INVENTION

### 1. Field of the Invention

The present invention relates to an actinic ray-sensitive or radiation-sensitive resin composition, an actinic ray-sensitive or radiation-sensitive film, a pattern forming method, and a method for manufacturing an electronic device. More specifically, the present invention relates to an actinic ray-sensitive or radiation-sensitive resin composition, an actinic ray-sensitive or radiation-sensitive film, a pattern forming method, and a method for manufacturing an electronic device, each of which is suitably used for an ultra-microlithography process applicable to a process for manufacturing an ultra-large scale integration (LSI) and a high-capacity microchip, a process for creating a mold for a nanoimprint, a process for manufacturing a high-density information recording medium, and the like, and other photofabrication processes.

### 2. Description of the Related Art

In processes for manufacturing semiconductor devices such as an integrated circuit (IC) and an LSI, microfabrication by lithography using a photoresist composition has been performed in the related art. In recent years, along with the high integration of integrated circuits, the formation of ultrafine patterns in a submicron region or quarter micron region has been required. Along with this, the exposure wavelength also tends to be shortened from g-line to i-line, and further to KrF excimer laser light, and an exposure machine using an ArF excimer laser having a wavelength of 193 nm as a light source is currently being developed. In addition, the development of a so-called liquid immersion method in which a liquid having a high refractive index (hereinafter also referred to as an “immersion liquid”) is filled between a projection lens and a sample as a technique for further enhancing a resolving power has been in progress since the related art.

Furthermore, at present, the development of lithography using electron beams (EB), X-rays, extreme ultraviolet rays (EUV), or the like in addition to excimer laser light is also in progress. Along with this, chemically amplified resist compositions which are effectively sensitive to various radiations and are excellent in a sensitivity and a resolution have been developed.

For example, JP2006-301609A describes a positive tone resist composition containing an acid-decomposable resin having a repeating unit derived from a monomer having a structure in which a lactone is fused with a benzene ring of styrene, and a photoacid generator; and the like.

In addition, JP2007-164145A describes a positive tone resist composition containing an acid-decomposable resin having a repeating unit derived from a monomer having a structure in which a ring having one of an ether group, a carbonyl group, and an ester group is fused with a benzene ring of phenyl (meth)acrylate, and an acid generator.

### SUMMARY OF THE INVENTION

However, in recent years, higher performance has been required for a resist composition due to miniaturization of a pattern, and the like. For example, in the formation of a pattern having a line width or a space width of 50 nm or less, it is required to reduce development residue defects while suppressing film thickness reduction of the pattern; and have a high resolution and the like by which a finer pattern (for example, a pattern having a line width or a space width of 30 nm or less) can be formed.

An object of the present invention is to provide an actinic ray-sensitive or radiation-sensitive resin composition which can reduce development residue defects while suppressing film thickness reduction of a pattern, and has a high resolution, and an actinic ray-sensitive or radiation-sensitive film, a pattern forming method, and a method for manufacturing an electronic device, each using the actinic ray-sensitive or radiation-sensitive resin composition.

The present inventors have found that the objects can be accomplished by the following configurations.

[1] An actinic ray-sensitive or radiation-sensitive resin composition comprising:

a resin (A) of which polarity increases by an action of an acid, the resin (A) having a repeating unit represented by General Formula (A1); and

a compound (B) that generates an acid upon irradiation with actinic rays or radiation.

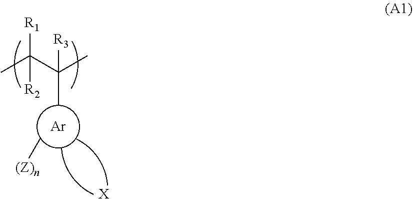

In General Formula (A1),

Ar represents an aromatic hydrocarbon group.

Z represents a substituent.

n represents an integer of 0 or more.

In a case where n represents an integer of 2 or more, a plurality of Z's may be the same as or different from each other.

R₁, R₂, and R₃ each independently represent a hydrogen atom, an alkyl group, a hydroxyl group, an alkoxy group, a halogen atom, a cyano group, a nitro group, an acyl group, an acyloxy group, a cycloalkyl group, an aryl group, a carboxy group, an alkyloxycarbonyl group, an alkylcarbonyloxy group, or an aralkyl group.

X represents an atomic group that forms an alkali-decomposable cyclic structure together with a carbon atom in Ar. It should be noted that the alkali-decomposable cyclic structure generates an acid group having a pKa of 6 to 12 by hydrolysis.

[2] An actinic ray-sensitive or radiation-sensitive resin composition comprising:

a resin (A) of which polarity increases by an action of an acid, the resin (A) having a repeating unit represented by General Formula (A1); and

a compound (B) that generates an acid upon irradiation with actinic rays or radiation.

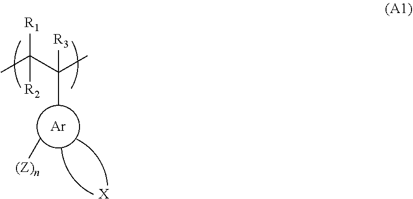

In General Formula (A1).

Ar represents an aromatic hydrocarbon group.

Z represents a substituent.

n represents an integer of 0 or more.

In a case where n represents an integer of 2 or more, a plurality of Z's may be the same as or different from each other.

R₁, R₂, and R₃ each independently represent a hydrogen atom, an alkyl group, a hydroxyl group, an alkoxy group, a halogen atom, a cyano group, a nitro group, an acyl group, an acyloxy group, a cycloalkyl group, an aryl group, a carboxy group, an alkyloxycarbonyl group, an alkylcarbonyloxy group, or an aralkyl group.

X represents an atomic group that forms an alkali-decomposable cyclic structure together with two carbon atoms in Ar. It should be noted that the alkali-decomposable cyclic structure generates an acid group having a pKa of 6 to 12 by hydrolysis.

[3] The actinic ray-sensitive or radiation-sensitive resin composition as described in [1] or [2],

in which the repeating unit represented by General Formula (A1) is a repeating unit represented by General Formula (A1-2) which will be described later.

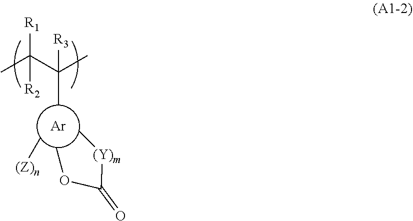

In General Formula (A1-2), Ar, Z, n, R₁, R₂, and R₃ each have the same definition as those in General Formula (A1).

Y represents a methanediyl group, an oxygen atom, or a sulfur atom.

m represents an integer of 0 to 10.

In a case where m represents an integer of 2 or more, a plurality of Y's may be the same as or different from each other.

[4] The actinic ray-sensitive or radiation-sensitive resin composition as described in [3],

in which all of m pieces of Y's represent a methanediyl group or an oxygen atom.

[5] The actinic ray-sensitive or radiation-sensitive resin composition as described in [3] or [4],

in which all of m pieces of Y's represent a methanediyl group.

[6] The actinic ray-sensitive or radiation-sensitive resin composition as described in any one of [3] to [5],

in which m represents an integer of 1 to 3.

[7] The actinic ray-sensitive or radiation-sensitive resin composition as described in any one of [1] to [6],

in which Ar represents an aromatic hydrocarbon group having 6 to 12 carbon atoms.

[8] The actinic ray-sensitive or radiation-sensitive resin composition as described in any one of [1] to [7],

in which Ar represents an aromatic hydrocarbon group having 6 carbon atoms.

[9] The actinic ray-sensitive or radiation-sensitive resin composition as described in [3],

in which the repeating unit represented by General Formula (A1-2) is a repeating unit represented by any one of General Formula (A1-3), (A1-4), or (A1-5),

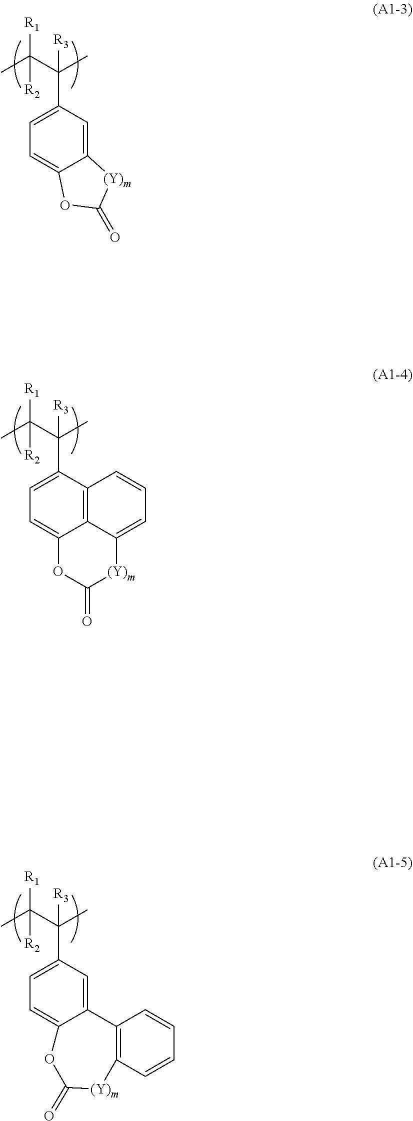

In General Formulae (A1-3) to (A1-5), R₁, R₂, R₃, Y, and m each have the same definition as those in General Formula (A1-2).

[10] The actinic ray-sensitive or radiation-sensitive resin composition as described in any one of [1] to [9], in which the compound (B) is a compound having an acid-decomposable group.

[11] The actinic ray-sensitive or radiation-sensitive resin composition as described in any one of [1] to [10],

in which the compound (B) is an ionic compound including an anion and a cation, and is a compound having an acid-decomposable group in the anion.

[12] The actinic ray-sensitive or radiation-sensitive resin composition as described in any one of [1] to [11],

in which the resin (A) has a repeating unit represented by General Formula (A2).

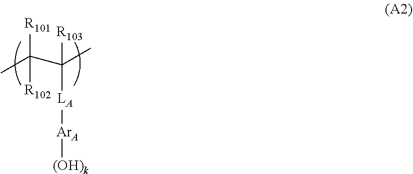

In General Formula (A2),

R₁₀₁, R₁₀₂, and R₁₀₃ each independently represent a hydrogen atom, an alkyl group, a cycloalkyl group, a halogen atom, a cyano group, or an alkyloxycarbonyl group. It should be noted that R₁₀₂ may be bonded to Ar_{A} to form a ring, in which case R₁₀₂ represents a single bond or an alkylene group.

L_{A} represents a single bond or a divalent linking group.

Ar_{A} represents an aromatic ring group.

k represents an integer of 1 to 5.

[13] The actinic ray-sensitive or radiation-sensitive resin composition as described in any one of [1] to [12],

in which the resin (A) has a repeating unit having at least one acid-decomposable group selected from the group consisting of a group that decomposes by an action of an acid to generate a carboxy group and a group that decomposes by an action of an acid to generate a phenolic hydroxyl group.

[14] The actinic ray-sensitive or radiation-sensitive resin composition as described in [13],

in which the repeating unit having an acid-decomposable group is a repeating unit represented by any one of General Formula (3), (4), (5), (6), or (7).

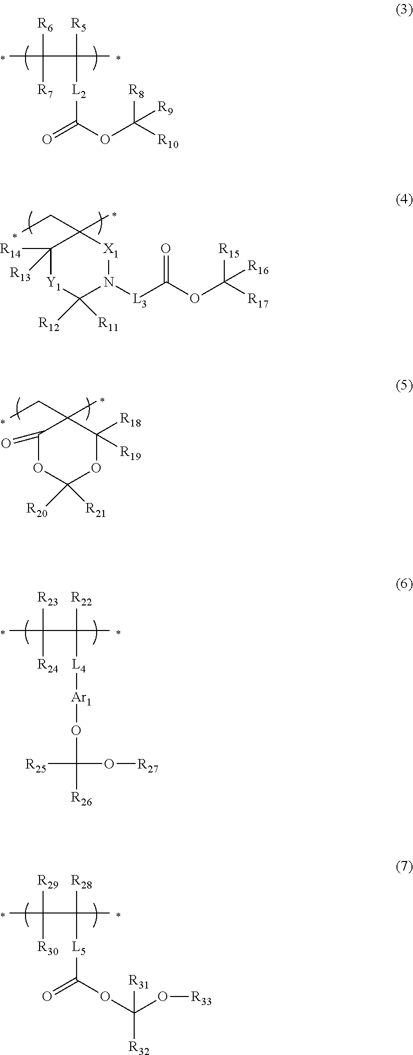

In General Formula (3), R₅, R₆, and R₇ each independently represent a hydrogen atom, an alkyl group, a cycloalkyl group, a halogen atom, a cyano group, or an alkoxycarbonyl group. L₂ represents a single bond or a divalent linking group. R₈ to R₁₀ each independently represent an alkyl group, a cycloalkyl group, an aryl group, an aralkyl group, or an alkenyl group. Furthermore, two of R₈ to R₁₀ may be bonded to each other to form a ring.

In General Formula (4). R₁₁ to R₁₄ each independently represent a hydrogen atom or an organic group. It should be noted that at least one of R₁₁ or R₁₂ represents an organic group. X₁ represents —CO—, —SO—, or —SO₂—. Y₁ represents —O—, —S—, —SO—, —SO₂—, or —NR₃₄—. R₃₄ represents a hydrogen atom or an organic group. L₃ represents a single bond or a divalent linking group. R₁₅ to R₁₇ each independently represent an alkyl group, a cycloalkyl group, an aryl group, an aralkyl group, or an alkenyl group. Furthermore, two of R₁₅ to R₁₇ may be bonded to each other to form a ring.

In General Formula (5), R₁₈ and R₁₉ each independently represent a hydrogen atom or an organic group. R₂₀ and R₂₁ each independently represent a hydrogen atom, an alkyl group, a cycloalkyl group, an aryl group, an aralkyl group, or an alkenyl group. Furthermore. R₂₀ and R₂₁ may be bonded to each other to form a ring.

In General Formula (6), R₂₂, R₂₃, and R₂₄ each independently represent a hydrogen atom, an alkyl group, a cycloalkyl group, a halogen atom, a cyano group, or an alkoxycarbonyl group. L₄ represents a single bond or a divalent linking group. An represents an aromatic ring group. R₂₅ to R₂₇ each independently represent a hydrogen atom, an alkyl group, a cycloalkyl group, an aryl group, an aralkyl group, or an alkenyl group. Furthermore, R₂₆ and R₂₇ may be bonded to each other to form a ring. In addition, Ar₁ may be bonded to R₂₄ or R₂₅ to form a ring.

In General Formula (7), R₂₈, R₂₉, and R₃₀ each independently represent a hydrogen atom, an alkyl group, a cycloalkyl group, a halogen atom, a cyano group, or an alkoxycarbonyl group. L₅ represents a single bond or a divalent linking group. R₃₁ and R₃₂ each independently represent a hydrogen atom, an alkyl group, a cycloalkyl group, an aryl group, an aralkyl group, or an alkenyl group. R₃₃ represents an alkyl group, a cycloalkyl group, an aryl group, an aralkyl group, or an alkenyl group. Furthermore. R₃₂ and R₃₃ may be bonded to each other to form a ring.

[15] The actinic ray-sensitive or radiation-sensitive resin composition as described in [14],

in which the repeating unit having an acid-decomposable group is the repeating unit represented by General Formula (6) or the repeating unit represented by General Formula (7).

[16] An actinic ray-sensitive or radiation-sensitive film formed of the actinic ray-sensitive or radiation-sensitive resin composition as described in any one of [1] to [15].

[17] A pattern forming method comprising:

forming a resist film using the actinic ray-sensitive or radiation-sensitive resin composition as described in any one of [1] to [15];

exposing the resist film; and

developing the exposed resist film, using a developer.

[18] A method for manufacturing an electronic device, comprising the pattern forming method as described in [17].

According to the present invention, it is possible to provide an actinic ray-sensitive or radiation-sensitive resin composition which can reduce development residue defects while suppressing film thickness reduction of a pattern, and has a high resolution; and an actinic ray-sensitive or radiation-sensitive film, a pattern forming method, and a method for manufacturing an electronic device, each using the actinic ray-sensitive or radiation-sensitive resin composition.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

“Actinic rays” or “radiation” in the present specification means, for example, a bright line spectrum of a mercury lamp, far ultraviolet rays typified by an excimer laser, extreme ultraviolet rays (EUV), X-rays, soft X-rays, electron beams (EB), or the like. “Light” in the present specification means actinic rays or radiation. Unless otherwise specified, “exposure” in the present specification encompasses not only exposure by a bright line spectrum of a mercury lamp, far ultraviolet rays typified by an excimer laser, extreme ultraviolet rays, X-rays, EUV, or the like, but also lithography by particle beams such as electron beams and ion beams.

In the present specification, a numerical range expressed using “to” is used in a meaning of a range that includes the preceding and succeeding numerical values of “to” as the lower limit value and the upper limit value, respectively.

The bonding direction of divalent groups noted in the present specification is not limited unless otherwise specified. For example, in a case where Y in a compound represented by General Formula “X—Y—Z” is —COO—, Y may be —CO—O— or —O—CO—. In addition, the compound may be “X—CO—O—Z” or “X—O—CO—Z”.

In the present specification, (meth)acrylate represents at least one of acrylate or methacrylate. In addition. (meth)acrylic acid represents at least one of acrylic acid or methacrylic acid.

In the present specification, the weight-average molecular weight (Mw), the number-average molecular weight (Mn), and the dispersity (also referred to as a molecular weight distribution) (Mw/Mn) of a resin are each defined as a value expressed in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, detector: differential refractive index detector) using a GPC apparatus (HLC-8120 GPC manufactured by Tosoh Corporation).

In notations for a group (atomic group) in the present specification, in a case where the group is noted without specifying that it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

Furthermore, in the present specification, the types of substituents, the positions of substituents, and the number of substituents in a case where it is described that “a substituent may be contained” are not particularly limited. The number of the substituents may be, for example, one, two, three, or more. Examples of the substituent include a monovalent non-metal atomic group excluding a hydrogen atom, and the substituent can be selected from, for example, the following substituent T.

(Substituent T)

Examples of the substituent T include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; alkyl groups (for example, an alkyl group having 1 to 10 carbon atoms); cycloalkyl groups (for example, a cycloalkyl group having 3 to 20 carbon atoms); aryl groups (for example, an aryl group having 6 to 20 carbon atoms); heteroaryl groups; a hydroxyl group; a carboxy group; a formyl group; a sulfo group; a cyano group; an alkylaminocarbonyl group; an arylaminocarbonyl group; a sulfonamide group; a silyl group; an amino group; a monoalkylamino group; a dialkylamino group; an arylamino group, a nitro group; a formyl group; and a combination thereof.

In the present specification, an acid dissociation constant (pKa) represents a pKa in an aqueous solution, and is specifically a value determined by computation from a value based on a Hammett's substituent constant and database of publicly known literature values, using the following software package 1. Any of the pKa values described in the present specification indicate values determined by computation using the software package.

Software Package 1: Advanced Chemistry Development (ACD/Labs) Software V 8.14 for Solaris (1994-2007 ACD/Labs).

On the other hand, the pKa can also be determined by a molecular orbital computation method. Examples of a specific method therefor include a method for performing calculation by computing H⁺ dissociation free energy in a solvent based on a thermodynamic cycle. Furthermore, in the present specification, water is usually used as the solvent, and in a case where a pKa is not determined with water, dimethyl sulfoxide (DMSO) is used.

With regard to the method for computing the H⁺ dissociation free energy, the H⁺ dissociation free energy can be computed by, for example, density functional theory (DFT), but various other methods have been reported in literature and the like, and are not limited thereto. Furthermore, there are a plurality of software applications capable of performing DFT, and examples thereof include Gaussian 16.

As described above, the pKa in the present specification refers to a value determined by computation from a value based on a Hammett's substituent constant and database of publicly known literature values, using the software package 1, but in a case where the pKa cannot be calculated by the method, a value obtained by Gaussian 16 based on density functional theory (DFT) shall be adopted.

[Actinic Ray-Sensitive or Radiation-Sensitive Resin Composition]

The actinic ray-sensitive or radiation-sensitive resin composition of an embodiment of the present invention (also referred to as “the composition of the embodiment of the present invention”) is an actinic ray-sensitive or radiation-sensitive resin composition containing a resin (A) of which polarity increases by the action of an acid, the resin (A) having a repeating unit represented by General Formula (A1), and a compound (B) that generates an acid upon irradiation with actinic rays or radiation.

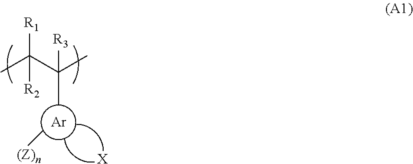

In General Formula (A1).

Ar represents an aromatic hydrocarbon group.

Z represents a substituent.

n represents an integer of 0 or more.

In a case where n represents an integer of 2 or more, a plurality of Z's may be the same as or different from each other.

R₁, R₂, and R₃ each independently represent a hydrogen atom, an alkyl group, a hydroxyl group, an alkoxy group, a halogen atom, a cyano group, a nitro group, an acyl group, an acyloxy group, a cycloalkyl group, an aryl group, a carboxy group, an alkyloxycarbonyl group, an alkylcarbonyloxy group, or an aralkyl group.

X represents an atomic group that forms an alkali-decomposable cyclic structure together with a carbon atom in Ar. It should be noted that the alkali-decomposable cyclic structure generates an acid group having a pKa of 6 to 12 by hydrolysis.

The composition of the embodiment of the present invention is preferably a resist composition, and may be either a positive tone resist composition or a negative tone resist composition. In addition, the resist composition may be either a resist composition for alkali development or a resist composition for organic solvent development.

The composition of the embodiment of the present invention is preferably a positive tone resist composition.

The composition of the embodiment of the present invention is preferably a resist composition for alkali development.

In addition, the composition of the embodiment of the present invention is preferably a chemically amplified resist composition, and more preferably a chemically amplified positive tone resist composition.

A reason why the composition of the embodiment of the present invention can reduce development residue defects while suppressing film thickness reduction of a pattern, and has a high resolution has not been completely clarified, but is presumed by the present inventors to be as follows.

The alkali-decomposable cyclic structure formed of X of the resin (A) and the carbon atom in Ar is hydrolyzed by coming into contact with an alkali developer which is a typical developer, thereby generating an acid group having a pKa of 6 to 12 (for example, a phenolic hydroxyl group). It is considered that by the acid group having a pKa of 6 to 12, a surface of an actinic ray-sensitive or radiation-sensitive film formed using the composition of the embodiment of the present invention is hydrophilized, and a dissolution rate of the exposed portion is improved, while since a degree of hydrophilization is lower, as compared with, for example, a case where a group having a pKa of less than 6 such as a carboxy group (since the acid group having a pKa of 6 to 12 has appropriate hydrophilicity), the dissolution rate of the unexposed portion is not extremely increased and a good dissolution contrast can be obtained. It is considered that this enables a high resolution in the formation of an ultrafine pattern (in particular, a line width or a space width of 30 nm or less) to be expressed. In addition, it is considered that the resin (A) has a rigid structure in which Ar (aromatic hydrocarbon group) is directly bonded to the main chain, and thus there is an effect of further improving the resolution.

Since the acid group having a pKa of 6 to 12 has appropriate hydrophilicity and is further generated by a hydrolysis reaction of the alkali-decomposable cyclic structure, the inside of an actinic ray-sensitive or radiation-sensitive film formed of the composition of the embodiment of the present invention is less likely to be hydrophilized due to hydrophilization of only the surface of the film. It is considered that this enables the film thickness reduction of the pattern to be suppressed. In addition, it is considered that since the surface of the unexposed portion where the development residue is easily generated is washed away with an alkali developer, the development residue defects can be reduced.

[Resin of which Polarity Increases by Action of Acid, which has Repeating Unit Represented by General Formula (A1)]

The resin (A) of which polarity increases by the action of an acid, which includes a repeating unit represented by General Formula (A1) (also referred to as a “resin (A)”) will be described.

<Repeating Unit Represented by General Formula (A1)>

The resin (A) includes a repeating unit represented by General Formula (A1).

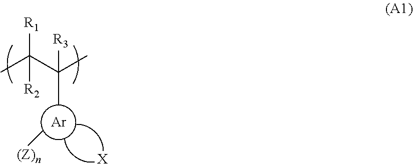

In General Formula (A1),

Ar represents an aromatic hydrocarbon group.

Z represents a substituent.

n represents an integer of 0 or more.

In a case where n represents an integer of 2 or more, a plurality of Z's may be the same as or different from each other.

R₁, R₂, and R₃ each independently represent a hydrogen atom, an alkyl group, a hydroxyl group, an alkoxy group, a halogen atom, a cyano group, a nitro group, an acyl group, an acyloxy group, a cycloalkyl group, an aryl group, a carboxy group, an alkyloxycarbonyl group, an alkylcarbonyloxy group, or an aralkyl group.

X represents an atomic group that forms an alkali-decomposable cyclic structure together with a carbon atom in Ar. It should be noted that the alkali-decomposable cyclic structure generates an acid group having a pKa of 6 to 12 by hydrolysis.

In General Formula (A1), R₁, R₂, and R₃ each independently represent a hydrogen atom, an alkyl group, a hydroxyl group, an alkoxy group, a halogen atom, a cyano group, a nitro group, an acyl group, an acyloxy group, a cycloalkyl group, an aryl group, a carboxy group, an alkyloxycarbonyl group, an alkylcarbonyloxy group, or an aralkyl group.

In a case where R₁, R₂, and R₃ in General Formula (A1) each represent the alkyl group, the alkyl group is not particularly limited, but is preferably an alkyl group having 1 to 20 carbon atoms, more preferably an alkyl group having 1 to 8 carbon atoms, and still more preferably an alkyl group having 1 to 3 carbon atoms. Specific examples of the alkyl group include a methyl group, an ethyl group, a propyl group, an isopropyl group, an n-butyl group, a sec-butyl group, a hexyl group, a 2-ethylhexyl group, an octyl group, and a dodecyl group.

In a case where R₁, R₂, and R₃ in General Formula (A1) represent the cycloalkyl group, the cycloalkyl group may be monocyclic or polycyclic. As the cycloalkyl group, a cycloalkyl group having 3 to 8 carbon atoms, such as a cyclopropyl group, a cyclopentyl group, and a monocyclic cyclohexyl group, is preferable.

In a case where R₁, R₂, and R₃ in General Formula (A1) each represent the halogen atom, examples of the halogen atom include a fluorine atom, a chlorine atom, a bromine atom, and an iodine atom, and the fluorine atom is preferable.

In a case where R₁, R₂, and R₃ in General Formula (A1) each represent the alkoxy group, the alkyloxycarbonyl group, or the alkylcarbonyloxy group, specific examples and preferred ranges of an alkyl group included in the alkoxy group, the alkyloxycarbonyl group, or the alkylcarbonyloxy group are the same as those of the alkyl group in the case where R₁, R₂, and R₃ each represent the alkyl group as described earlier.

In a case where R₁, R₂, and R₃ in General Formula (A1) each represent the acyl group including the alkyl group or the acyloxy group including an alkyl group, specific examples and preferred ranges of an alkyl group included in the acyl group or acyloxy group are the same as those of the alkyl group in a case where R₁, R₂, and R₃ each represent the alkyl group as described earlier.

In a case where R₁, R₂, and R₃ in General Formula (A1) each represent the aralkyl group, specific examples and preferred ranges of an alkyl group included in the aralkyl group are the same as those of the alkyl group in a case where R₁, R₂, and R₃ each represent the alkyl group as described earlier.

In a case where R₁, R₂, and R₃ in General Formula (A1) each represent the aryl group, the aryl group is not particularly limited, but is preferably an aryl group having 6 to 14 carbon atoms, more preferably an aryl group having 6 to 12 carbon atoms, and particularly preferably an aryl group having 6 to 10 carbon atoms. Specific examples of the aryl group include a phenyl group and a naphthyl group, and the phenyl group is preferable.

In a case where R₁, R₂, and R₃ in General Formula (A1) each represent the acyl group including the aryl group or the acyloxy group including the aryl group, specific examples and preferred ranges of an aryl group included in the acyl group or the acyloxy group are the same as those of the aryl group in a case where R₁, R₂, and R₃ each represent the aryl group as described earlier.

In a case where R₁, R₂, and R₃ in General Formula (A1) each represent the aralkyl group, specific examples and preferred ranges of an aryl group included in the aralkyl group are the same as those of the aryl group in a case where R₁, R₂, and R₃ each represent the aryl group as described earlier.

In a case where each of the above-described groups can further have one or more substituents, the one or more additional substituents may be provided. The additional substituent is not particularly limited, but examples thereof include an alkyl group, a cycloalkyl group, an aryl group, an amino group, an amide group, a ureide group, a urethane group, a hydroxyl group, a carboxy group, a halogen atom, an alkoxy group, a thioether group, an acyl group, an acyloxy group, an alkoxycarbonyl group, a cyano group, and a nitro group. The additional substituent preferably has 8 or less carbon atoms.

It is preferable that R₁ and R₂ in General Formula (A1) are each a hydrogen atom.

R₃ in General Formula (A1) is preferably a hydrogen atom or a methyl group, and more preferably the hydrogen atom.

In General Formula (A1), Ar represents an aromatic hydrocarbon group, preferably an aromatic hydrocarbon group having 6 to 18 carbon atoms, more preferably an aromatic hydrocarbon group having 6 to 12 carbon atoms, still more preferably an aromatic hydrocarbon group having 6 to 10 carbon atoms, and particularly preferably an aromatic hydrocarbon group having 6 carbon atoms. Specific examples of Ar include a phenyl group, a naphthyl group, a biphenyl group, and an anthryl group; and the phenyl group, the naphthyl group, or the biphenyl group is preferable, the phenyl group or the naphthyl group is more preferable, and the phenyl group is still more preferable.

In General Formula (A1), Z represents a substituent. The substituent represented by Z is not particularly limited, and examples thereof include an alkyl group, a hydroxyl group, an alkoxy group, a halogen atom, a cyano group, a nitro group, an acyl group, an acyloxy group, a cycloalkyl group, an aryl group, a carboxy group, an alkyloxycarbonyl group, an alkylcarbonyloxy group, and an aralkyl group.

In a case where Z represents the alkyl group, the alkoxy group, the halogen atom, the acyl group, the acyloxy group, the cycloalkyl group, the aryl group, the alkyloxycarbonyl group, the alkylcarbonyloxy group, or the aralkyl group, specific examples and preferred ranges of each of these groups are the same as those of each of the groups in R₁, R₂, and R₃ as described earlier.

In General Formula (A1), n represents an integer of 0 or more, preferably represents an integer of 0 to 15, more preferably represents an integer of 0 to 9, still more preferably represents an integer of 0 to 7, and particularly preferably represents an integer of 0 to 3.

In a case where n represents an integer of 2 or more, a plurality of Z's may be the same as or different from each other.

In General Formula (A1), X represents an atomic group that forms an alkali-decomposable cyclic structure together with a carbon atom in Ar. It should be noted that the alkali-decomposable cyclic structure generates an acid group having a pKa of 6 to 12 by hydrolysis.

The number of carbon atoms in Ar that forms an alkali-decomposable cyclic structure together with X is not particularly limited.

X typically represents an atomic group that forms an alkali-decomposable cyclic structure together with two, three, or four carbon atoms in Ar, preferably represents an atomic group that forms an alkali-decomposable cyclic structure together with two or three carbon atoms in Ar, and more preferably represents an atomic group that forms an alkali-decomposable cyclic structure together with two carbon atoms in Ar.

The expression. “alkali-decomposable”, means a property of causing a decomposition reaction by the action of an aqueous alkaline solution having a pH of 10.0 or more.

The alkali-decomposable cyclic structure formed by X together with the carbon atom in Ar causes a hydrolysis reaction with an alkali developer which is a typical developer, and thus, generates an acid group having a pKa of 6 to 12.

Examples of the acid group having a pKa of 6 to 12 include a phenolic hydroxyl group, a thiol group, and a thiophenol group.

As the alkali-decomposable cyclic structure, a cyclic structure including an ester bond (*1-O—CO—*2), in which an oxygen atom in the ester bond is directly bonded to one carbon atom in Ar, is preferable (in which *1 and *2 each represent a bonding position, and *1 preferably represents a bonding position with one carbon atom in Ar). In a case where this cyclic structure is hydrolyzed, a bond between the oxygen atom of the ester bond and the carbonyl group is cleaved to generate a hydroxyl group and a carboxy group, but since this hydroxyl group is directly bonded to one carbon atom in Ar, the structure is a phenolic hydroxyl group. Furthermore, as described above, the alkali-decomposable cyclic structure formed by X together with the carbon atom in Ar only needs to be hydrolyzed to generate an acid group having a pKa of 6 to 12, and may also be the one that further generates an acid group having a pKa of less than 6 or a group having a pKa of more than 12, in addition to the acid group having a pKa of 6 to 12.

For example, a repeating unit of the following (1) serves as a repeating unit of the following (2) by hydrolysis.

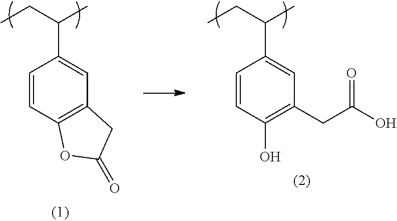

The pKa of the acid group generated by the hydrolysis of the alkali-decomposable cyclic structure can be obtained by the method described above. More specifically, with respect to a monomer (M) having a structure corresponding to the repeating unit having an acid group generated by hydrolysis of the alkali-decomposable cyclic structure, a value determined by computation using the above-described software package 1 (a value obtained by Gaussian 16 based on DFT in a case where a pKa cannot be calculated by the method) is defined as a pKa of the acid group generated by hydrolysis of the alkali-decomposable cyclic structure. In a case where the monomer (M) has two or more acid groups, two or more pKa values are also calculated, but even in this case, whether or not it is included in the resin (A) of the present invention is determined, based on whether or not the pKa of the acid group generated by hydrolysis of the alkali-decomposable cyclic structure is within the range of 6 to 12.

For example, the pKa of the acid group generated by hydrolysis of the repeating unit of (1) above is determined by the method for the following (2m) which is a monomer having a structure corresponding to the repeating unit of (2) above. The following (2m) has two acid groups generated by hydrolysis of the alkali-decomposable cyclic structure, and thus, a pKa of a dissociation reaction between (2m) and (2m−1) (which is an acid dissociation constant of a first step, and is called “pKa1”), and a pKa of a dissociation reaction between (2m−1) and (2m−2) (which is an acid dissociation constant of a second step, and is called “pKa2”) are determined, but the pKa2 is 6 to 12.

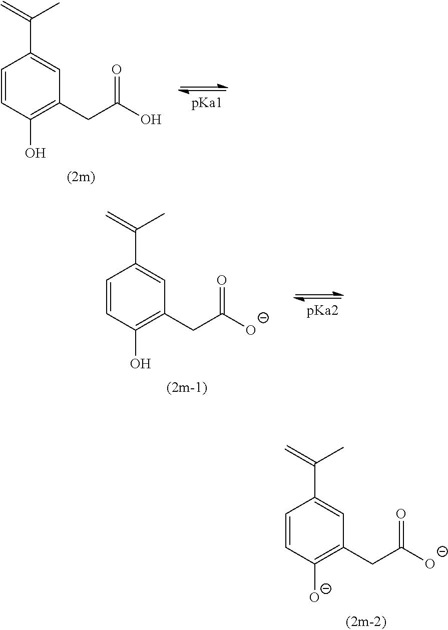

The repeating unit represented by General Formula (A1) is preferably a repeating unit represented by General Formula (A1-2).

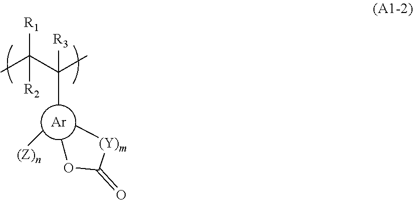

In General Formula (A1-2), Ar, Z, n, R₁, R₂, and R₃ each have the same definition as those in General Formula (A1).

Y represents a methanediyl group, an oxygen atom, or a sulfur atom.

m represents an integer of 0 to 10.

In a case where m represents an integer of 2 or more, a plurality of Y's may be the same as or different from each other.

In General Formula (A1-2), Ar, Z, n, R₁, R₂, and R₃ each have the same definitions as those in General Formula (A1), and specific examples and preferred ranges thereof are also the same.

In General Formula (A1-2), Y represents a methanediyl group (—CH₂—), an oxygen atom, or a sulfur atom. In a case where Y represents a methanediyl group, one or two of the two hydrogen atoms in the methanediyl group may be substituted with a substituent. Examples of the substituent include the substituent T, and the alkyl group (preferably an alkyl group having 1 to 6 carbon atoms), the halogen atom, or the hydroxyl group is preferable. In addition, in a case where m represents an integer of 2 or more and two or more Y's represent methanediyl groups, hydrogen atoms in the two or more methanediyl groups or substituents that substitute the hydrogen atoms may be bonded to form a ring (for example, a benzene ring).

Y preferably represents the methanediyl group or the oxygen atom, and more preferably represents the methanediyl group.

It is preferable that all of m pieces of Y's represent methanediyl groups or oxygen atoms, and it is more preferable that all of m pieces Y's represent the methanediyl groups.

In General Formula (A1-2), m represents an integer of 0 to 10, preferably represents an integer of 1 to 5, more preferably represents an integer of 1 to 3, still more preferably represents 1 or 2, and most preferably represents 2.

In a case where m represents an integer of 2 or more, a plurality of Y's may be the same as or different from each other.

The repeating unit represented by General Formula (A1-2) is more preferably a repeating unit represented by any one of General Formula (A1-3), . . . , or (A1-5), and particularly preferably the repeating unit represented by General Formula (A1-3)

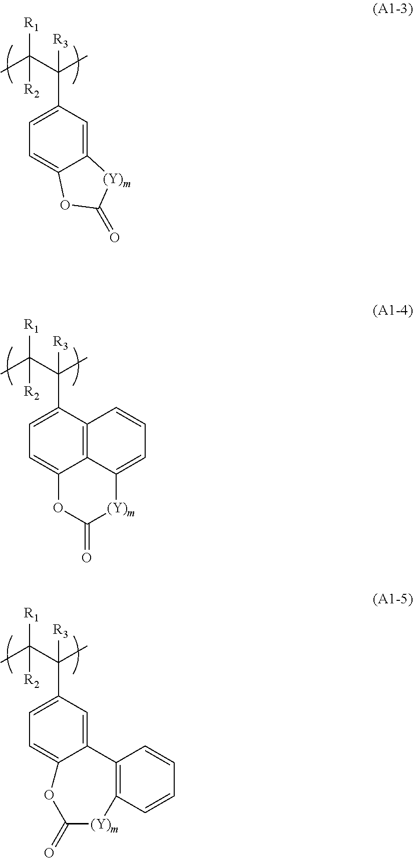

In General Formulae (A1-3) to (A1-5), R₁, R₂, R₃, Y, and m each have the same definition as those in General Formula (A1-2).

In General Formulae (A1-3) to (A1-5), R₁, R₂, R₃, Y, and m each have the same definitions as those in General Formula (A1-2), and specific examples and preferred ranges thereof are also the same.

Specific examples of the repeating unit represented by General Formula (A1) will be shown below, but are not limited thereto.

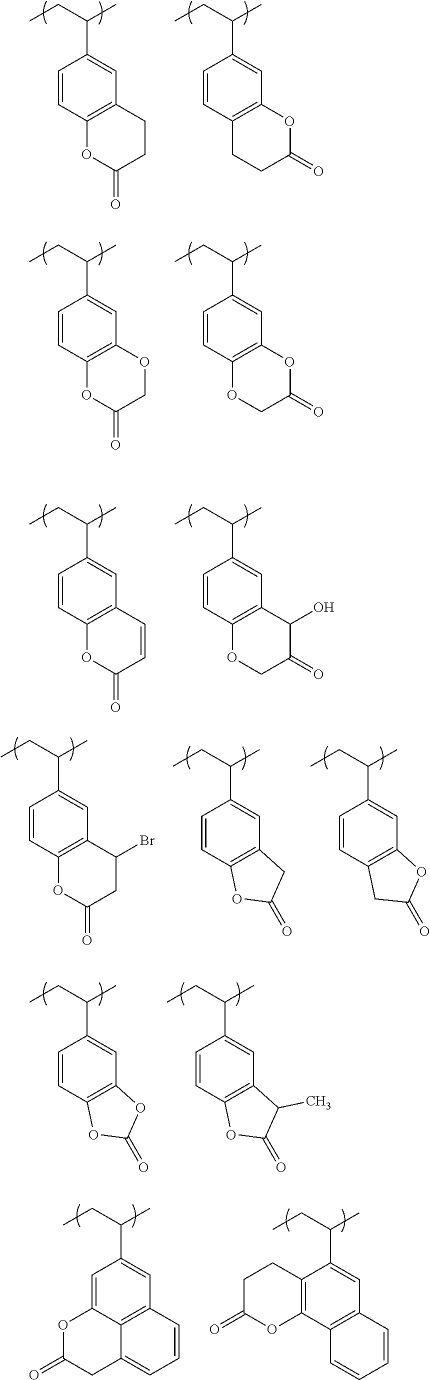

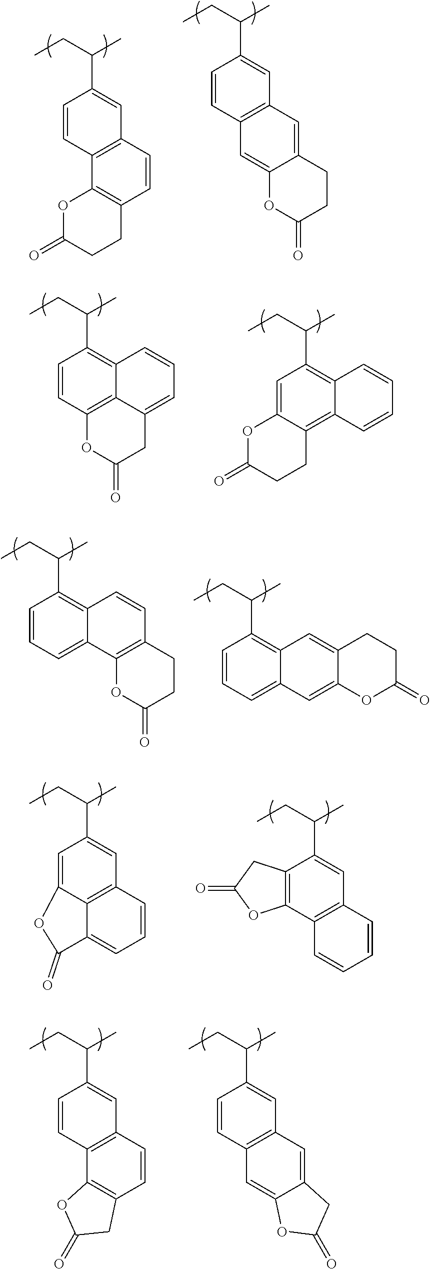

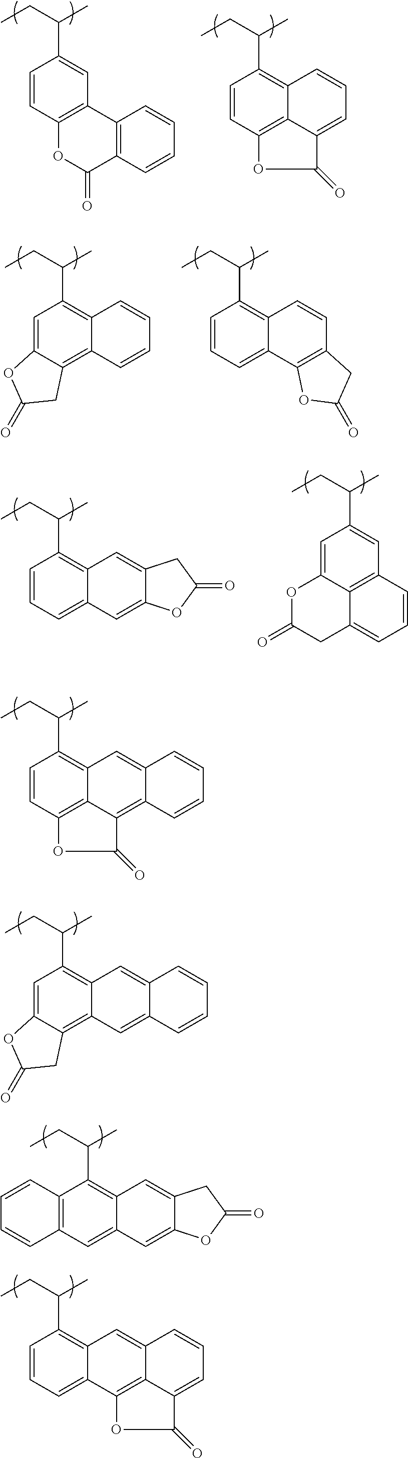

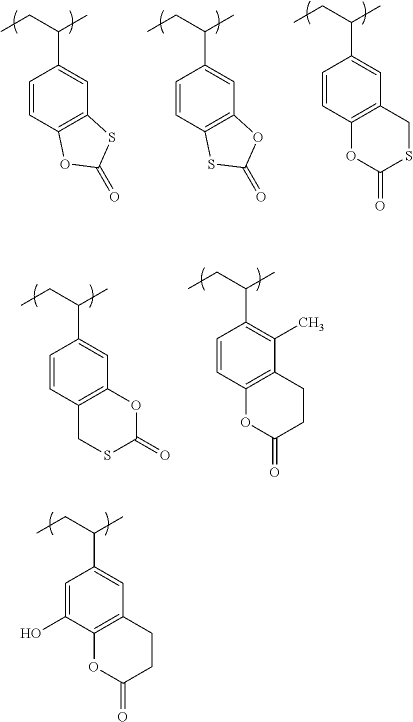

The content of the repeating unit represented by General Formula (A1) is not particularly limited, but is preferably 3% by mole or more, more preferably 5% by mole or more, still more preferably 10% by mole or more, and particularly preferably 15% by mole or more with respect to all repeating units in the resin (A). In addition, the content of the repeating unit represented by General Formula (A1) is preferably 80% by mole or less, more preferably 70% by mole or less, still more preferably 60% by mole or less, and particularly preferably 50% by mole or less with respect to all repeating units in the resin (A).

<Repeating Unit Represented by General Formula (A2)>

The resin (A) preferably has a repeating unit represented by General Formula (A2).

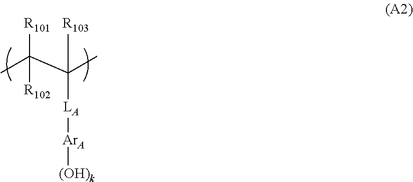

In General Formula (A2),

R₁₀₁, R₁₀₂, and R₁₀₃ each independently represent a hydrogen atom, an alkyl group, a cycloalkyl group, a halogen atom, a cyano group, or an alkyloxycarbonyl group. It should be noted that R₁₀₂ may be bonded to Ar_{A} to form a ring, in which case R₁₀₂ represents a single bond or an alkylene group.

L_{A} represents a single bond or a divalent linking group.

Ar_{A} represents an aromatic ring group.

k represents an integer of 1 to 5.

In a case where R₁₀₁, R₁₀₂, and R₁₀₃ in General Formula (A2) each represent the alkyl group, the cycloalkyl group, the halogen atom, or the alkyloxycarbonyl group, specific examples and preferred examples of the alkyl group, the cycloalkyl group, the halogen atom, or the alkyloxycarbonyl group are the same as those of an alkyl group, a cycloalkyl group, a halogen atom, or an alkyloxycarbonyl group in the case where R₁, R₂, and R₃ in General Formula (A1) each represent the alkyl group, the cycloalkyl group, the halogen atom, or the alkyloxycarbonyl group as described earlier. In addition, in a case where each of the above-described groups can further have one or more substituents, the additional substituents may be provided, and specific examples and preferred ranges of the additional substituents are the same as the specific examples and the preferred ranges of the additional substituents which may be contained in each of the groups represented by R₁, R₂, and R₃ in General Formula (A1) as described earlier.

Ar_{A} in General Formula (A2) represents an aromatic ring group, and more specifically a (k+1)-valent aromatic ring group. The divalent aromatic ring group in a case where k is 1 is preferably, for example, an arylene group having 6 to 18 carbon atoms, such as a phenylene group, a tolylene group, a naphthylene group, and an anthracenylene group, or a divalent aromatic ring group including a heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Furthermore, the aromatic ring group may have a substituent.

Specific examples of the (k+1)-valent aromatic ring group in a case where k is an integer of 2 or more include groups formed by removing any (k−1) hydrogen atoms from the above-described specific examples of the divalent aromatic ring group.

The (k+1)-valent aromatic ring group may further have a substituent.

The substituent which can be contained in the (k+1)-valent aromatic ring group is not particularly limited, and examples thereof include alkyl groups such as a methyl group, an ethyl group, a propyl group, an isopropyl group, an n-butyl group, a sec-butyl group, a hexyl group, a 2-ethylhexyl group, an octyl group, and a dodecyl group; alkoxy groups such as a methoxy group, an ethoxy group, a hydroxyethoxy group, a propoxy group, a hydroxypropoxy group, and a butoxy group; and aryl groups such as a phenyl group.

Ar_{A} preferably represents an aromatic ring group having 6 to 18 carbon atoms, and more preferably represents a benzene ring group, a naphthalene ring group, or a biphenylene ring group.

L_{A} in General Formula (A2) represents a single bond or a divalent linking group.

In a case where L_{A} represents the divalent linking group, the divalent linking group is not particularly limited, but examples thereof include —COO—, —CONR₆₄—, an alkylene group, or a group formed by combination of two or more kinds of these groups. R₆₄ represents a hydrogen atom or an alkyl group,

The alkylene group is not particularly limited, but examples thereof include alkylene groups having 1 to 8 carbon atoms, such as a methylene group, an ethylene group, a propylene group, a butylene group, a hexylene group, and an octylene group, are preferable.

In a case where R₆₄ represents the alkyl group, examples of the alkyl group include alkyl groups having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and an alkyl group having 8 or less carbon atoms, are preferable.

The repeating unit represented by General Formula (A2) preferably has a hydroxystyrene structure. That is, Ar_{A} preferably represents the benzene ring group.

k preferably represents an integer of 1 to 3, and more preferably represents 1 or 2.

Specific examples of the repeating unit represented by General Formula (A2) will be shown below. In the structural formulae of the following specific examples, a represents 1, 2, or 3. In addition, with regard to the specific examples of the repeating unit represented by General Formula (A2), reference can be made to the description in paragraphs [0068] to [0072] of WO2018/193954A, the contents of which are incorporated herein by reference.

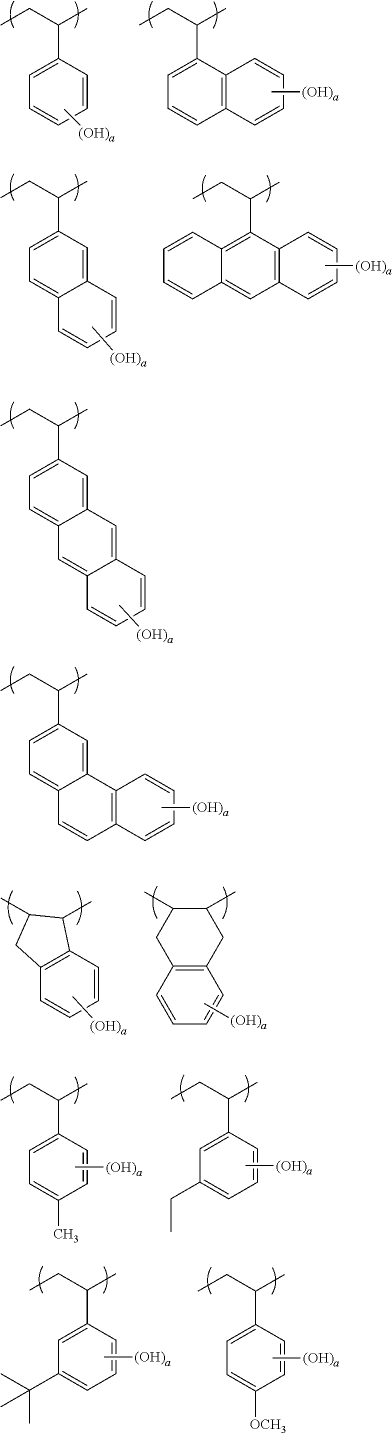

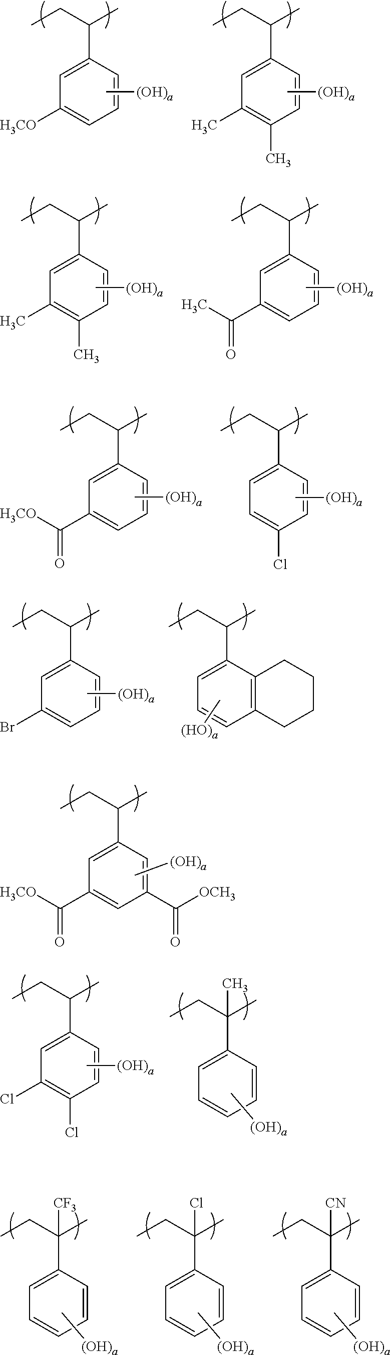

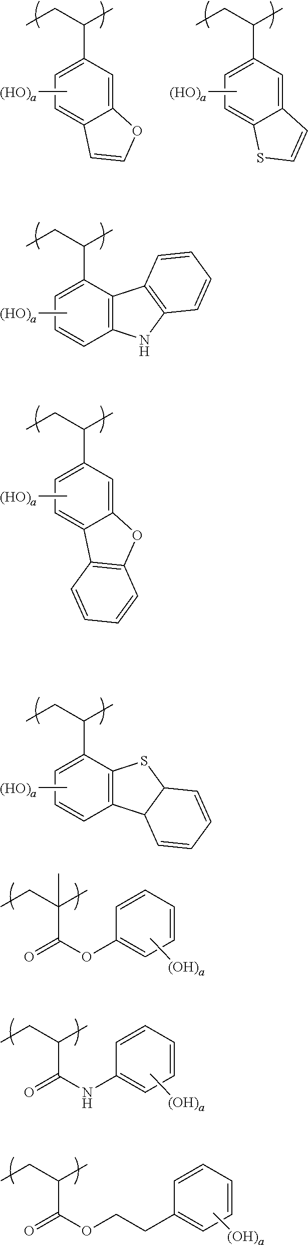

In a case where the resin (A) contains the repeating unit represented by General Formula (A2), the content of the repeating unit represented by General Formula (A2) is not particularly limited, but is preferably 30% by mole or more, and more preferably 40% by mole or more with respect to all repeating units in the resin (A). In addition, the content of the repeating unit represented by General Formula (A2) is preferably 90% by mole or less, more preferably 85% by mole or less, and still more preferably 80% by mole or less with respect to all repeating units in the resin (A).

<Repeating Unit Having Acid-Decomposable Group>

The resin (A) is a resin of which polarity increases through decomposition by the action of an acid.

The resin (A) preferably includes a group of which polarity increases through decomposition by the action of an acid (also referred to as an “acid-decomposable group”), and more preferably includes a repeating unit having an acid-decomposable group.

The polarity of the resin (A) increases by the action of an acid, and thus, the solubility in an alkali developer increases and the solubility in an organic solvent decreases.

In pattern formation using the composition of the embodiment of the present invention, including the resin (A), typically, in a case where an alkali developer is adopted as the developer, a positive tone pattern is formed, and in a case where an organic developer is adopted as the developer, a negative tone pattern is formed.

The acid-decomposable group is preferably a group that decomposes by the action of an acid to generate a polar group. The acid-decomposable group preferably has a structure in which the polar group is protected by a leaving group that leaves by the action of an acid. That is, the resin (A) preferably has a repeating unit having a group that decomposes by the action of an acid to generate a polar group.

As the polar group, an alkali-soluble group is preferable, and examples thereof include an acidic group such as a carboxy group, a phenolic hydroxyl group, a fluorinated alcohol group, a sulfonic acid group, a phosphoric acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group, and an alcoholic hydroxyl group.

As the polar group, the carboxy group, the phenolic hydroxyl group, the fluorinated alcohol group (preferably a hexafluoroisopropanol group), or the sulfonic acid group is preferable, and the carboxy group or the phenolic hydroxyl group is more preferable. That is, as the acid-decomposable group, a group that decomposes by the action of an acid to generate a carboxy group or a group that decomposes by the action of an acid to generate a phenolic hydroxyl group is preferable.

The resin (A) preferably has a repeating unit having at least one acid-decomposable group selected from the group consisting of a group that decomposes by the action of an acid to generate a carboxy group or a group that decomposes by the action of an acid to generate a phenolic hydroxyl group.

Examples of the leaving group that leaves by the action of an acid include groups represented by Formulae (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (Y4):

In Formula (Y1) and Formula (Y2), Rx₁ to Rx₃ each independently represent an (linear or branched) alkyl group or (monocyclic or polycyclic) cycloalkyl group, an (monocyclic or polycyclic) aryl group, an (linear or branched) aralkyl group, or an (linear or branched) alkenyl group. Furthermore, in a case where all of Rx₁ to Rx₃ are (linear or branched) alkyl groups, it is preferable that at least two of Rx₁, Rx₂, or Rx₃ are methyl groups.

Above all, it is preferable that Rx₁ to Rx₃ each independently represent a linear or branched alkyl group, and it is more preferable that Rx₁ to Rx₃ each independently represent the linear alkyl group.

Two of Rx₁ to Rx₃ may be bonded to each other to form a ring (which may be either a monocycle or a polycycle).

As the alkyl group of each of Rx₁ to Rx₃, an alkyl group having 1 to 5 carbon atoms, such as a methyl group, an ethyl group, an n-propyl group, an isopropyl group, an n-butyl group, an isobutyl group, and a t-butyl group, is preferable.

As the cycloalkyl group of each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group as each of Rx₁ to Rx₃, an aryl group having 6 to 10 carbon atoms is preferable, and examples thereof include a phenyl group, a naphthyl group, and an anthryl group.

As the aralkyl group of each of Rx₁ to Rx₃, a group formed by substituting one hydrogen atom in the alkyl group of each of Rx₁ to Rx₃ mentioned above with an aryl group having 6 to 10 carbon atoms (preferably a phenyl group) is preferable, and examples thereof include a benzyl group.

As the alkenyl group of each of Rx₁ to Rx₃, a vinyl group is preferable.

As a ring formed by the bonding of two of Rx₁ to Rx₃, a cycloalkyl group is preferable. As the cycloalkyl group formed by the bonding of two of Rx₁ to Rx₃, a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group is preferable, and a monocyclic cycloalkyl group having 5 or 6 carbon atoms is more preferable.

In the cycloalkyl group formed by the bonding of two of Rx₁ to Rx₃, for example, one of the methylene groups constituting the ring may be substituted with a heteroatom such as an oxygen atom, a group having a heteroatom, such as a carbonyl group, or a vinylidene group. In addition, in the cycloalkyl group, one or more of the ethylene groups constituting the cycloalkane ring may be substituted with a vinylene group.

With regard to the group represented by Formula (Y1) or Formula (Y2), for example, an aspect in which Rx₁ is a methyl group or an ethyl group, and Rx₂ and Rx₃ are bonded to each other to form a cycloalkyl group is preferable.

In Formula (Y3), R₃₆ to R₃₈ each independently represent a hydrogen atom or a monovalent organic group. R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ is the hydrogen atom.

Furthermore, the alkyl group, the cycloalkyl group, the aryl group, and the aralkyl group may include a heteroatom such as an oxygen atom, and/or a group having a heteroatom, such as a carbonyl group. For example, in the alkyl group, the cycloalkyl group, the aryl group, and the aralkyl group, one or more of the methylene groups may be substituted with a heteroatom such as an oxygen atom, and/or a group having a heteroatom, such as a carbonyl group.

In addition, R₃₈ and another substituent contained in the main chain of the repeating unit may be bonded to each other to form a ring. A group formed by the mutual bonding of R₃₈ and another substituent in the main chain of the repeating unit is preferably an alkylene group such as a methylene group.

As Formula (Y3), a group represented by Formula (Y3-1) is preferable.

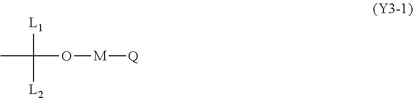

Here, L₁ and L₂ each independently represent a hydrogen atom, an alkyl group, a cycloalkyl group, an aryl group, or a group formed by combination thereof (for example, a group formed by combination of an alkyl group and an aryl group).

M represents a single bond or a divalent linking group.

Q represents an alkyl group which may include a heteroatom, a cycloalkyl group which may include a heteroatom, an aryl group which may include a heteroatom, an amino group, an ammonium group, a mercapto group, a cyano group, an aldehyde group, or a group formed by combination thereof (for example, a group formed by combination of an alkyl group and a cycloalkyl group).

In the alkyl group and the cycloalkyl group, for example, one of the methylene groups may be substituted with a heteroatom such as an oxygen atom or a group having a heteroatom, such as a carbonyl group.

In addition, it is preferable that one of L₁ or L₂ is a hydrogen atom, and the other is an alkyl group, a cycloalkyl group, an aryl group, or a group formed by combination of an alkylene group and an aryl group.

At least two of Q, M, or L₁ may be bonded to each other to form a ring (preferably a 5- or 6-membered ring).

From the viewpoint of pattern miniaturization, L₂ is preferably a secondary or tertiary alkyl group, and more preferably the tertiary alkyl group. Examples of the secondary alkyl group include an isopropyl group, a cyclohexyl group, and a norbornyl group, and examples of the tertiary alkyl group include a tert-butyl group and an adamantane group. In these aspects, since the glass transition temperature (Tg) and the activation energy are increased, it is possible to suppress fogging in addition to ensuring film hardness.

In Formula (Y4), Ar represents an aromatic ring group. Rn represents an alkyl group, a cycloalkyl group, or an aryl group. Rn and Ar may be bonded to each other to form a non-aromatic ring. Ar is more preferably the aryl group.

From the viewpoint that the acid decomposability of the repeating unit is excellent, in a case where a non-aromatic ring is directly bonded to a polar group (or a residue thereof) in a leaving group that protects the polar group, it is also preferable that a ring member atom adjacent to the ring member atom directly bonded to the polar group (or a residue thereof) in the non-aromatic ring has no halogen atom such as a fluorine atom as a substituent.

In addition, the leaving group that leaves by the action of an acid may be a 2-cyclopentenyl group having a substituent (an alkyl group and the like), such as a 3-methyl-2-cyclopentenyl group, and a cyclohexyl group having a substituent (an alkyl group and the like), such as a 1,1,4,4-tetramethylcyclohexyl group.

It is preferable that the repeating unit having an acid-decomposable group includes one or more selected from repeating units represented by the General formulae (3) to (7), and it is more preferable that the repeating unit having an acid-decomposable group includes one or more selected from the repeating unit represented by General Formula (6) and the repeating unit represented by General Formula (7).

It is preferable that the repeating unit having an acid-decomposable group includes a repeating unit represented by any one of General formula (3) . . . . , or (7), and it is more preferable that the repeating unit having an acid-decomposable group includes a repeating unit represented by General Formula (6) or the repeating unit represented by General Formula (7). Since the repeating unit represented by General Formula (6) or the repeating unit represented by General Formula (7) has a high reactivity with an acid, it is presumed that the repeating unit is advantageous for forming a space pattern.

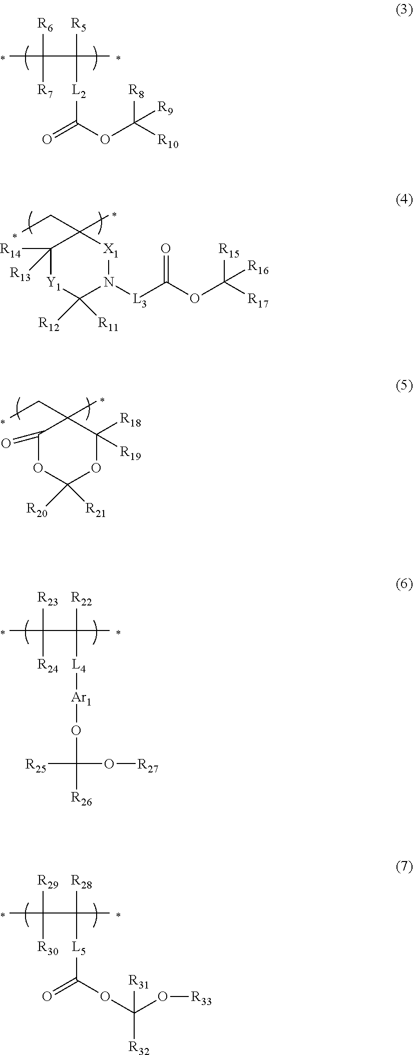

In General Formula (3), R₅, R₆, and R₇ each independently represent a hydrogen atom, an alkyl group, a cycloalkyl group, a halogen atom, a cyano group, or an alkoxycarbonyl group. L₂ represents a single bond or a divalent linking group. R₈ to R₁₀ each independently represent an alkyl group, a cycloalkyl group, an aryl group, an aralkyl group, or an alkenyl group. Furthermore, two of R₈ to R₁₀ may be bonded to each other to form a ring.

In General Formula (4), R₁₁ to R₁₄ each independently represent a hydrogen atom or an organic group. It should be noted that at least one of R₁₁ or R₁₂ represents an organic group. X₁ represents —CO—, —SO—, or —SO₂—. Y₁ represents —O—, —S—, —SO—, —SO₂—, or —NR₃₄—. R₃₄ represents a hydrogen atom or an organic group. L₃ represents a single bond or a divalent linking group. R₁₅ to R₁₇ each independently represent an alkyl group, a cycloalkyl group, an aryl group, an aralkyl group, or an alkenyl group. Furthermore, two of R₁₅ to R₁₇ may be bonded to each other to form a ring.

In General Formula (5), R₁₈ and R₁₉ each independently represent a hydrogen atom or an organic group. R₂₀ and R₂₁ each independently represent a hydrogen atom, an alkyl group, a cycloalkyl group, an aryl group, an aralkyl group, or an alkenyl group. Furthermore, R₂₀ and R₂₁ may be bonded to each other to form a ring.

In General Formula (6), R₂₂, R₂₃, and R₂₄ each independently represent a hydrogen atom, an alkyl group, a cycloalkyl group, a halogen atom, a cyano group, or an alkoxycarbonyl group. L₄ represents a single bond or a divalent linking group. An represents an aromatic ring group. R₂₅ to R₂₇ each independently represent a hydrogen atom, an alkyl group, a cycloalkyl group, an aryl group, an aralkyl group, or an alkenyl group. Furthermore, R₂₆ and R₂₇ may be bonded to each other to form a ring. In addition, Ar₁ may be bonded to R₂₄ or R₂₅ to form a ring.

In General Formula (7), R₂₈, R₂₉, and R₃₀ each independently represent a hydrogen atom, an alkyl group, a cycloalkyl group, a halogen atom, a cyano group, or an alkoxycarbonyl group. L₅ represents a single bond or a divalent linking group. R₃₁ and R₃₂ each independently represent a hydrogen atom, an alkyl group, a cycloalkyl group, an aryl group, an aralkyl group, or an alkenyl group. R₃₃ represents an alkyl group, a cycloalkyl group, an aryl group, an aralkyl group, or an alkenyl group. Furthermore, R₃₂ and R₃₃ may be bonded to each other to form a ring.

Hereinafter, the repeating unit represented by General Formula (3) w % ill be described.

The alkyl group represented by each of R₅, R₆, and R₇ may be either linear or branched. The number of carbon atoms of the alkyl group is not particularly limited, but is preferably 1 to 5, and more preferably 1 to 3.

As the cycloalkyl group represented by each of R₅, R₆, and R₇, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

Examples of the halogen atom represented by each of R₅, R₆, and R₇ include a fluorine atom, a chlorine atom, a bromine atom, and an iodine atom, and the fluorine atom or the iodine atom is preferable.

The alkyl group included in the alkoxycarbonyl group represented by each of R₅, R₆, and R₇ may be either linear or branched. The number of carbon atoms of the alkyl group included in the alkoxycarbonyl group is not particularly limited, but is preferably 1 to 5, and more preferably 1 to 3.

Examples of the divalent linking group represented by L₂ include —CO—, —O—, —S—, —SO—, —SO₂—, a hydrocarbon group (for example, an alkylene group, a cycloalkylene group, an alkenylene group, and an arylene group), and a linking group in which a plurality of these groups are linked.

The alkyl group represented by each of R₈ to R₁₀ may be either linear or branched. The number of carbon atoms of the alkyl group is not particularly limited, but is preferably 1 to 5, and more preferably 1 to 3. In the alkyl group represented by each of R₈ to R₁₀, the methylene group may be substituted with —CO— and/or —O—.

As the cycloalkyl group of each of R₈ to R₁₀, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group represented by each of R₈ to R₁₀, a phenyl group is preferable.

As the aralkyl group represented by each of R₈ to R₁₀, a group formed by substituting one hydrogen atom in the above-mentioned alkyl group represented by each of R₈ to R₁₀ with an aryl group having 6 to 10 carbon atoms (preferably a phenyl group) is preferable, and examples thereof include a benzyl group.

As the alkenyl group represented by each of R₈ to R₁₀, a vinyl group is preferable.

As a ring formed by the bonding of two of R₈ to R₁₀, a cycloalkyl group is preferable. As the cycloalkyl group formed by the bonding of two of R₈ to R₁₀, a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group is preferable, and a monocyclic cycloalkyl group having 5 or 6 carbon atoms is more preferable.

In the cycloalkyl group formed by the bonding of two of R₈ to R₁₀, for example, one of the methylene groups constituting the ring may be substituted with a heteroatom such as an oxygen atom, a group having a heteroatom, such as a carbonyl group, or a vinylidene group. In addition, in the cycloalkyl group, one or more of the ethylene groups constituting the cycloalkane ring may be substituted with a vinylene group.

The group in General Formula (3) may have a substituent, and examples of the substituent include the substituent T.

Hereinafter, the repeating unit represented by General Formula (4) will be described.

The organic group represented by each of R₁₁ to R₁₄ represents an alkyl group, a cycloalkyl group, an aryl group, an aralkyl group, or an alkenyl group.

Examples of the alkyl group, the cycloalkyl group, the aryl group, the aralkyl group, and the alkenyl group represented by each of R₁₁ to R₁₄ include the same groups as those of the alkyl group, the cycloalkyl group, the aryl group, the aralkyl group, and the alkenyl group represented by each of R₈ to R₁₀ in General Formula (3) mentioned above.

As X₁, —CO— is preferable among those.

The organic group represented by R₃₄ has the same definition as the organic group represented by each of R₁₁ to R₁₄ mentioned above, and a suitable aspect thereof is also the same.

As Y₁, —O— is preferable.

The divalent linking group represented by L₃ has the same definition as the divalent linking group represented by L₂ in General Formula (3) mentioned above, and a suitable aspect thereof is also the same.

Examples of the alkyl group, the cycloalkyl group, the aryl group, the aralkyl group, and the alkenyl group represented by each of R₁₅ to R₁₇ include the same groups as those of the alkyl group, the cycloalkyl group, the aryl group, the aralkyl group, and the alkenyl group represented by each of R₈ to R₁₀ in General Formula (3) mentioned above.

As a ring formed by the bonding of two of R₁₅ to R₁₇, a cycloalkyl group is preferable. As the cycloalkyl group formed by the bonding of two of R₁₅ to R₁₇, a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group is preferable, and a monocyclic cycloalkyl group having 5 or 6 carbon atoms is more preferable.

In the cycloalkyl group formed by the bonding of two of R₁₅ to R₁₇, for example, one of the methylene groups constituting the ring may be substituted with a heteroatom such as an oxygen atom, a group having a heteroatom, such as a carbonyl group, or a vinylidene group. In addition, in the cycloalkyl group, one or more of the ethylene groups constituting the cycloalkane ring may be substituted with a vinylene group.

The group in General Formula (4) may have a substituent, and examples of the substituent include the substituent T.

Hereinafter, the repeating unit represented by General Formula (5) will be described.

The organic group represented by each of R₁₈ and R₁₉ has the same definition as the organic group represented by each of R₁₁ to R₁₄ in General Formula (4) mentioned above, and a suitable aspect thereof is also the same.

Examples of the alkyl group, the cycloalkyl group, the aryl group, the aralkyl group, and the alkenyl group represented by each of R₂₀ and R₂₁ include the same groups as those of the alkyl group, the cycloalkyl group, the aryl group, the aralkyl group, and the alkenyl group represented by each of R₈ to R₁₀ in General Formula (3) mentioned above.

The alkyl group, the cycloalkyl group, the aryl group, the aralkyl group, and the alkenyl group represented by each of R₂₀ and R₂₁ may have a substituent, and examples of the substituent include the substituent T.

As the ring formed by the bonding of R₂₀ and R₂₁, a cycloalkyl group is preferable. As the cycloalkyl group formed by the bonding of R₂₀ and R₂₁, a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group is preferable, and a monocyclic cycloalkyl group having 5 or 6 carbon atoms is more preferable.

In the cycloalkyl group formed by the bonding of R₂₀ and R₂₁, for example, one of the methylene groups constituting the ring may be substituted with a heteroatom such as an oxygen atom, a group having a heteroatom, such as a carbonyl group, or a vinylidene group. In addition, in the cycloalkyl group, one or more of the ethylene groups constituting the cycloalkane ring may be substituted with a vinylene group.

Hereinafter, the repeating unit represented by General Formula (6) will be described.

R₂₂, R₂₃, R₂₄, and L₄ have the same definitions as R₅, R₆, R₇, and L₂ in General Formula (3), respectively, and suitable aspects are also the same.

The aromatic ring group represented by Ar₁ is not particularly limited, examples thereof include a benzene ring and a naphthalene ring, and the benzene ring is preferable.

Examples of the alkyl group, the cycloalkyl group, the aryl group, the aralkyl group, and the alkenyl group represented by each of R₂₅ to R₂₇ include the same groups as those of the alkyl group, the cycloalkyl group, the aryl group, the aralkyl group, and the alkenyl group represented by each of R₈ to R₁₀ in General Formula (3) mentioned above.

The alkyl group, the cycloalkyl group, the aryl group, the aralkyl group, and the alkenyl group represented by each of R₂₅ to R₂₇ may have a substituent, and examples of the substituent include the substituent T.

A cycloalkyl group is preferable as the ring formed by the bonding of R₂₆ and R₂₇, Ar₁ and R₂₄, or R₂₅ and Ar₁. As the cycloalkyl group formed by the bonding of R₂₆ and R₂₇, Ar₁ and R₂₄, or R₂₅ and Ar₁, a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group is preferable, and a monocyclic cycloalkyl group having 5 or 6 carbon atoms is more preferable.

In the cycloalkyl group formed by the bonding of R₂₆ and R₂₇, Ar₁ and R₂₄, or R₂₅ and Ar₁, for example, one of the methylene groups constituting the ring may be substituted with a heteroatom such as an oxygen atom, a group having a heteroatom, such as a carbonyl group, or a vinylidene group. In addition, in the cycloalkyl group, one or more of the ethylene groups constituting the cycloalkane ring may be substituted with a vinylene group.

Hereinafter, the repeating unit represented by General Formula (7) will be described.

R₂₈, R₂₉, R₃₀, and L₅ have the same definitions as R₅, R₆, R₇, and L₂ in General Formula (3), respectively, and suitable aspects are also the same.

Examples of the alkyl group, the cycloalkyl group, the aryl group, the aralkyl group, and the alkenyl group represented by each of R₃₁, R₃₂, and R₃₃ include the same groups as those of the alkyl group, the cycloalkyl group, the aryl group, the aralkyl group, and the alkenyl group represented by each of R₈ to R₁₀ in General Formula (3) mentioned above.

The alkyl group, the cycloalkyl group, the aryl group, the aralkyl group, and the alkenyl group represented by each of R₃₁, R₃₂, and R₃₃ may have a substituent, and examples of the substituent include the substituent T.

A cycloalkyl group is preferable as the ring formed by the bonding of R₃₂ and R₃₃. As the cycloalkyl group formed by the bonding of R₃₂ and R₃₃, a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group is preferable, and a monocyclic cycloalkyl group having 5 or 6 carbon atoms is more preferable.

In the cycloalkyl group formed by the bonding of R₃₂ and R₃₃, for example, one of the methylene groups constituting the ring may be substituted with a heteroatom such as an oxygen atom, a group having a heteroatom, such as a carbonyl group, or a vinylidene group. In addition, in the cycloalkyl group, one or more of the ethylene groups constituting the cycloalkane ring may be substituted with a vinylene group.

The repeating unit having an acid-decomposable group may or may not include a halogen atom, and it is preferable that the repeating unit having an acid-decomposable group does not include a halogen atom.

The content of the repeating unit having an acid-decomposable group is preferably 5% by mole or more, more preferably 10% by mole or more, and still more preferably 15% by mole or more with respect to all repeating units in the resin (A). In addition, the content of the repeating unit having an acid-decomposable group is preferably 95% by mole or less, more preferably 90% by mole or less, and particularly preferably 85% by mole or less with respect to all repeating units in the resin (A).

Specific examples of the repeating unit having an acid-decomposable group are shown below, but are not limited thereto. In the following structural formulae, Xa₁ represents any one of H, CH₃, CF₃, or CH₂OH, and Rxa and Rxb each independently represent a linear or branched alkyl group having 1 to 5 carbon atoms.

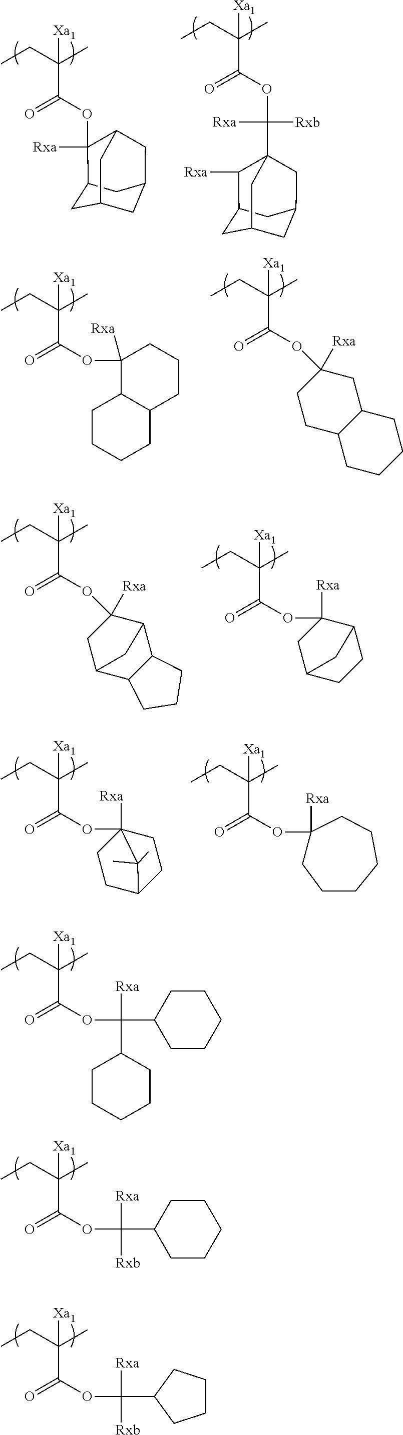

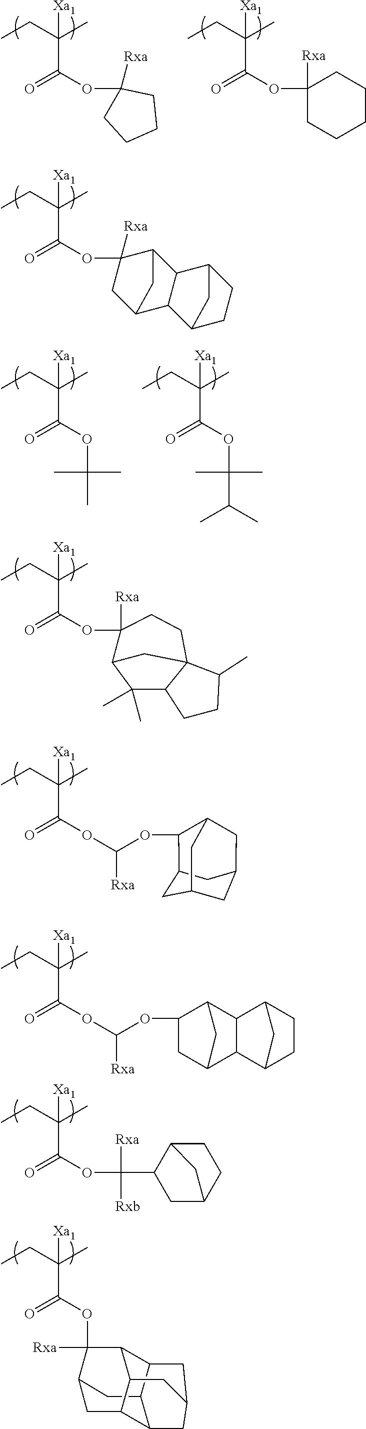

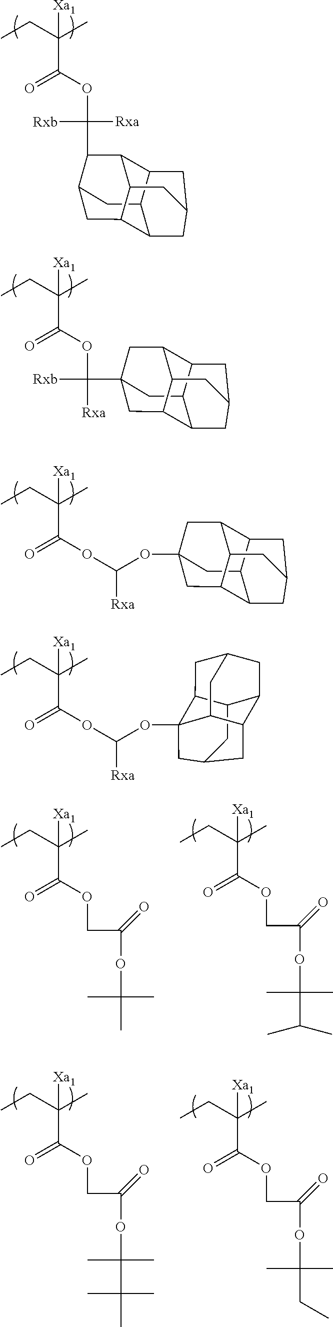

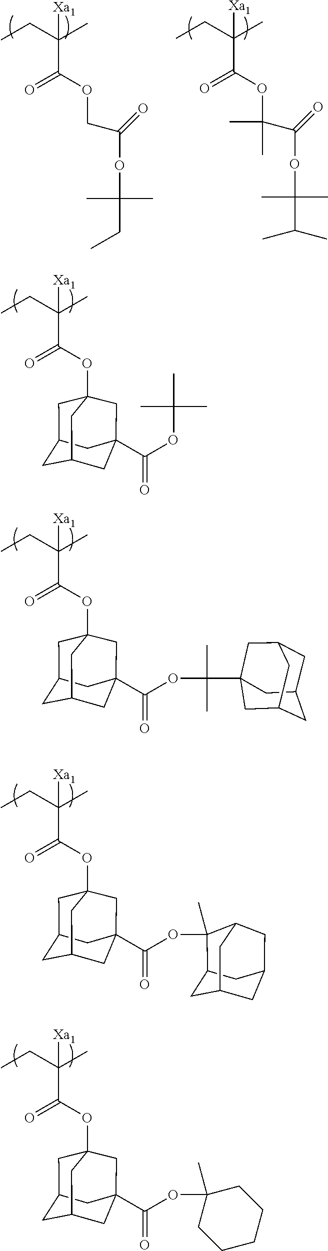

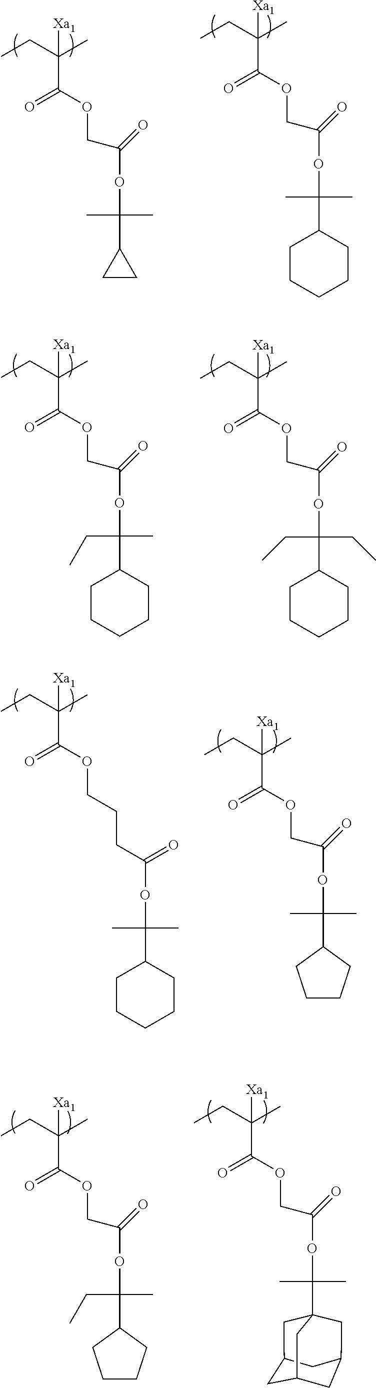

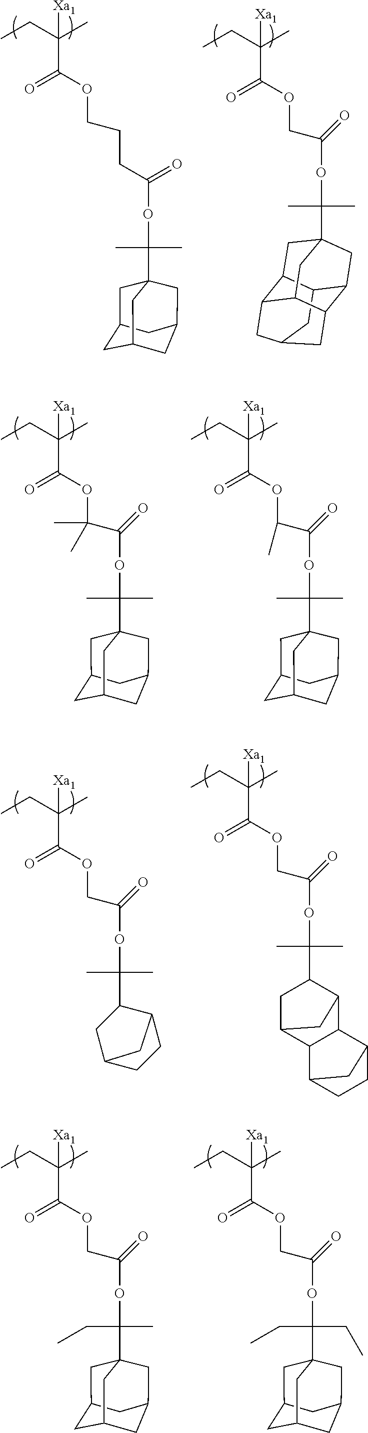

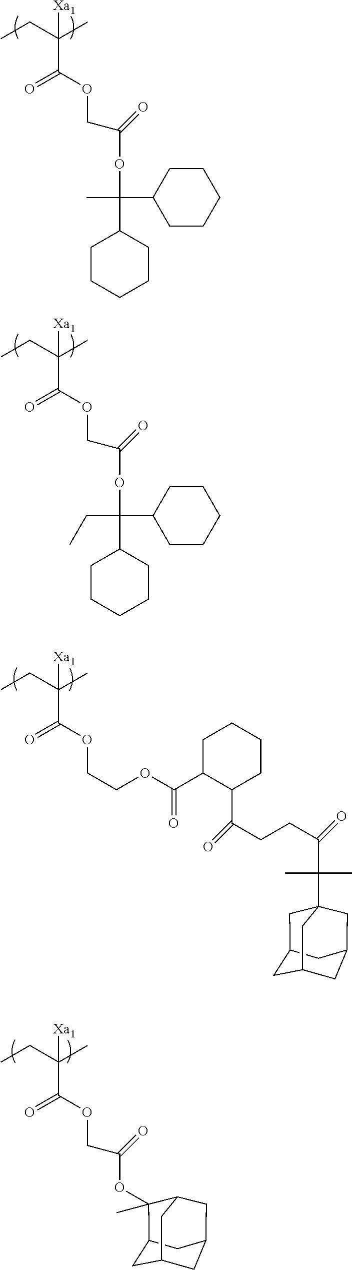

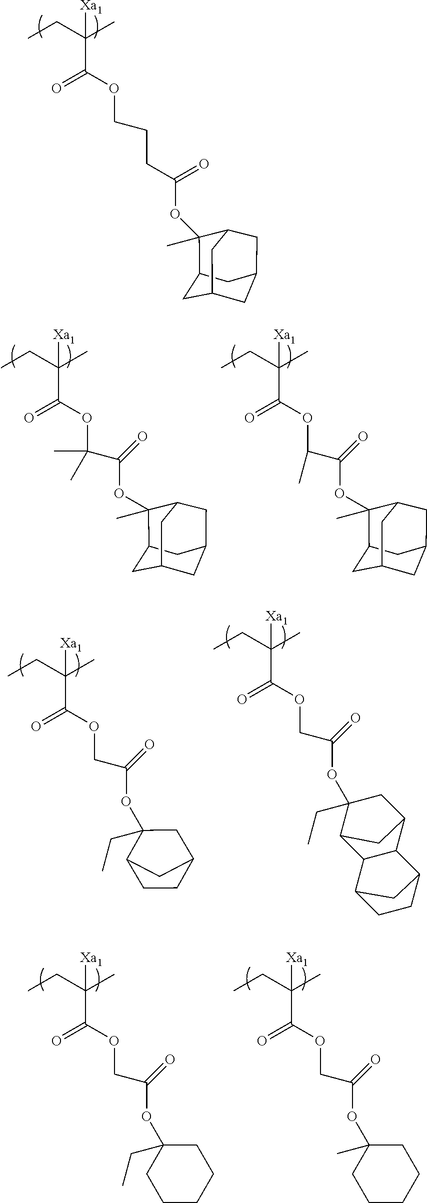

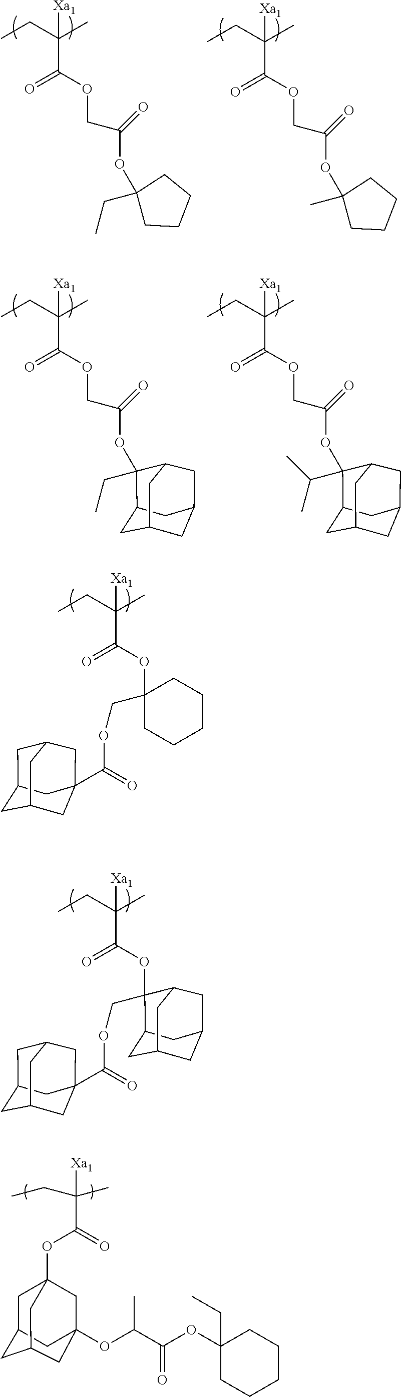

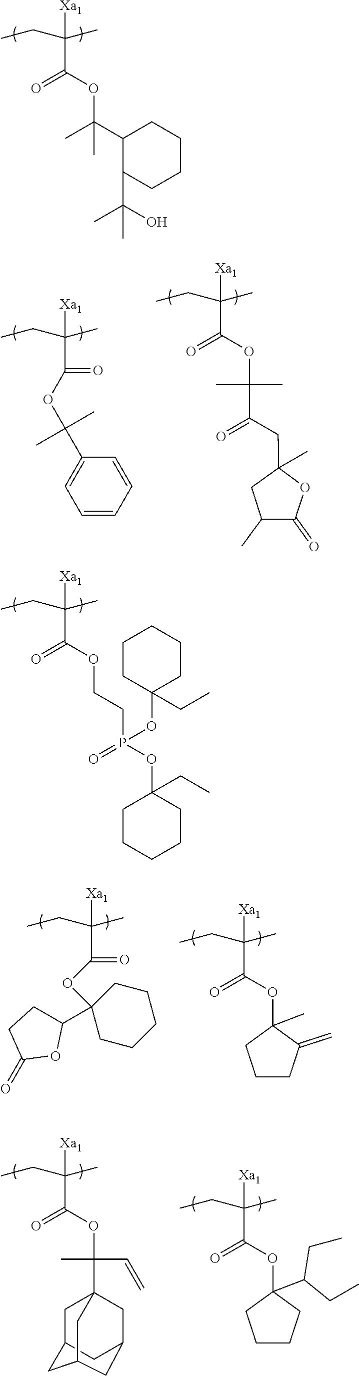

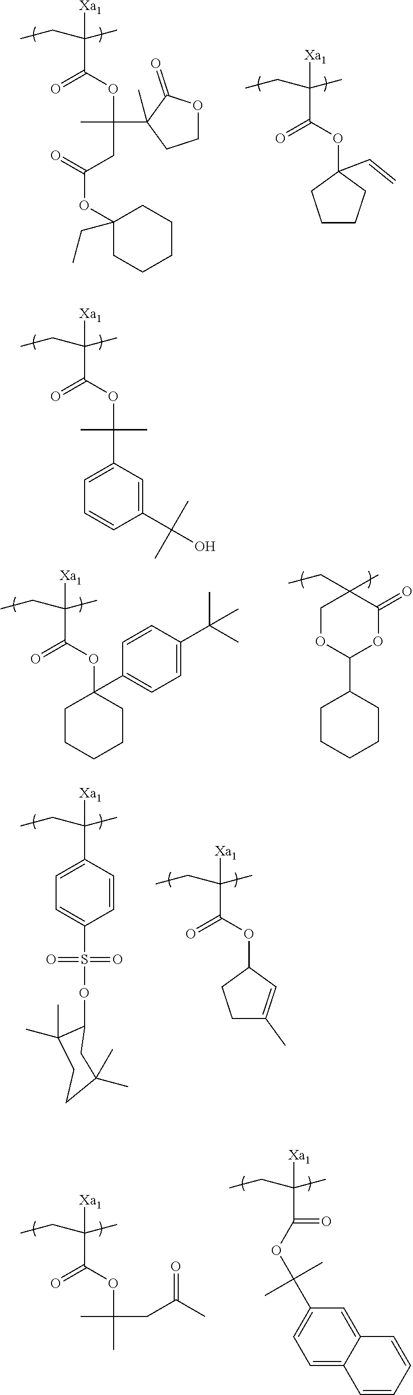

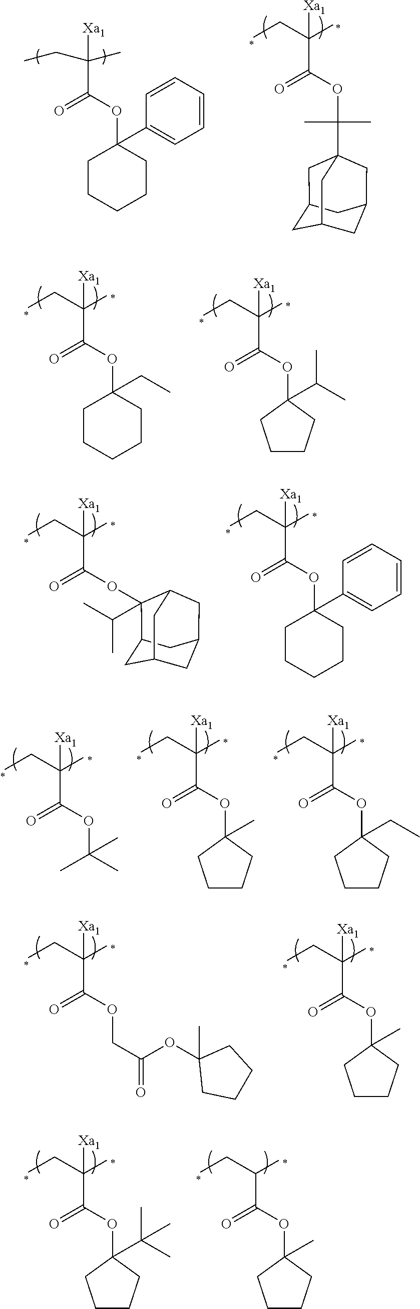

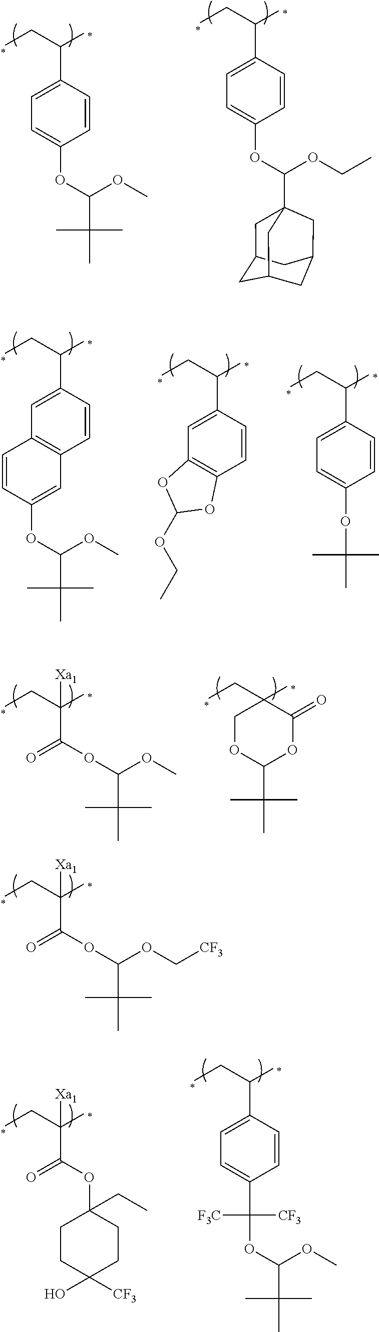

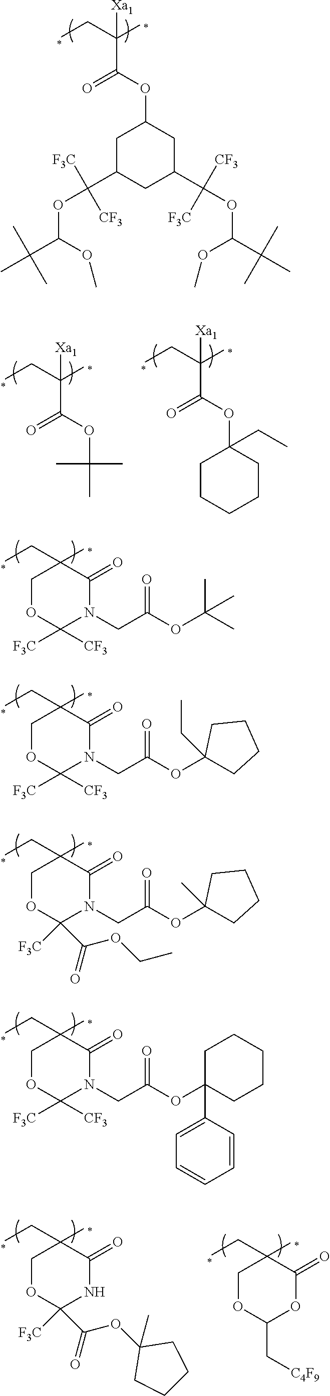

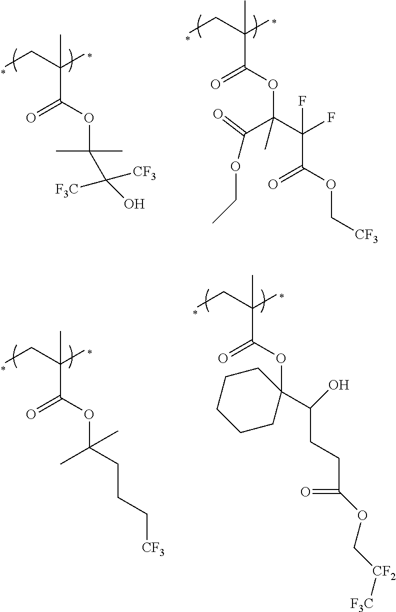

<Other Repeating Units>

The resin (A) may include other repeating units other than the above-mentioned repeating units.

In a case where the resin (A) includes other repeating units other than the above-mentioned repeating units, the content of such other repeating units is not particularly limited, but is preferably from 1% by mole to 60% by mole, more preferably from 3% by mole to 50% by mole, and still more preferably from 5% by mole to 40% by mole with respect to all repeating units in the resin (A).

(Repeating Unit Having Acid Group)

The resin (A) may further have a repeating unit having an acid group, in addition to the repeating units.

As the acid group, for example, a carboxy group, a fluorinated alcohol group (preferably a hexafluoroisopropanol group), a sulfonic acid group, a sulfonamide group, or an isopropanol group is preferable.

In addition, in the hexafluoroisopropanol group, one or more (preferably one or two) fluorine atoms may be substituted with a group (for example, an alkyloxycarbonyl group) other than a fluorine atom. —C(CF₃)(OH)—CF₂— formed as above is also preferable as the acid group. In addition, one or more fluorine atoms may be substituted with a group other than a fluorine atom to form a ring including —C(CF₃)(OH)—CF₂—.

With regard to the specific examples of the repeating unit having an acid group, reference can be made to, for example, the description in paragraph [0205] of WO2019/054282A, the contents of which are incorporated herein by reference. It should be noted that the repeating unit having an acid group is not limited thereto.

(Repeating Unit Having Fluorine Atom or Iodine Atom and not Exhibiting Acid Decomposability)

The resin (A) may further have a repeating unit which has a fluorine atom or an iodine atom, and does not exhibit acid decomposability, in addition to the above-described repeating units.

A repeating unit having a fluorine atom or an iodine atom and not exhibiting acid decomposability will be exemplified below, but is not limited thereto.

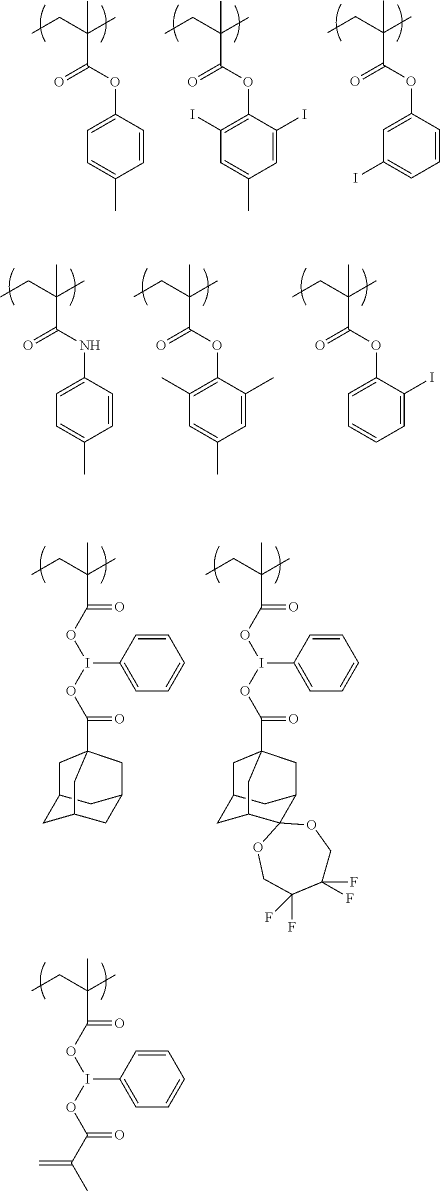

(Repeating Unit Having Lactone Group, Sultone Group, or Carbonate Group)

The resin (A) may further have a repeating unit having a lactone group, a sultone group, or a carbonate group, in addition to the above-described repeating units.

The lactone group or the sultone group may have a lactone structure or a sultone structure. The lactone structure or the sultone structure is preferably a 5- to 7-membered ring lactone structure or a 5- to 7-membered ring sultone structure. Among those, the structure is more preferably a 5- to 7-membered ring lactone structure with which another ring structure is fused so as to form a bicyclo structure or a spiro structure, or a 5- to 7-membered ring sultone structure with which another ring structure is fused so as to form a bicyclo structure or a spiro structure.

The resin (A) preferably has a repeating unit having a lactone group or a sultone group, formed by extracting one or more hydrogen atoms from a ring member atom of a lactone structure represented by any of General Formulae (LC1-1) to (LC1-21) or a sultone structure represented by any of General Formulae (SL1-1) to (SL1-3).

In addition, the lactone group or the sultone group may be bonded directly to the main chain. For example, a ring member atom of the lactone group or the sultone group may constitute the main chain of the resin (A).

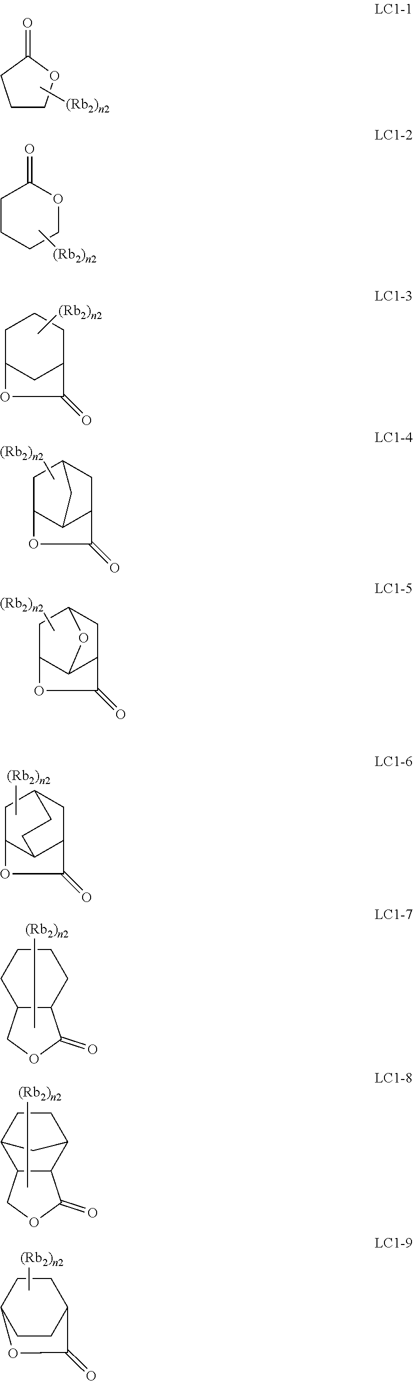

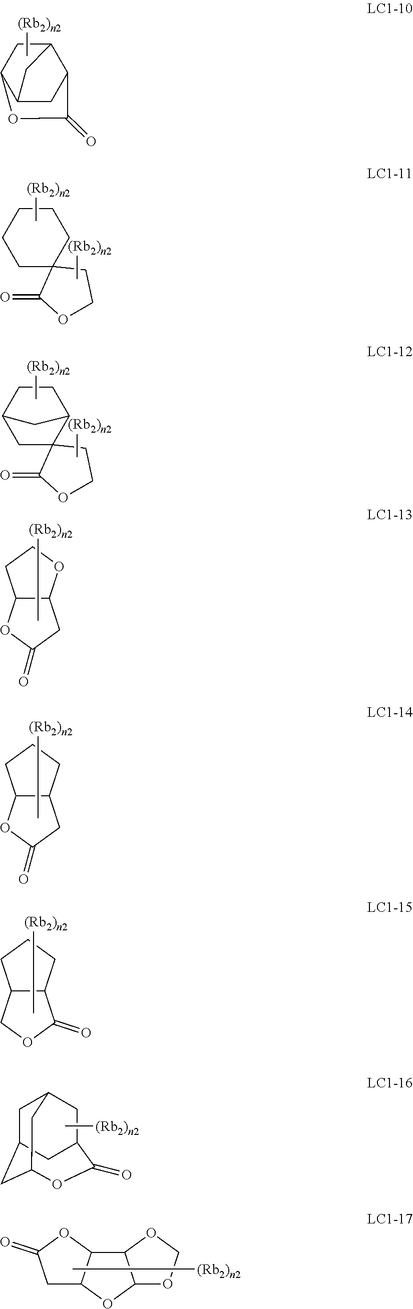

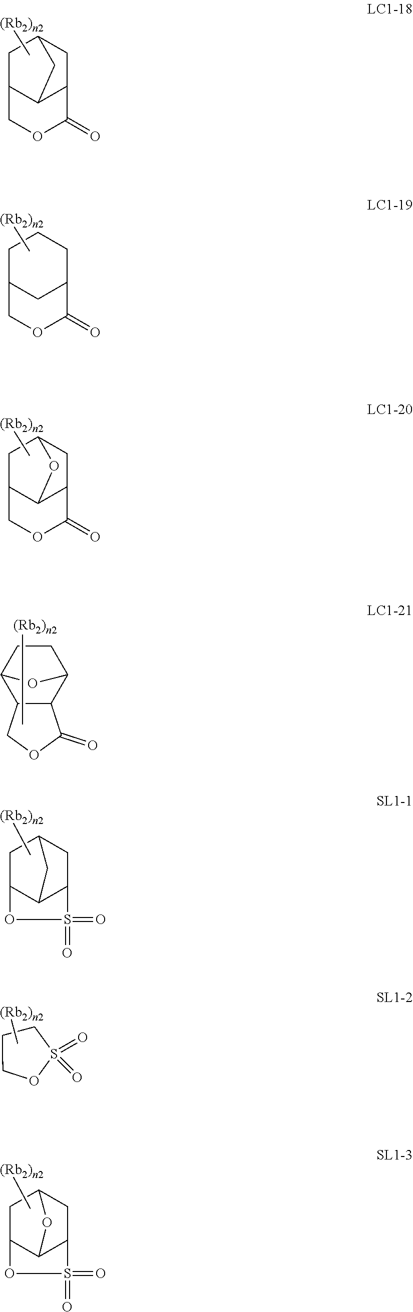

The moiety of the lactone structure or the sultone structure may have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxy group, a halogen atom, a hydroxyl group, a cyano group, and an acid-decomposable group. n₂ represents an integer of 0 to 4. In a case where n₂ is 2 or more, Rb₂'s which are present in a plural number may be different from each other, and Rb₂'s which are present in a plural number may be bonded to each other to form a ring.

With regard to the specific examples of the repeating unit having a lactone structure, reference can be made to, for example, the description in paragraph [0088] of WO2018/193954A, the contents of which are incorporated herein by reference. It should be noted that the repeating unit having a lactone structure is not limited thereto.

As the carbonate group, a cyclic carbonate group is preferable.

(Repeating Unit Having Photoacid Generating Group)

The resin (A) may have a repeating unit having a photoacid generating group. With regard to the repeating unit having a photoacid generating group, reference can be made to the description in paragraphs [0090] to [0096] of WO2018/193954A, the contents of which are incorporated herein by reference.

(Other Repeating Units)

The resin (A) may have a variety of repeating units, in addition to the repeating units described above, for the purpose of, for example, adjusting dry etching resistance, suitability for a standard developer, adhesiveness to a substrate, a resist profile, resolving power, heat resistance, sensitivity, and the like.

With regard to other repeating units other than those above, reference can be made to the description in paragraphs [0097] to [0100] and [0102] to [0133] of WO2018/193954A, the contents of which are incorporated herein by reference.

The resin (A) can be synthesized in accordance with an ordinary method (for example, radical polymerization).

The weight-average molecular weight of the resin (A) is not particularly limited, but is preferably 1,000 to 200,000, more preferably 2,000 to 30,000, and still more preferably 3,000 to 20,000.

The dispersity (molecular weight distribution) of the resin (A) is usually 1.0 to 5.0, preferably 1.0 to 3.0, more preferably 1.0 to 2.5, and still more preferably 1.0 to 2.0.

The content of the resin (A) in the composition of the embodiment of the present invention is not particularly limited, but is preferably 50% to 99.9% by mass, and more preferably 60% to 99.0% by mass with respect to the total solid content of the composition. Furthermore, the solid content is intended to be components excluding the solvent in the composition, and any of components other than the solvent are regarded as the solid content even in a case where they are liquid components.

In addition, the composition of the embodiment of the present invention may include one kind or two or more kinds of the resin (A).

[Compound that Generates Acid Upon Irradiation with Actinic Rays or Radiation (B)]

The composition of the embodiment of the present invention contains a compound (B) that generates an acid upon irradiation with actinic rays or radiation (also referred to as a “compound (B)” or a “photoacid generator (B)”).

The compound (B) is a compound that generates an acid upon irradiation with actinic rays or radiation (photoacid generator).

The compound (B) is preferably a compound that generates an organic acid upon irradiation with actinic rays or radiation. Examples thereof include a sulfonium salt compound, an iodonium salt compound, a diazonium salt compound, a phosphonium salt compound, an imidosulfonate compound, an oxime sulfonate compound, a diazodisulfone compound, a disulfone compound, and an o-nitrobenzyl sulfonate compound.

As the compound (B), known compounds that generate an acid upon irradiation with actinic rays or radiation can be appropriately selected and used singly or as a mixture thereof. For example, the known compounds disclosed in paragraphs [0125] to [0319] of the specification of US2016/0070167A1, paragraphs [0086] to [0094] of the specification of US2015/0004544A1, and paragraphs [0323] to [0402] of the specification of US2016/0237190A1 can be suitably used.

The compound (B) is preferably an ionic compound including an anion and a cation.

With regard to the compound (B), reference can be made to the description in paragraphs [0135] to [0171] of WO2018/193954A, the contents of which are incorporated herein by reference.

The molecular weight of the compound (B) is not particularly limited, but is preferably 300 to 3,000, more preferably 300 to 2,000, and still more preferably 300 to 1,500.

The compound (B) is preferably a compound having an acid-decomposable group.

The compound (B) is more preferably an ionic compound including an anion and a cation, in which the compound has an acid-decomposable group in the anion.

The acid-decomposable group in the compound (B) is the same as the acid-decomposable group in the resin (A) described earlier, and reference can be made to the description above.

It is considered that by incorporating an acid-decomposable group into the compound (B), in the exposed portion of an actinic ray-sensitive or radiation-sensitive film formed of the composition of the embodiment of the present invention, a decomposition product of the compound (B) can be easily dissolved in an alkali developer by the action of an acid generated from the compound (B), thereby suppressing the generation of development defects. Furthermore, it is considered that a dissolution contrast between the exposed portion and the unexposed portion can be improved by an increase in the solubility of a developer in the exposed portion, thereby further improving the resolving power of a fine pattern.

<Compound Represented by General Formula (b1)>

The compound (B) is preferably a compound represented by General Formula (b1).

ₙ(A-L [symbol] X—SO₃⁻M⁺ (b1)

In General Formula (b1), L represents a single bond or a divalent linking group. In a case where there are a plurality of L's, the plurality of L's may be the same as or different from each other. A represents a group that decomposes by the action of an acid. In a case where there are a plurality of A's, the plurality of A's may be the same as or different from each other. n represents an integer from 1 to 5. X represents an (n+1)-valent linking group. M⁺ represents a sulfonium ion or an iodonium ion.

In General Formula (b1), X represents an (n+1)-valent linking group.

The linking group represented by X is not particularly limited, but examples thereof include an aliphatic group (which may be linear, branched, or cyclic), an aromatic group, —O—, —CO—, —COO—, —OCO—, and a group formed by combination of two or more of these groups.

As the aliphatic group, a group obtained by removing n pieces of hydrogen atoms from an alkyl group (which may be linear or branched, and is preferably an alkyl group having 1 to 20 carbon atoms, and more preferably an alkyl group having 1 to 10 carbon atoms) and a group obtained by removing n pieces of hydrogen atoms from a cycloalkyl group (which may be either a monocycle or a polycycle, and is preferably a cycloalkyl group having 3 to 20 carbon atoms, and more preferably a cycloalkyl group having 5 to 10 carbon atoms) are preferable.

The aliphatic group may have a substituent, and examples of the substituent include the substituent T.

The aliphatic group may have a heteroatom (for example, a sulfur atom, an oxygen atom, and a nitrogen atom) between carbon atoms.

As the aromatic group, a group obtained by removing n pieces of hydrogen atoms from an aryl group (preferably an aryl group having 6 to 20 carbon atoms, and more preferably an aryl group having 6 to 18 carbon atoms, in which the aryl group is also preferably an aryl group having 6 to 10 carbon atoms, and specific examples of the aryl group include a phenyl group and a terphenyl group) is preferable.

The aromatic group may have a substituent, and examples of the substituent include the substituent T.

The aromatic group may have a heteroatom (for example, a sulfur atom, an oxygen atom, and a nitrogen atom) between carbon atoms.

X is preferably an (n+1)-valent aromatic group.

In General Formula (b1), n represents an integer of 1 to 5, preferably represents an integer of 1 to 3, more preferably represents 2 or 3, and still more preferably represents 3.

In General Formula (b1), L represents a single bond or a divalent linking group.

The divalent linking group represented by L is not particularly limited, but examples thereof include an aliphatic group (which may be linear, branched, or cyclic), an aromatic group, —O—, —CO—, —COO—, —OCO—, and a group formed by combination of two or more of these groups.

As the aliphatic group, an alkylene group (which may be linear or branched, and is preferably an alkylene group having 1 to 20 carbon atoms, and more preferably an alkylene group having 1 to 10 carbon atoms) and a cycloalkylene group (which may be either a monocycle or a polycycle, and is preferably a cycloalkylene group having 3 to 20 carbon atoms, and more preferably a cycloalkylene group having 5 to 10 carbon atoms) are preferable.

The aliphatic group may have a substituent, and examples of the substituent include the substituent T.

The aliphatic group may have a heteroatom (for example, a sulfur atom, an oxygen atom, and a nitrogen atom) between carbon atoms.

As the aromatic group, an arylene group (preferably an arylene group having 6 to 20 carbon atoms, and more preferably an arylene group having 6 to 10 carbon atoms) is preferable.

The aromatic group may have a substituent, and examples of the substituent include the substituent T.

The aromatic group may have a heteroatom (for example, a sulfur atom, an oxygen atom, and a nitrogen atom) between carbon atoms.

L is preferably an arylene group.

In General Formula (b1), A represents a group that decomposes by the action of an acid.

The group that decomposes by the action of an acid represented by A (acid-decomposable group) is not particularly limited, and examples thereof include the acid-decomposable group described in the resin (A).

The acid-decomposable group preferably has a structure in which a polar group is protected by a group that leaves through decomposition by the action of an acid (leaving group).

As the polar group, a carboxy group, a phenolic hydroxyl group, or an alcoholic hydroxyl group is preferable.

The group that decomposes by the action of an acid represented by A is preferably at least one selected from the group consisting of a group represented by General Formula (T-1) and a group represented by General Formula (T-2), and more preferably the group represented by General Formula (T-1).

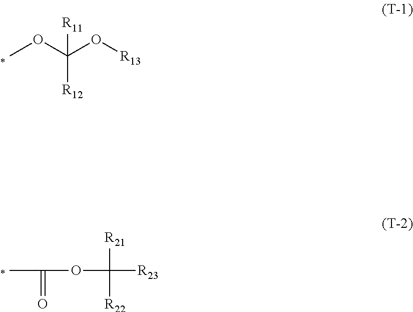

In General Formula (T-1),

R₁₁ represents a hydrogen atom or an alkyl group.

R₁₂ represents a hydrogen atom, an alkyl group, a cycloalkyl group, or an aryl group, and the alkyl group and the cycloalkyl group may include an ether bond or a carbonyl bond.

R₁₃ represents an alkyl group, a cycloalkyl group, or an aryl group, and the alkyl group and the cycloalkyl group may include an ether bond or a carbonyl bond.

R₁₁ and R₁₂ may be bonded to each other to form a ring.

R₁₂ and R₁₃ may be bonded to each other to form a ring.

* represents a bond.

In General Formula (T-2),

R₂₁, R₂₂, and R₂₃ each independently represent an alkyl group.

Two of R₂₁ to R₂₃ may be bonded to each other to form a ring.

* represents a bond.

In General Formula (T-1), R₁₁ represents a hydrogen atom or an alkyl group.

In a case where R₁₁ represents the alkyl group, the alkyl group may be linear or branched, and is preferably an alkyl group having 1 to 10 carbon atoms, more preferably an alkyl group having 1 to 5 carbon atoms, and still more preferably an alkyl group having 1 to 3 carbon atoms. Examples of the alkyl group include a methyl group, an ethyl group, a propyl group, an n-butyl group, a sec-butyl group, a hexyl group, and an octyl group.

The alkyl group may have a substituent, and examples of the substituent include the substituent T.

R₁₁ is preferably the hydrogen atom or the alkyl group having 1 to 3 carbon atoms, and more preferably the hydrogen atom.

In General Formula (T-1), R₁₂ represents a hydrogen atom, an alkyl group, a cycloalkyl group, or an aryl group.

In a case where R₁₂ represents the alkyl group, the alkyl group may be linear or branched, and is preferably an alkyl group having 1 to 10 carbon atoms, and more preferably an alkyl group having 1 to 5 carbon atoms. Examples of the alkyl group include a methyl group, an ethyl group, a propyl group, an n-butyl group, a sec-butyl group, a hexyl group, and an octyl group.

The alkyl group may have a substituent, and examples of the substituent include the substituent T.

The alkyl group may include an ether bond or a carbonyl bond.

In a case where R₁₂ represents the cycloalkyl group, the cycloalkyl group may be a monocycle or a polycycle, and is preferably a cycloalkyl group having 3 to 20 carbon atoms, more preferably a cycloalkyl group having 5 to 15 carbon atoms, and still more preferably a cycloalkyl group having 5 to 10 carbon atoms. Examples of the cycloalkyl group include a cyclopropyl group, a cyclobutyl group, a cyclopentyl group, a cyclohexyl group, a cyclooctyl group, an adamantyl group, a norbornyl group, an isobornyl group, a camphanyl group, a dicyclopentyl group, an α-pinel group, a tricyclodecanyl group, a tetracyclododecyl group, and an androstanyl group.

The cycloalkyl group may have a substituent, and examples of the substituent include the substituent T.

The cycloalkyl group may include an ether bond or a carbonyl bond.

In a case where R₁₂ represents the aryl group, the aryl group is preferably an aryl group having 6 to 20 carbon atoms, more preferably an aryl group having 6 to 15 carbon atoms, and still more preferably an aryl group having 6 to 10 carbon atoms. Examples of the aryl group include a phenyl group and a naphthyl group.

The aryl group may have a substituent, and examples of the substituent include the substituent T.

R₁₂ is preferably the hydrogen atom or the alkyl group having 1 to 5 carbon atoms.

In General Formula (T-1), R₁₃ represents an alkyl group, a cycloalkyl group, or an aryl group.

The alkyl group, the cycloalkyl group, or the aryl group represented by R₁₃ is the same as the alkyl group, the cycloalkyl group, or the aryl group described as represented by R₁₂, respectively.

R₁₃ is preferably the alkyl group having 1 to 5 carbon atoms.

R₁₁ and R₁₂ may be bonded to each other to form a ring.

The ring formed by the mutual bonding of R₁₁ and R₁₂ is preferably an aliphatic ring.

The aliphatic ring is preferably a cycloalkane having 3 to 20 carbon atoms, and more preferably a cycloalkane having 5 to 15 carbon atoms. The cycloalkane may be either a monocycle or a polycycle.

The aliphatic ring may have a substituent, and examples of the substituent include the substituent T.

The aliphatic ring may have a heteroatom (for example, a sulfur atom, an oxygen atom, and a nitrogen atom) between carbon atoms.

R₁₂ and R₁₃ may be bonded to each other to form a ring.

The ring formed by the mutual bonding of R₁₂ and R₁₃ is preferably an aliphatic ring containing an oxygen atom as a ring member.

The aliphatic ring preferably has 3 to 20 carbon atoms, and more preferably has 5 to 15 carbon atoms. The aliphatic ring may be either a monocycle or a polycycle.

The aliphatic ring may have a substituent, and examples of the substituent include the substituent T.

The aliphatic ring may have a heteroatom other than an oxygen atom (for example, a sulfur atom and a nitrogen atom) between carbon atoms.

An aspect in which in General Formula (T-1), R₁₁ and R₁₂ are not bonded to each other, and R₁₂ and R₁₃ are bonded to each other to form a ring is one of preferred aspects of the present invention.

In General Formula (T-2), R₂₁, R₂₂, and R₂₃ each independently represent an alkyl group.

In a case where R₂₁, R₂₂, and R₂₃ represent the alkyl group, the alkyl group is not particularly limited and may be linear or branched. As the alkyl group, an alkyl group having 1 to 4 carbon atoms, such as a methyl group, an ethyl group, an n-propyl group, an isopropyl group, an n-butyl group, an isobutyl group, and a t-butyl group, is preferable.

The alkyl group may have a substituent. Examples of the substituent include an aryl group (for example, an aryl group having 6 to 15 carbon atoms), a halogen atom, a hydroxyl group, an alkoxy group (for example, an alkoxy group having 1 to 4 carbon atoms), a carboxy group, and an alkoxycarbonyl group (for example, an alkoxycarbonyl group having 2 to 6 carbon atoms). The substituent preferably has 8 or less carbon atoms.

Two of R₂₁ to R₂₃ may be bonded to each other to form a ring.

In a case where two of R₂₁ to R₂₃ are bonded to each other to form a ring, it is preferable that two of R₂₁ to R₂₃ are bonded to each other to form a cycloalkyl group. The cycloalkyl group may be either a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group. Among those, a monocyclic cycloalkyl group having 5 or 6 carbon atoms is preferable.

In the cycloalkyl group, for example, one of the methylene groups constituting the ring may be substituted with a heteroatom such as an oxygen atom or a group having a heteroatom, such as a carbonyl group.

In General Formula (b1), M⁺ represents a sulfonium ion or an iodonium ion.

The sulfonium ion or the iodonium ion represented by M⁺ preferably has no nitrogen atom. It is considered that in a case where the sulfonium ion or the iodonium ion has no nitrogen atom, an acid generated is not neutralized and the LWR performance is particularly good.

M⁺ is not particularly limited, but is preferably a cation represented by General Formula (ZIA) or General Formula (ZIIA).

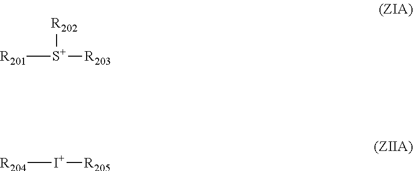

In General Formula (ZIA),

R₂₀₁, R₂₀₂, and R₂₀₃ each independently represent an organic group.

The organic group as each of R₂₀₁, R₂₀₂, and R₂₀₃ generally has 1 to 30 carbon atoms, and preferably has 1 to 20 carbon atoms.

In addition, two of R₂₀₁ to R₂₀₃ may be bonded to each other to form a ring structure, and the ring may include an oxygen atom, a sulfur atom, an ester bond, an amide bond, or a carbonyl group. Examples of the group formed by the bonding of two of R₂₀₁ to R₂₀₃ include an alkylene group (for example, a butylene group and a pentylene group) and —CH₂—CH₂—O—CH₂—CH₂—.

Suitable aspects of the cation as General Formula (ZIA) include a cation (ZI-11), a cation (ZI-12), a cation represented by General Formula (ZI-13) (cation (ZI-13)), and a cation represented by General Formula (ZI-14) (cation (ZI-14)), each of which will be described later.

The divalent or higher cation in a case where n is 2 or more may be a cation having a plurality of structures represented by General Formula (ZIA). Examples of such the cation include a divalent cation having a structure in which at least one of R₂₀₁, R₂₀₂, or R₂₀₃ of a cation represented by General Formula (ZIA) and at least one of R₂₀₁, R₂₀₂, or R₂₀₃ of another cation represented by General Formula (ZIA) are bonded through a single bond or a linking group.

First, the cation (ZI-11) will be described.

The cation (ZI-11) is a cation, that is, an arylsulfonium cation in which at least one of R₂₀₁, . . . , or R₂₀₃ of General Formula (ZIA) is an aryl group.

In the arylsulfonium cation, all of R₂₀₁ to R₂₀₃ may be aryl groups, or some of R₂₀₁ to R₂₀₃ may be an aryl group, and the rest may be an alkyl group or a cycloalkyl group.

Examples of the arylsulfonium cation include a triarylsulfonium cation, a diarylalkylsulfonium cation, an aryldialkylsulfonium cation, a diarylcycloalkylsulfonium cation, and an aryldicycloalkylsulfonium cation.

As the aryl group included in the arylsulfonium cation, a phenyl group or a naphthyl group is preferable, and the phenyl group is more preferable. The aryl group may be an aryl group which has a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium cation has two or more aryl groups, the two or more aryl groups may be the same as or different from each other.

The alkyl group or the cycloalkyl group contained in the arylsulfonium cation, as necessary, is preferably a linear alkyl group having 1 to 15 carbon atoms, a branched alkyl group having 3 to 15 carbon atoms, or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group of each of R₂₀₁ to R₂₀₃ may each independently have an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, a lactone ring group, or a phenylthio group as a substituent.

Examples of the lactone ring group include groups obtained by removing a hydrogen atom from a structure represented by any of (KA-1-1) to (KA-1-17) which will be described later.

Next, the cation (ZI-12) will be described.

The cation (ZI-12) is a compound in which R₂₀₁ to R₂₀₃ in Formula (ZIA) each independently represent an organic group having no aromatic ring. Here, the aromatic ring also includes an aromatic ring including a heteroatom.

The organic group having no aromatic ring as each of R₂₀₁ to R₂₀₃ generally has 1 to 30 carbon atoms, and preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably the linear or branched 2-oxoalkyl group.

Preferred examples of the alkyl group and the cycloalkyl group of each of R₂₀₁ to R₂₀₃ include a linear alkyl group having 1 to 10 carbon atoms or branched alkyl group having 3 to 10 carbon atoms (for example, a methyl group, an ethyl group, a propyl group, a butyl group, and a pentyl group), and a cycloalkyl group having 3 to 10 carbon atoms (for example, a cyclopentyl group, a cyclohexyl group, and a norbornyl group).

R₂₀₁ to R₂₀₃ may be further substituted with a halogen atom, an alkoxy group (for example, having 1 to 5 carbon atoms), a hydroxyl group, a cyano group, or a nitro group.

Next, the cation (ZI-13) will be described.

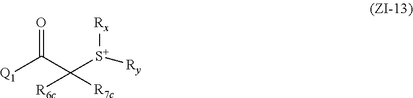

In General Formula (ZI-13), Q₁ represents an alkyl group, a cycloalkyl group, or an aryl group, and in a case where M has a ring structure, the ring structure may include at least one of an oxygen atom, a sulfur atom, an ester bond, an amide bond, or a carbon-carbon double bond. R_{6c} and R_{7c} each independently represent a hydrogen atom, an alkyl group, a cycloalkyl group, a halogen atom, a cyano group, or an aryl group. R_{6c} and R_{7c} may be bonded to each other to form a ring. Rₓ and R_{y} each independently represent an alkyl group, a cycloalkyl group, or an alkenyl group. Rₓ and R_{y} may be bonded to each other to form a ring. In addition, at least two selected from Q₁, R_{6c}, or R_{7c} may be bonded to each other to form a ring structure, and the ring structure may include a carbon-carbon double bond.

In General Formula (ZI-13), as the alkyl group and the cycloalkyl group represented by Q₁, a linear alkyl group having 1 to 15 carbon atoms (preferably having 1 to 10 carbon atoms), a branched alkyl group having 3 to 15 carbon atoms (preferably having 3 to 10 carbon atoms), or a cycloalkyl group having 3 to 15 carbon atoms (preferably having 1 to 10 carbon atoms) is preferable, and specific examples thereof include a methyl group, an ethyl group, a propyl group, an n-butyl group, a sec-butyl group, a t-butyl group, a cyclopropyl group, a cyclobutyl group, a cyclohexyl group, and a norbornyl group.

The aryl group represented by Q₁ is preferably a phenyl group or a naphthyl group, and more preferably the phenyl group. The aryl group may be an aryl group which has a heterocyclic structure having an oxygen atom, a sulfur atom, or the like. Examples of the heterocyclic structure include a furan ring, a thiophene ring, a benzofuran ring, and a benzothiophene ring.

Q₁ may further have a substituent. In this aspect, examples of Q₁ include a benzyl group.

In addition, in a case where Q₁ has a ring structure, the ring structure may include at least one of an oxygen atom, a sulfur atom, an ester bond, an amide bond, or a carbon-carbon double bond.

Examples of the alkyl group, the cycloalkyl group, and the aryl group represented by each of R_{6c} and R_{7c} include the same groups as those of Q₁ as mentioned above, and preferred aspects thereof are also the same. In addition, R_{6c} and R_{7c} may be bonded to each other to form a ring.

Examples of the halogen atom represented by each of R_{6c} and R_{7c} include a fluorine atom, a chlorine atom, a bromine atom, and an iodine atom.

Examples of the alkyl group and the cycloalkyl group represented by each of Rₓ and R_{y} include the same groups as those of Q₁ as mentioned above, and preferred aspects thereof are also the same.

As the alkenyl group represented by each of Rₓ and R_{y}, an allyl group or a vinyl group is preferable.

Rₓ and R_{y} may further have a substituent. In this aspect, examples of each of Rₓ and R_{y} include a 2-oxoalkyl group or an alkoxycarbonylalkyl group.

Examples of the 2-oxoalkyl group represented by each of Rₓ and R_{y} include those having 1 to 15 carbon atoms (preferably having 1 to 10 carbon atoms), and specifically a 2-oxopropyl group and a 2-oxobutyl group.

Examples of the alkoxycarbonylalkyl group represented by each of Rₓ and R_{y} include those having 1 to 15 carbon atoms (preferably having 1 to 10 carbon atoms). In addition. Rₓ and R_{y} may be bonded to each other to form a ring.

The ring structure formed by the mutual linkage of Rₓ and R_{y} may include an oxygen atom, a sulfur atom, an ester bond, an amide bond, or a carbon-carbon double bond.

In General Formula (ZI-13), Q₁ and R_{6c} may be bonded to each other to form a ring structure, and the ring structure formed may include a carbon-carbon double bond.

Among those, the cation (ZI-13) is preferably a cation (ZI-13A).

The cation (ZI-13A) is a phenacylsulfonium cation represented by General Formula (ZI-13A).

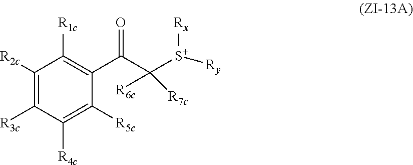

In General Formula (ZI-13A),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} have the same definitions as R_{6c} and R_{7c} in General Formula (ZI-13) as mentioned above, respectively, and preferred aspects thereof are also the same.

Rₓ and R_{y} have the same definitions as Rₓ and R_{y} respectively, in General Formula (ZI-13) described above, and preferred aspects thereof are also the same.

Any two or more of R_{1c}, . . . , or R_{5c}, and Rₓ and R_{y} may be bonded to each other to form a ring structure, and the ring structure may each independently include an oxygen atom, a sulfur atom, an ester bond, an amide bond, or a carbon-carbon double bond. Furthermore, R_{5c} and R_{6c}, or R_{5c} and Rₓ may be bonded to each other to form a ring structure, and the ring structure may each independently include a carbon-carbon double bond. In addition, R_{6c} and R_{7c} may be bonded to each other to form a ring structure.

Examples of the ring structure include an aromatic or non-aromatic hydrocarbon ring, an aromatic or non-aromatic heterocyclic ring, and a polycyclic fused ring in which two or more of these rings are combined. Examples of the ring structure include a 3- to 10-membered ring and the ring structure is preferably a 4- to 8-membered ring, and more preferably a 5- or 6-membered ring.

Examples of the group formed by the bonding of any two or more of R_{1c}, . . . , or R_{5c}, R_{6c} and R_{7c}, and Rₓ and R_{y} include a butylene group and a pentylene group.

As the group formed by the bonding of R_{5c} and R_{6c}, and R_{5c} and Rₓ, a single bond or an alkylene group is preferable. Examples of the alkylene group include a methylene group and an ethylene group.

Next, the cation (ZI-14) will be described.

The cation (ZI-14) is represented by General Formula (ZI-14).

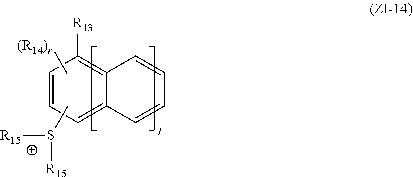

In General Formula (ZI-14),

l represents an integer of 0 to 2.

r represents an integer of 0 to 8.

R₁₃ represents a hydrogen atom, a fluorine atom, a hydroxyl group, an alkyl group, a cycloalkyl group, an alkoxy group, an alkoxycarbonyl group, or a group having a monocyclic or polycyclic cycloalkyl skeleton. These groups may have a substituent.

In a case where a plurality of R₁₄'s are present. R₁₄'s each independently represent an alkyl group, a cycloalkyl group, an alkoxy group, an alkylsulfonyl group, a cycloalkylsulfonyl group, an alkylcarbonyl group, an alkoxycarbonyl group, or an alkoxy group having a monocyclic or polycyclic cycloalkyl skeleton. These groups may have a substituent.

R₁₅'s each independently represent an alkyl group, a cycloalkyl group, or a naphthyl group. These groups may have a substituent. Two R₁₅'s may be bonded to each other to form a ring. In a case where two R₁₅'s are bonded to each other to form a ring, the ring skeleton may include a heteroatom such as an oxygen atom and a nitrogen atom. In one aspect, it is preferable that two R₁₅'s are alkylene groups and are bonded to each other to form a ring structure.

In General Formula (ZI-14), the alkyl group of each of R₁₃, R₁₄, and R₁₅ is linear or branched. The alkyl group preferably has 1 to 10 carbon atoms. As the alkyl group, a methyl group, an ethyl group, an n-butyl group, a t-butyl group, or the like is more preferable.

Next, General Formula (ZIIA) will be described.

In General Formula (ZIIA), R₂₀₄ and R₂₀₅ each independently represent an aryl group, an alkyl group, or a cycloalkyl group.

The aryl group of each of R₂₀₄ and R₂₀₅ is preferably a phenyl group or a naphthyl group, and more preferably the phenyl group. The aryl group of each of R₂₀₄ and R₂₀₅ may be an aryl group which has a heterocyclic structure having an oxygen atom, a nitrogen atom, a sulfur atom, or the like. Examples of the skeleton of the aryl group having a heterocyclic structure include pyrrole, furan, thiophene, indole, benzofuran, and benzothiophene.

As the alkyl group and the cycloalkyl group of each of R₂₀₄ and R₂₀₅, a linear alkyl group having 1 to 10 carbon atoms or branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, and a norbornyl group) is preferable.

The aryl group, the alkyl group, and the cycloalkyl group of each of R₂₀₄ and R₂₀₅ may each independently have a substituent. Examples of the substituent which may be contained in the aryl group, the alkyl group, or the cycloalkyl group of each of R₂₀₄ to R₂₀₇ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, a lactone ring group, and a phenylthio group.

Examples of the lactone ring group include groups obtained by removing a hydrogen atom from a structure represented by any of (KA-1-1) to (KA-1-17).

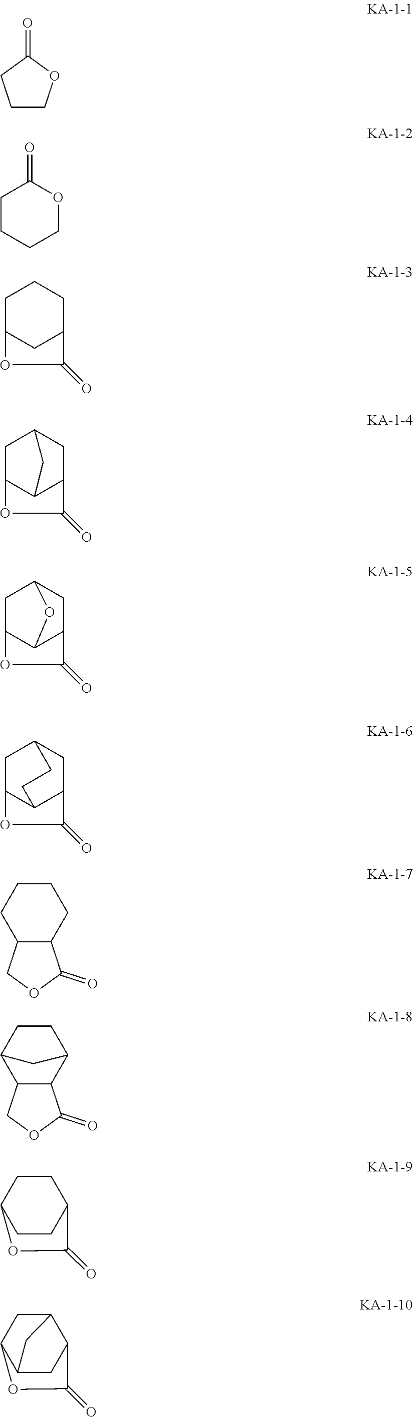

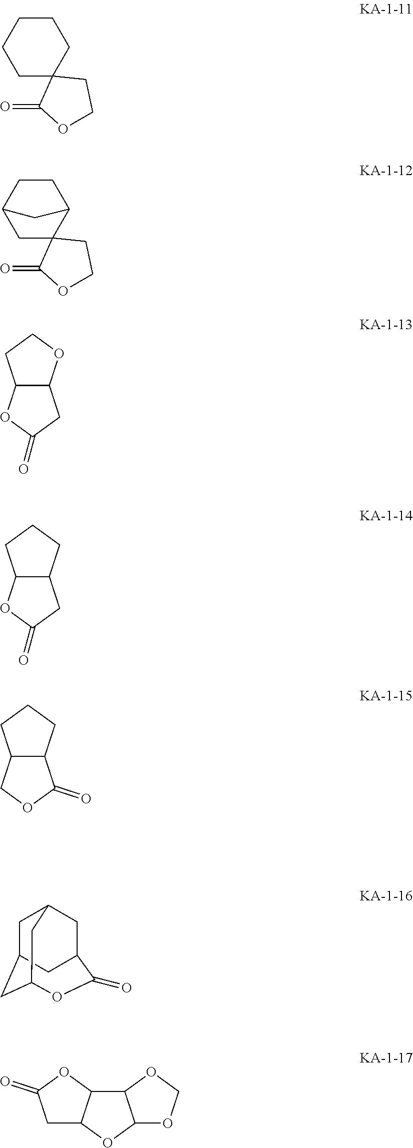

The structure containing the lactone ring structure may or may not have a substituent. Examples of the substituent include the substituent T.

Preferred examples of M⁺ are shown below, but the present invention is not limited thereto. Me represents a methyl group and Bu represents an n-butyl group.

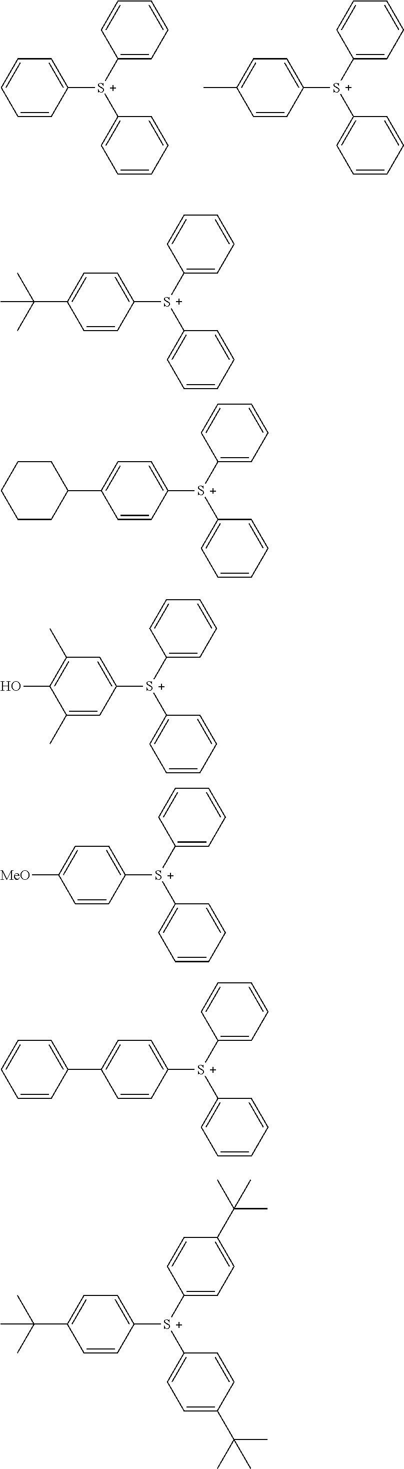

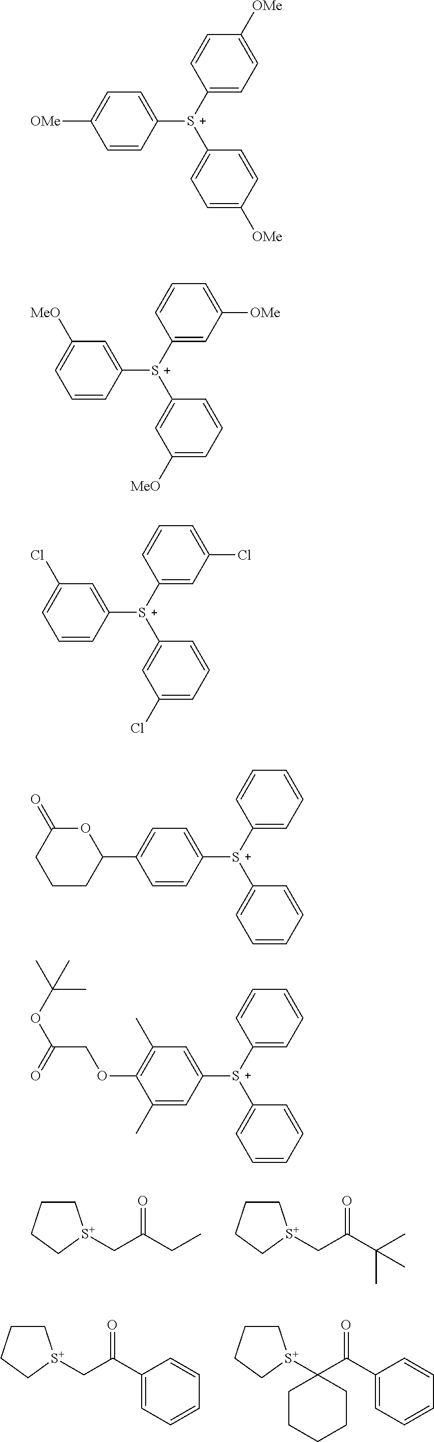

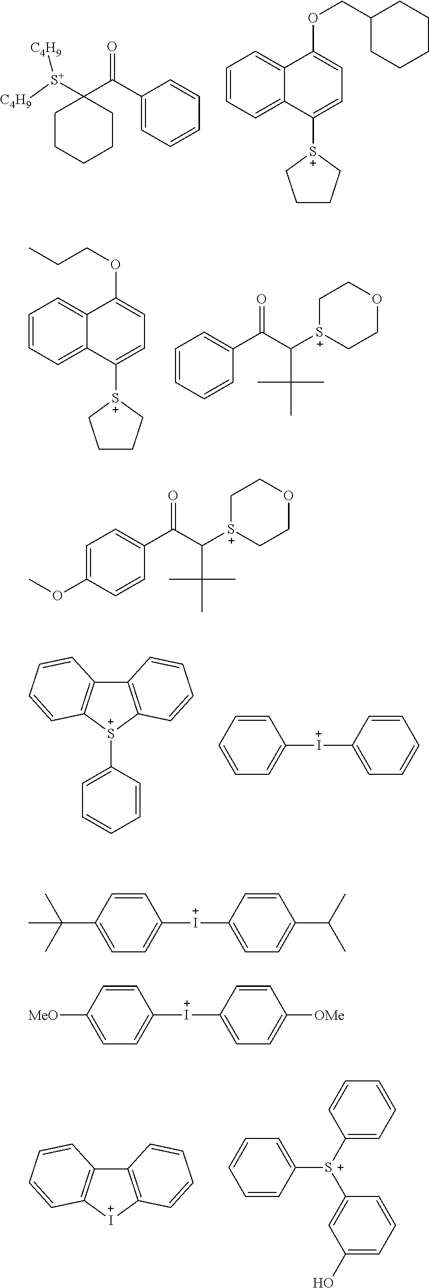

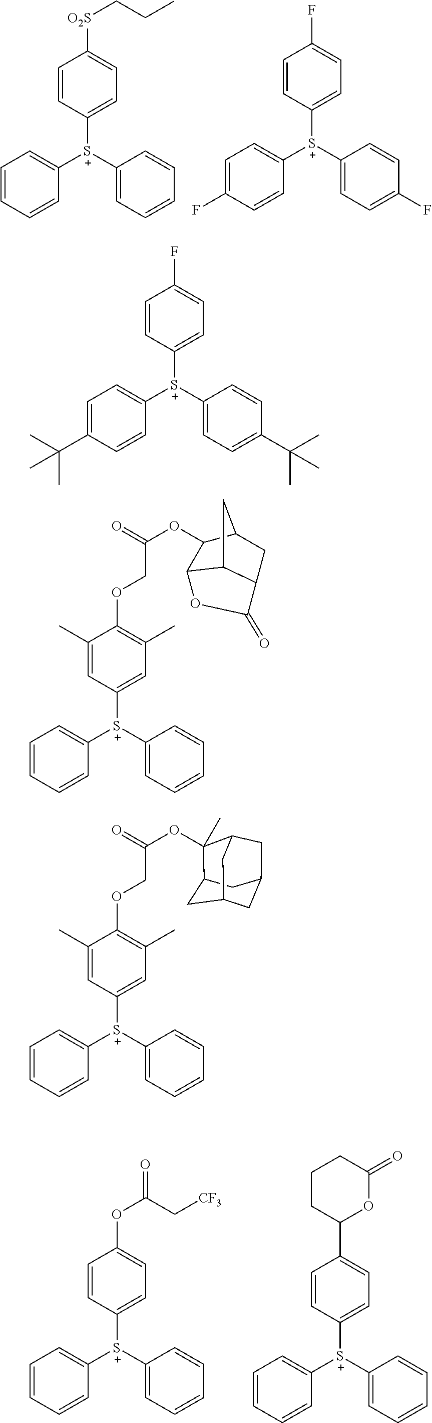

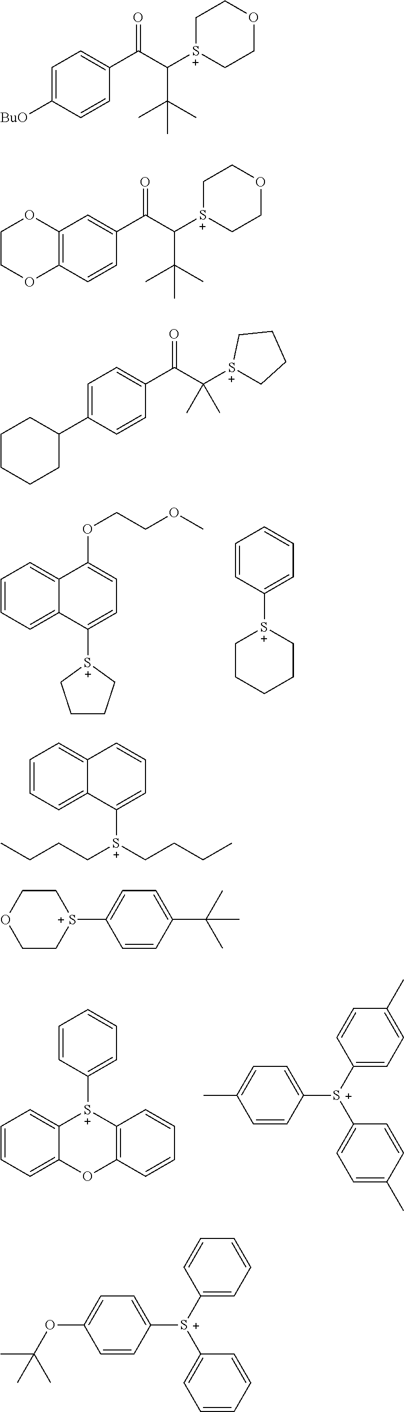

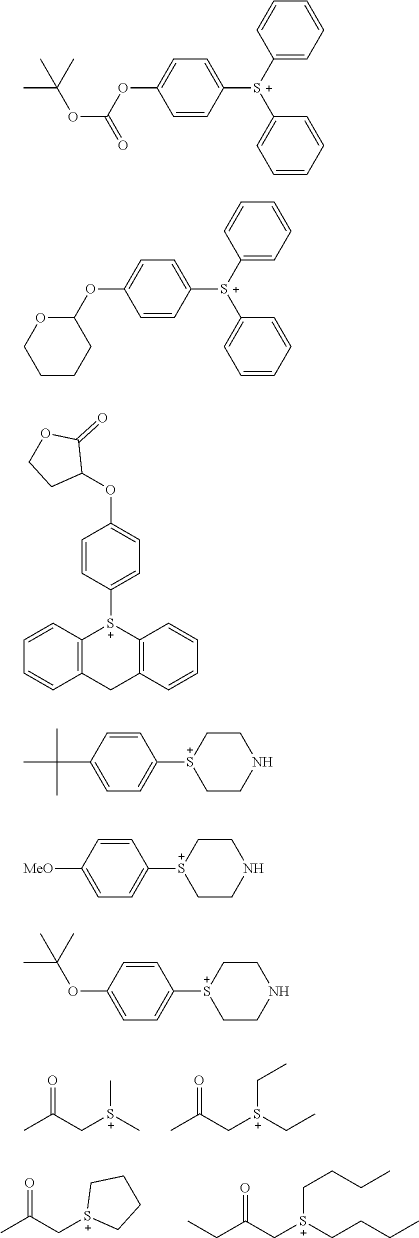

The compound (B) is preferably represented by General Formula (b2).

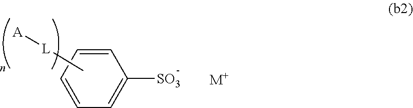

In General Formula (b2), L represents a single bond or a divalent linking group. In a case where there are a plurality of L's, the plurality of L's may be the same as or different from each other. A represents a group that decomposes by the action of an acid. In a case where there are a plurality of A's, the plurality of A's may be the same as or different from each other. n represents an integer from 1 to 5. M⁺ represents a sulfonium ion or an iodonium ion.

L, A, n, and M⁺ in General Formula (b2) are the same as L, A, n, and M⁺ in General Formula (b1) described above, respectively.

The compound (B) is particularly preferably represented by General Formula (b3).

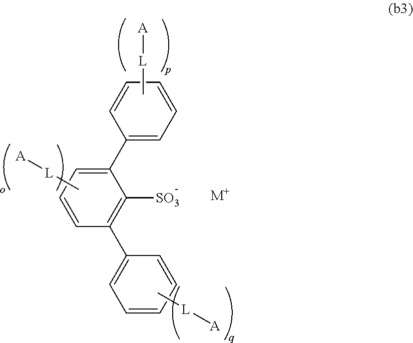

In General Formula (b3), L represents a single bond or a divalent linking group. In a case where there are a plurality of L's, the plurality of L's may be the same as or different from each other. A represents a group that decomposes by the action of an acid. In a case where there are a plurality of A's, the plurality of A's may be the same as or different from each other. o, p, and q each independently represent an integer from 0 to 5. It should be noted that a sum of o, p, and q is from 1 to 5. M⁺ represents a sulfonium ion or an iodonium ion.

L, A, and M⁺ in General Formula (b3) are the same as L, A, and M⁺ in General Formula (b1) described above, respectively.

o, p, and q in General Formula (b3) each independently preferably represent an integer of 0 to 3, more preferably represent an integer of 0 to 2, and still more preferably represent 0 or 1.

Preferred specific examples of the anionic moiety of the compound (B) are shown below, but the present invention is not limited thereto. Me represents a methyl group, and Et represents an ethyl group.

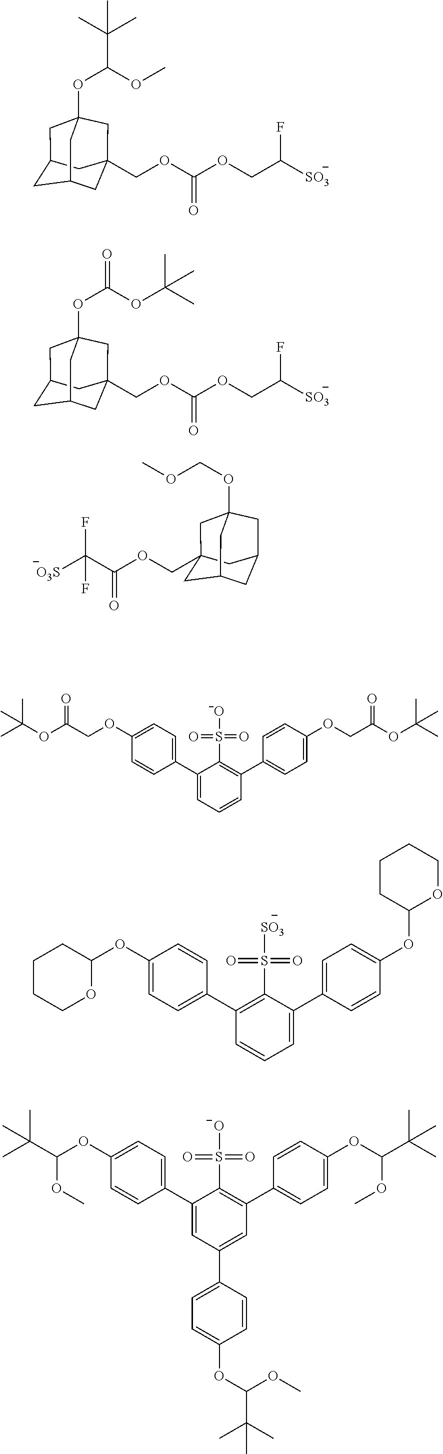

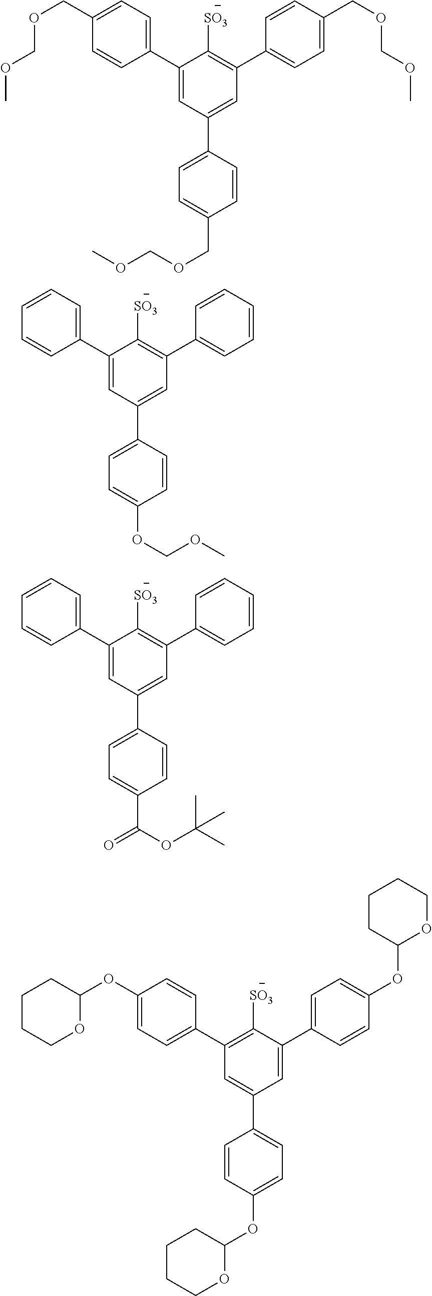

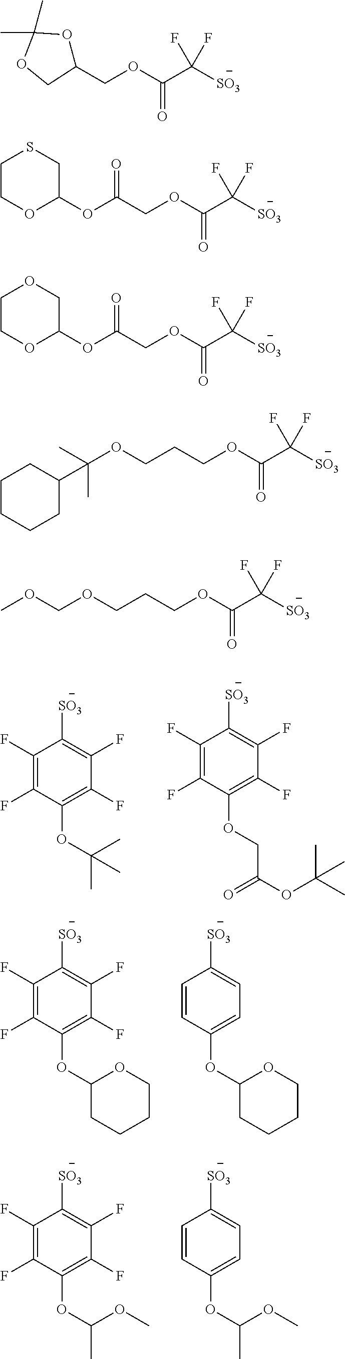

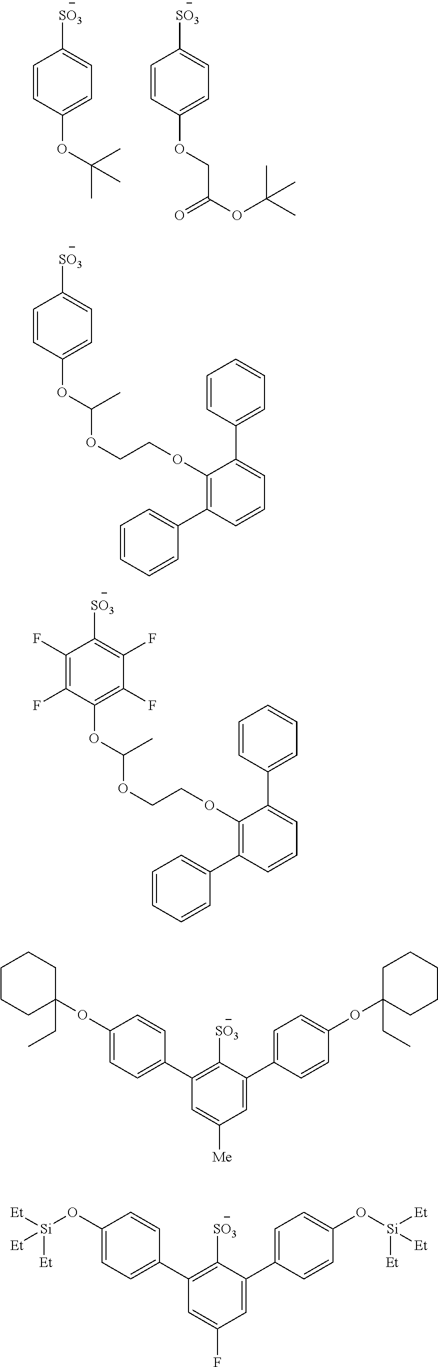

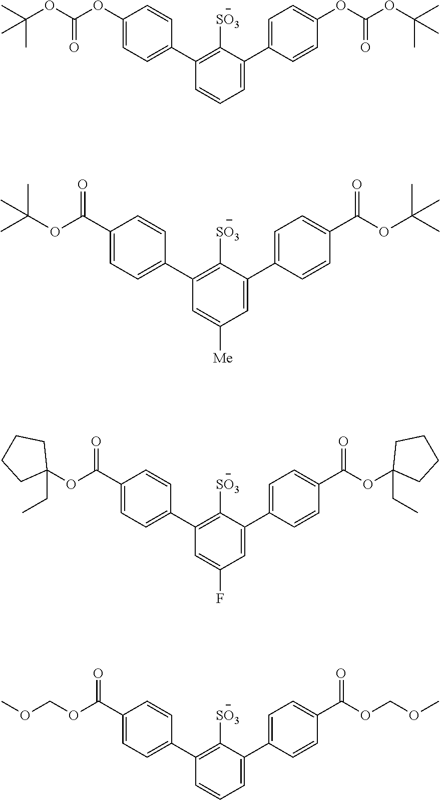

It is preferable that the pKa of an acid generated by the compound (B) is from −10 to 5.

Preferred examples of the compound (B) include those shown in Examples and a compound obtained by combination of the anion and the cation.

<Compound Represented by General Formula (I)>

As a preferred aspect of the compound (B), aspects other than those described above are described below.

The compound (B) is also preferably a compound represented by General Formula (I).

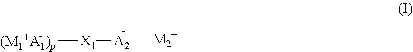

In General Formula (I),

M₁⁺ and M₂⁺ each independently represent a cation.

A₁⁻ and A₂⁻ each independently represent an anionic group. It should be noted that A₁⁻ and A₂⁻ have different structures.

p represents 1 or 2.

X₁ represents a single bond or a (p+1)-valent linking group.

In a case where p represents 2, a plurality of M₁⁺'s may be the same as or different from each other. In a case where p represents 2, a plurality of A₁⁻'s may be the same as or different from each other.

X₁ in General Formula (I) represents a single bond or a (p+1)-valent linking group.

In General Formula (I), the divalent linking group represented by X₁ in a case where p is 1 is not particularly limited, and examples thereof include —NR—, —CO—, —O—, an alkylene group (which preferably has 1 to 8 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of a nitrogen atom, an oxygen atom, a sulfur atom, or a selenium atom in the ring structure), a divalent aromatic heterocyclic group (preferably having a 5- to 10-membered ring, more preferably having a 5- to 7-membered ring, and still more preferably having a 5- or 6-membered ring, each having at least one of a nitrogen atom, an oxygen atom, a sulfur atom, or a selenium atom in the ring structure), a divalent aromatic hydrocarbon ring group (preferably having a 6- to 10-membered ring, and more preferably having a 6-membered ring), and a group formed by combination of a plurality of these groups. R represents a hydrogen atom or a monovalent organic group, and the monovalent organic group is not particularly limited, but is preferably, for example, an alkyl group (preferably having 1 to 6 carbon atoms).

The divalent linking group may further include a group selected from the group consisting of —S—, —SO—, and —SO₂—.

In addition, the alkylene group, the cycloalkylene group, the alkenylene group, the divalent aliphatic heterocyclic group, the divalent aromatic heterocyclic group, and the divalent aromatic hydrocarbon ring group may each have a substituent. The substituent is not particularly limited, and examples thereof include the above-mentioned substituent T.

Suitable specific examples of the trivalent linking group represented by X₁ in a case where p is 2 include groups formed by removing any one hydrogen atom from the specific examples of the divalent linking group.

In General Formula (I), M₁⁺ and M₂⁺ each independently represent a cation.

In a case where p represents 1, M₁⁺ and M₂⁺ may be bonded through a single bond or a linking group to form a divalent cation.

In addition, in a case where p represents 2, at least two of the two cations, M₁⁺ and M₂⁺, may be bonded through a single bond or a linking group to form a divalent or trivalent cation.

The cation represented by each of M₁⁺ and M₂⁺ is not particularly limited, but is preferably a sulfonium ion or an iodonium ion. Specific examples and the preferred ranges of M₁⁺ and M₂⁺ in General Formula (I) are the same as the specific examples and the preferred ranges of M⁺ in General Formula (b1) as described earlier.

The anionic group represented by each of A₁⁻ and A₂⁻ is not particularly limited, but examples thereof each independently include a group selected from the group consisting of groups represented by Formulae (B-1) to (B-37). Furthermore, the compound represented by General Formula (I) is an ionic compound including a cation consisting of M₂⁺ and p pieces of M₁⁺'s, and an anion in which A₂⁻ and p pieces of A₁⁻'s are bonded to X₁.

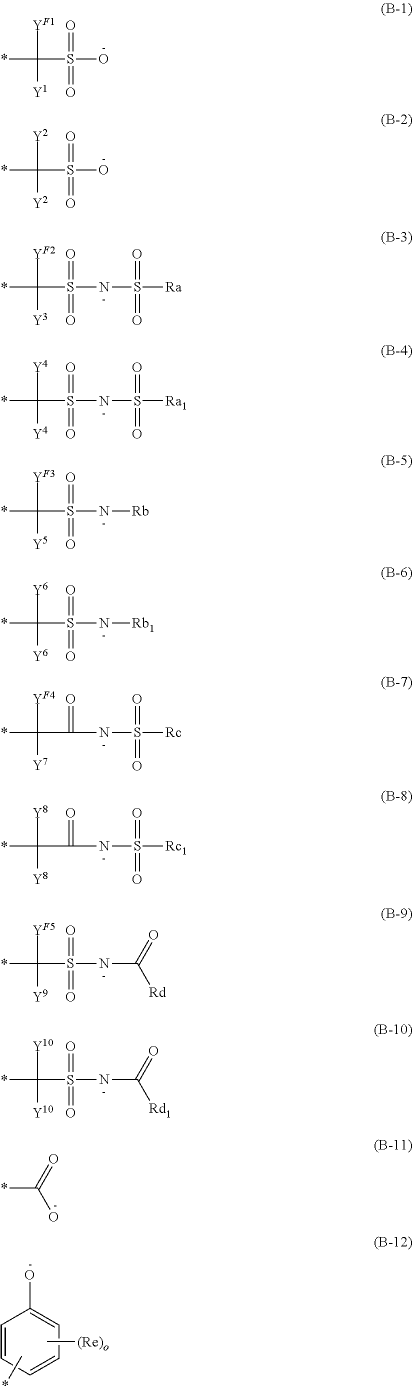

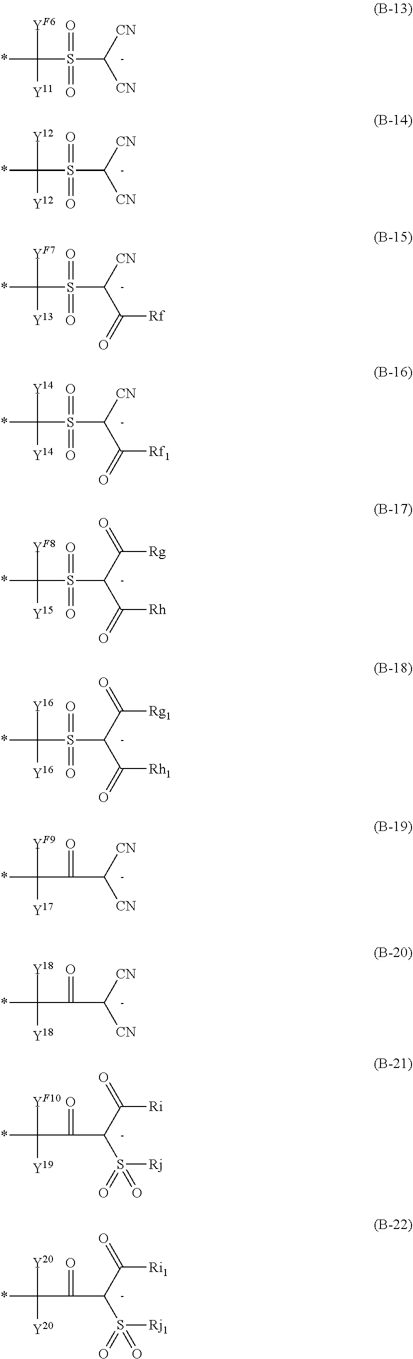

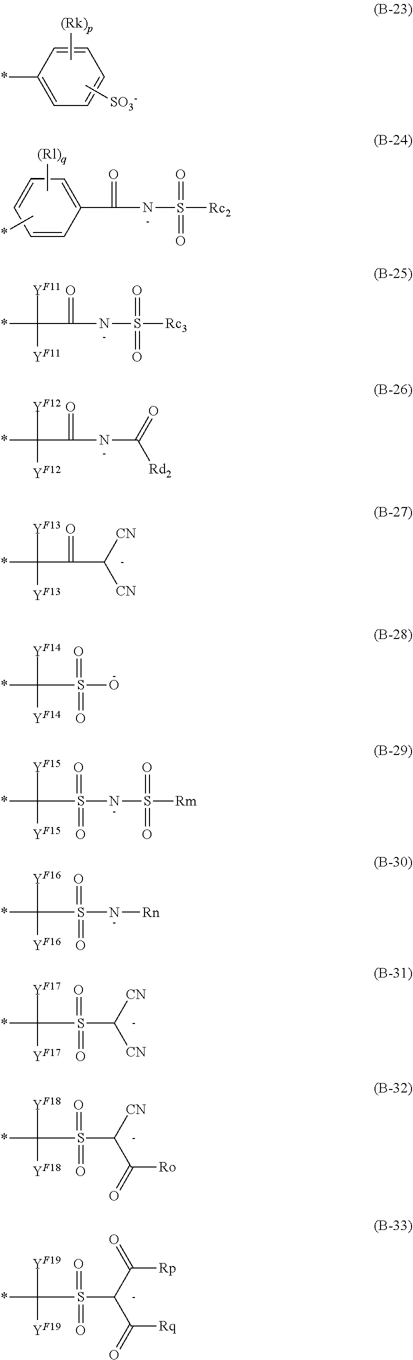

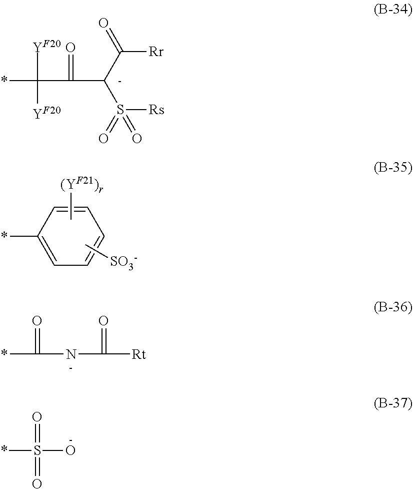

In Formula (B-1), Y^{F1} represents a fluorine atom or a perfluoroalkyl group. Y₁ represents a hydrogen atom or a substituent having no fluorine atom.

In Formula (B-2), Y²'s each independently represent a hydrogen atom or a substituent having no fluorine atom.

In Formula (B-3), Y^{F2} represents a fluorine atom or a perfluoroalkyl group. Y³ represents a hydrogen atom or a substituent having no fluorine atom. Ra represents an organic group,

In Formula (B-4), Y⁴'s each independently represent a hydrogen atom or a substituent having no fluorine atom. Rai represents an organic group.

In Formula (B-5), Y^{F3} represents a fluorine atom or a perfluoroalkyl group. Y⁵ represents a hydrogen atom or a substituent having no fluorine atom. Rb represents a hydrogen atom or an organic group.

In Formula (B-6), Y⁶'s each independently represent a hydrogen atom or a substituent having no fluorine atom. Rb₁ represents a hydrogen atom or an organic group.

In Formula (B-7), Y^{F4} represents a fluorine atom or a perfluoroalkyl group. Y⁷ represents a hydrogen atom or a substituent having no fluorine atom. Rc represents an organic group.

In Formula (B-8), Y⁸'s each independently represent a hydrogen atom or a substituent having no fluorine atom. Rc₁ represents an organic group.

In Formula (B-9), Y^{F5} represents a fluorine atom or a perfluoroalkyl group. Y⁹ represents a hydrogen atom or a substituent having no fluorine atom. Rd represents an organic group.

In Formula (B-10), Y¹⁰'s each independently represent a hydrogen atom or a substituent having no fluorine atom. Rd₁ represents an organic group.

In Formula (B-12). Re represents an organic group, or a halogen atom. o represents an integer of 1 to 4. In a case where a plurality of Re's are present, Re's may be the same as or different from each other.

In Formula (B-13), Y^{F6} represents a fluorine atom or a perfluoroalkyl group. Y¹¹ represents a hydrogen atom or a substituent having no fluorine atom.

In Formula (B-14), Y¹²'s each independently represent a hydrogen atom or a substituent having no fluorine atom.

In Formula (B-15), Y^{F7} represents a fluorine atom or a perfluoroalkyl group. Y¹³ represents a hydrogen atom or a substituent having no fluorine atom. Rf represents an organic group.

In Formula (B-16), Y¹⁴'s each independently represent a hydrogen atom or a substituent having no fluorine atom. Rf₁ represents an organic group.

In Formula (B-17), Y^{F8} represents a fluorine atom or a perfluoroalkyl group. Y¹⁵ represents a hydrogen atom or a substituent having no fluorine atom. Rg represents an organic group. Rh represents an organic group.

In Formula (B-18), Y¹⁶'s each independently represent a hydrogen atom or a substituent having no fluorine atom. Rg₁ represents an organic group. Rh₁ represents an organic group.

In Formula (B-19), Y^{F9} represents a fluorine atom or a perfluoroalkyl group. Y¹⁷ represents a hydrogen atom or a substituent having no fluorine atom.

In Formula (B-20), Y¹⁸'s each independently represent a hydrogen atom or a substituent having no fluorine atom.

In Formula (B-21), Y^{F10} represents a fluorine atom or a perfluoroalkyl group. Y¹⁹ represents a hydrogen atom or a substituent having no fluorine atom. Ri represents an organic group. Rj represents an organic group.

In Formula (B-22), Y²⁰'s each independently represent a hydrogen atom or a substituent having no fluorine atom. Ri₁ represents an organic group. Rj₁ represents an organic group.

In Formula (B-23), Rk represents a substituent having no fluorine atom. p represents an integer of 1 to 4. In a case where a plurality of Rk's are present, Rk's may be the same as or different from each other.

In Formula (B-24), Rl represents an organic group, or a halogen atom. q represents an integer of 1 to 4, Rc₂ represents an organic group. In a case where a plurality of Rl's are present, Rl's may be the same as or different from each other.

In Formula (B-25), Y^{F11}'s each independently represent a fluorine atom or a perfluoroalkyl group. Rc₃ represents an organic group.

In Formula (B-26), Y^{F12}'s each independently represent a fluorine atom or a perfluoroalkyl group. Rd₂ represents an organic group.

In Formula (B-27), Y^{F13}'s each independently represent a fluorine atom or a perfluoroalkyl group.

In Formula (B-28), Y^{F14}'s each independently represent a fluorine atom or a perfluoroalkyl group.

In Formula (B-29), Y^{F15}'s each independently represent a fluorine atom or a perfluoroalkyl group. Rm represents an organic group.

In Formula (B-30), Y^{F16}'s each independently represent a fluorine atom or a perfluoroalkyl group. Rn represents a hydrogen atom or an organic group.

In Formula (B-31), Y^{F17}'s each independently represent a fluorine atom or a perfluoroalkyl group.

In Formula (B-32), Y^{F18}'s each independently represent a fluorine atom or a perfluoroalkyl group. Ro represents an organic group.

In Formula (B-33), Y^{F19}'s each independently represent a fluorine atom or a perfluoroalkyl group. Rp represents an organic group. Rq represents an organic group.

In Formula (B-34), Y^{F20}'s each independently represent a fluorine atom or a perfluoroalkyl group. Rr represents an organic group. Rs represents an organic group.

In Formula (B-35), Y^{F21} represents a fluorine atom or a perfluoroalkyl group. r represents an integer of 1 to 4.

In Formula (B-36). Rt represents an organic group.

In Formulae (B-1) to (B-37), * represents a bonding position.

In Formula (B-1), The perfluoroalkyl group represented by Y^{F1} preferably has 1 to 15 carbon atoms, more preferably has 1 to 10 carbon atoms, and still more preferably has 1 to 6 carbon atoms.

The substituent having no fluorine atom represented by Y¹ is not particularly limited as long as it is a substituent having no fluorine atom, but is preferably an organic group having no fluorine atom, and for example, an alkyl group having no fluorine atom, or a cycloalkyl group having no fluorine atom is preferable.

The alkyl group may be linear or branched, and is not particularly limited, but is preferably an alkyl group having 1 to 15 carbon atoms, and more preferably an alkyl group having 1 to 10 carbon atoms.

The cycloalkyl group may be monocyclic or polycyclic, and is not particularly limited, but is preferably a cycloalkyl group having 3 to 15 carbon atoms, and more preferably a cycloalkyl group having 3 to 10 carbon atoms.

The alkyl group and the cycloalkyl group may have a substituent other than a fluorine atom. The substituent is not particularly limited, and examples thereof include the substituent T (provided that a fluorine atom is excluded).

In Formula (B-2), the substituent having no fluorine atom represented by Y² has the same definition as the substituent having no fluorine atom represented by Y¹ in Formula (B-1), and a suitable aspect thereof is also the same.

In Formula (B-3), the perfluoroalkyl group represented by Y^{F2} has the same definition as the perfluoroalkyl group represented by Y^{F1} in Formula (B-1), and a suitable aspect thereof is also the same.

The substituent having no fluorine atom represented by Y³ has the same definition as the substituent having no fluorine atom represented by Y¹ in Formula (B-1), and a suitable aspect thereof is also the same.

The organic group represented by Ra is not particularly limited, and examples thereof include an organic group having 1 to 30 carbon atoms. The organic group is not particularly limited, and preferred examples thereof include an alkyl group, a cycloalkyl group, or an aryl group.

The alkyl group may be linear or branched, and is not particularly limited, but is preferably an alkyl group having 1 to 15 carbon atoms, and more preferably an alkyl group having 1 to 10 carbon atoms.

The cycloalkyl group may be monocyclic or polycyclic, and is not particularly limited, but is preferably a cycloalkyl group having 3 to 15 carbon atoms, and more preferably a cycloalkyl group having 3 to 10 carbon atoms.

The aryl group is not particularly limited, but is preferably an aryl group having 6 to 20 carbon atoms, and more preferably an aryl group having 6 to 10 carbon atoms.

The alkyl group, the cycloalkyl group, and the aryl group may have a substituent. The substituent is not particularly limited, and examples thereof include the substituent T.

In Formula (B-4), the substituent having no fluorine atom represented by Y⁴ has the same definition as the substituent having no fluorine atom represented by Y¹ in Formula (B-1), and a suitable aspect thereof is also the same.

The organic group represented by Rai has the same definition as the organic group represented by Ra in Formula (B-3) mentioned above, and a suitable aspect thereof is also the same.

In Formula (B-5), the perfluoroalkyl group represented by Y^{F3} has the same definition as the perfluoroalkyl group represented by Y^{F1} in General Formula (B-1), and a suitable aspect thereof is also the same.

The substituent having no fluorine atom represented by Y⁵ has the same definition as the substituent having no fluorine atom represented by Y¹ in Formula (B-1), and a suitable aspect thereof is also the same.

The organic group represented by Rb has the same definition as the organic group represented by Ra in Formula (B-3), and a suitable aspect thereof is also the same.

In Formula (B-6), the substituent having no fluorine atom represented by Y⁶ has the same definition as the substituent having no fluorine atom represented by Y¹ in Formula (B-1), and a suitable aspect thereof is also the same.

The organic group represented by Rb₁ has the same definition as the organic group represented by Ra in Formula (B-3), and a suitable aspect thereof is also the same.

In Formula (B-7), the perfluoroalkyl group represented by Y^{F4} has the same definition as the perfluoroalkyl group represented by Y^{F1} in Formula (B-1), and a suitable aspect thereof is also the same.

The substituent having no fluorine atom represented by Y⁷ has the same definition as the substituent having no fluorine atom represented by Y¹ in Formula (B-1), and a suitable aspect thereof is also the same.

The organic group represented by Rc has the same definition as the organic group represented by Ra in Formula (B-3), and a suitable aspect thereof is also the same.

In Formula (B-8), the substituent having no fluorine atom represented by Y⁸ has the same definition as the substituent having no fluorine atom represented by Y¹ in Formula (B-1), and a suitable aspect thereof is also the same.

The organic group represented by Rc₁ has the same definition as the organic group represented by Ra in Formula (B-3), and a suitable aspect thereof is also the same.

In Formula (B-9), the perfluoroalkyl group represented by Y^{F}s has the same definition as the perfluoroalkyl group represented by Y^{F1} in Formula (B-1), and a suitable aspect thereof is also the same.

The substituent having no fluorine atom represented by Y⁹ has the same definition as the substituent having no fluorine atom represented by Y¹ in Formula (B-1), and a suitable aspect thereof is also the same.

The organic group represented by Rd has the same definition as the organic group represented by Ra in Formula (B-3), and a suitable aspect thereof is also the same.

In Formula (B-10), the substituent having no fluorine atom represented by Y¹⁰ has the same definition as the substituent having no fluorine atom represented by Y¹ in Formula (B-1), and a suitable aspect thereof is also the same.

The organic group represented by Rd₁ has the same definition as the organic group represented by Ra in Formula (B-3), and a suitable aspect thereof is also the same.

In Formula (B-12), the organic group represented by Re has the same definition as the organic group represented by Ra in Formula (B-3), and a suitable aspect thereof is also the same.

Examples of the halogen atom represented by Re include a fluorine atom, a chlorine atom, a bromine atom, or an iodine atom.

In Formula (B-13), the perfluoroalkyl group represented by Y^{F6} has the same definition as the perfluoroalkyl group represented by Y^{F1} in Formula (B-1), and a suitable aspect thereof is also the same.

The substituent having no fluorine atom represented by Y¹¹ has the same definition as the substituent having no fluorine atom represented by Y¹ in Formula (B-1), and a suitable aspect thereof is also the same.

In Formula (B-14), the substituent having no fluorine atom represented by Y¹² has the same definition as the substituent having no fluorine atom represented by Y¹ in Formula (B-1), and a suitable aspect thereof is also the same.

In Formula (B-15), the perfluoroalkyl group represented by Y^{F7} has the same definition as the perfluoroalkyl group represented by Y^{F1} in Formula (B-1), and a suitable aspect thereof is also the same.

The substituent having no fluorine atom represented by Y¹³ has the same definition as the substituent having no fluorine atom represented by Y¹ in Formula (B-1), and a suitable aspect thereof is also the same.

The organic group represented by Rf has the same definition as the organic group represented by Ra in Formula (B-3), and a suitable aspect thereof is also the same.

In Formula (B-16), the substituent having no fluorine atom represented by Y¹⁴ has the same definition as the substituent having no fluorine atom represented by Y¹ in Formula (B-1), and a suitable aspect thereof is also the same.

The organic group represented by Rf₁ has the same definition as the organic group represented by Ra in Formula (B-3), and a suitable aspect thereof is also the same.

In Formula (B-17), the perfluoroalkyl group represented by Y^{F8} has the same definition as the perfluoroalkyl group represented by Y^{F1} in Formula (B-1), and a suitable aspect thereof is also the same.

The substituent having no fluorine atom represented by Y¹⁵ has the same definition as the substituent having no fluorine atom represented by Y¹ in Formula (B-1), and a suitable aspect thereof is also the same.

The organic group represented by each of Rg and Rh has the same definition as the organic group represented by Ra in Formula (B-3), and suitable aspects thereof are also the same.

In Formula (B-18), the substituent having no fluorine atom represented by Y¹⁶ has the same definition as the substituent having no fluorine atom represented by Y¹ in Formula (B-1), and a suitable aspect thereof is also the same.

The organic group represented by each of Rg₁ and Rh₁ has the same definition as the organic group represented by Ra in Formula (B-3), and suitable aspects thereof are also the same.

In Formula (B-19), the perfluoroalkyl group represented by Y^{F9} has the same definition as the perfluoroalkyl group represented by Y^{F1} in Formula (B-1), and a suitable aspect thereof is also the same.

The substituent having no fluorine atom represented by Y¹⁷ has the same definition as the substituent having no fluorine atom represented by Y¹ in Formula (B-1), and a suitable aspect thereof is also the same.

In Formula (B-20), the substituent having no fluorine atom represented by Y¹⁸ has the same definition as the substituent having no fluorine atom represented by Y¹ in Formula (B-1), and a suitable aspect thereof is also the same.

In Formula (B-21), the perfluoroalkyl group represented by Y^{F10} has the same definition as the perfluoroalkyl group represented by Y^{F1} in Formula (B-1), and a suitable aspect thereof is also the same.

The substituent having no fluorine atom represented by Y¹⁹ has the same definition as the substituent having no fluorine atom represented by Y¹ in Formula (B-1), and a suitable aspect thereof is also the same.

The organic group represented by each of Ri and Rj has the same definition as the organic group represented by Ra in Formula (B-3), and a suitable aspect thereof is also the same.

In Formula (B-22), the substituent having no fluorine atom represented by Y²⁰ has the same definition as the substituent having no fluorine atom represented by Y¹ in Formula (B-1), and a suitable aspect thereof is also the same.

The organic group represented by each of Ri₁ and Rj₁ has the same definition as the organic group represented by Ra in Formula (B-3), and a suitable aspect thereof is also the same.

In Formula (B-23), the substituent having no fluorine atom represented by Rk has the same definition as the substituent having no fluorine atom represented by Y¹ in Formula (B-1), and a suitable aspect thereof is also the same.

In Formula (B-24), the organic group represented by Rl has the same definition as the organic group represented by Ra in Formula (B-3), and suitable aspects thereof are also the same.

In addition, as a preferred aspect, the organic group represented by Rl is preferably an organic group having no fluorine atom.

Examples of the halogen atom represented by Rl include a fluorine atom, a chlorine atom, a bromine atom, or an iodine atom.

The organic group represented by Rc₂ has the same definition as the organic group represented by Ra in Formula (B-3), and a suitable aspect thereof is also the same.

In Formula (B-25), the perfluoroalkyl group represented by Y^{F11} has the same definition as the perfluoroalkyl group represented by Y^{F1} in Formula (B-1), and a suitable aspect thereof is also the same.

The organic group represented by Rc₃ has the same definition as the organic group represented by Ra in Formula (B-3), and a suitable aspect thereof is also the same.

In Formula (B-26), the perfluoroalkyl group represented by Y^{F12} has the same definition as the perfluoroalkyl group represented by Y^{F1} in Formula (B-1), and a suitable aspect thereof is also the same.

The organic group represented by Rd₂ has the same definition as the organic group represented by Ra in Formula (B-3), and a suitable aspect thereof is also the same.

In Formula (B-27), the perfluoroalkyl group represented by Y^{F13} has the same definition as the perfluoroalkyl group represented by Y^{F1} in Formula (B-1), and a suitable aspect thereof is also the same.

In Formula (B-28), the perfluoroalkyl group represented by Y^{F14} has the same definition as the perfluoroalkyl group represented by Y^{F1} in Formula (B-1), and a suitable aspect thereof is also the same.

In Formula (B-29), the perfluoroalkyl group represented by Y^{F15} has the same definition as the perfluoroalkyl group represented by Y^{F1} in Formula (B-1), and a suitable aspect thereof is also the same.

The organic group represented by Rm has the same definition as the organic group represented by Ra in Formula (B-3) mentioned above, and a suitable aspect thereof is also the same.

In Formula (B-30), the perfluoroalkyl group represented by Y^{F16} has the same definition as the perfluoroalkyl group represented by Y^{F1} in Formula (B-1), and a suitable aspect thereof is also the same.

The organic group represented by Rn has the same definition as the organic group represented by Ra in Formula (B-3) mentioned above, and a suitable aspect thereof is also the same.

In Formula (B-31), the perfluoroalkyl group represented by Y^{F17} has the same definition as the perfluoroalkyl group represented by Y^{F1} in Formula (B-1), and a suitable aspect thereof is also the same.

In Formula (B-32), the perfluoroalkyl group represented by Y^{F18} has the same definition as the perfluoroalkyl group represented by Y^{F1} in Formula (B-1), and a suitable aspect thereof is also the same.

The organic group represented by Ro has the same definition as the organic group represented by Ra in Formula (B-3) mentioned above, and a suitable aspect thereof is also the same.

In Formula (B-33), the perfluoroalkyl group represented by Y^{F19} has the same definition as the perfluoroalkyl group represented by Y^{F1} in Formula (B-1), and a suitable aspect thereof is also the same.

The organic group represented by each of Rp and Rq has the same definition as the organic group represented by Ra in Formula (B-3), and a suitable aspect thereof is also the same.

In Formula (B-34), the perfluoroalkyl group represented by Y^{F20} has the same definition as the perfluoroalkyl group represented by Y^{F1} in Formula (B-1), and a suitable aspect thereof is also the same.

The organic group represented by each of Rr and Rs has the same definition as the organic group represented by Ra in Formula (B-3), and a suitable aspect thereof is also the same.

In Formula (B-35), the perfluoroalkyl group represented by Y^{F21} has the same definition as the perfluoroalkyl group represented by Y^{F1} in Formula (B-1), and a suitable aspect thereof is also the same.

In Formula (B-36), the organic group represented by Rt has the same definition as the organic group represented by Ra in Formula (B-3), and a suitable aspect thereof is also the same.

As a preferred aspect of a case where the compound (B) is the compound represented by General Formula (I), an aspect in which a compound (PI) in which M₁⁺ and M₂⁺ in General Formula (I) are each substituted with a hydrogen atom has an acid dissociation constant (pKa_{I}) of a group represented by HA1 and an acid dissociation constant (pKa_{II}) of a group represented by A2H, where pKa_{I} is lower than pKa_{II} and pKa_{I} is −1.5 or more may be mentioned (this aspect is hereinafter also referred to as an “aspect (1-1)”).

pKa_{I} and pKa_{II} can be determined by the above-mentioned method.

pKa_{I} and pKa_{II} of the compound PI will be specifically described below.

In a case where p represents 1 in General Formula (I), the pKa with which the compound PI (in which the compound PI is a “compound having HA₁ and HA₂”) serves as a “compound having A₁⁻ and HA₂” is pKa_{I}, and the pKa with which the “compound having A₁⁻ and HA₂” serves as a “compound having A₁⁻ and A₂⁻” is pKa_{II}.

In a case where p represents 2 in General Formula (I), the pKa with which the compound PI (in which the compound PI is a “compound having two (HA₁ and HA₂)'s”) serves as a “compound having one (A₁⁻ and HA₂)” is pKa_{I}, and the pKa with which “compound having two (A₁⁻ and HA₂)'s” serves as a “compound having two (A₁⁻ and A₂⁻)'s” is pKa_{II}. That is, in a case where the compound PI has two pKa's derived from the acidic moiety represented by HA₁, the smallest value is considered as pKa_{I}.

In addition, the compound PI is an acid generated by irradiating a compound represented by General Formula (I) with actinic rays or radiation.

From the viewpoint that the roughness performance of a pattern formed is more excellent, in the compound PI in the aspect (I-1), a difference between pKa_{I} and pKa_{II} (pKa_{II}−pKa_{I}) is preferably 2.0 or more, and more preferably 3.0 or more. Furthermore, the upper limit value of the difference between pKa_{I} and pKa_{II} is not particularly limited, but is, for example, 15.0 or less.

In addition, from the suppression of excessive diffusion of the acid into the unexposed portion is more excellent, in the compound PI in the aspect (I-1), pKa_{II} is, for example, preferably 2.0 or more, more preferably 3.0 or more, and still more preferably 4.0 or more.

In addition, the upper limit value of pKa_{II} is not particularly limited, but is, for example, 10.0 or less, and is preferably 7.0 or less, and more preferably 6.0 or less.

In addition, in the compound PI in the aspect (1-1), pKa_{I} is preferably −1.5 or more, more preferably −1.2 or more, and still more preferably −1.0 or more. Furthermore, the upper limit value of pKa_{I} is not particularly limited, but is, for example, 2.0 or less, and is preferably 1.5 or less.

In a case of the aspect (I-1), in General Formula (I), A₁⁻ is preferably the group represented by Formula (B-1), (B-2), (B-3), (B-4), or (B-23), more preferably the group represented by Formula (B-2) or (B-23), and still more preferably the group represented by (B-2).

In a case of the aspect (1-1), in General Formula (I), A₂⁻ is preferably the group represented by Formula (B-6), (B-8), (B-10), (B-11), (B-12), or (B-24), more preferably the group represented by Formula (B-10), (B-11), (B-12), or (B-24), and still more preferably the group represented by Formula (B-11) or (B-24).

In a case of the aspect (I-1), in General Formula (I), the combination of A₁⁻ and A₂⁻ is more preferably a combination of preferred groups as each of A₁⁻ and A₂⁻.

Other preferred aspects of a case where the compound (B) is the compound represented by General Formula (I) include an aspect in which a compound (PI) in which M₁⁺ and M₂⁺ in General Formula (I) are each substituted with a hydrogen atom has an acid dissociation constant (pKa_{I}) of a group represented by HA₁ and an acid dissociation constant (pKa_{II}) of a group represented by A₂H, where pKa_{I} is lower than pKa_{II}, pKa_{I} is −12.00 to 1.00, and pKa_{II} is −4.00 to 14.00 (this aspect is hereinafter also referred to as an “aspect (I-2)”).

In the compound PI in the aspect (I-2), pKa_{I} is preferably −12.00 to 1.00, more preferably −7.00 to 0.50, and still more preferably −5.00 to 0.00.

In the compound PI in the aspect (I-2), pKa_{II} is preferably −4.00 to 14.00, more preferably −2.00 to 12.00, and still more preferably −1.00 to 5.00.

In the compound PI in the aspect (I-2), a difference (pKa_{II}−pKa_{I}) between pKa_{I} and pKa_{II} is preferably 0.10 to 20.00, more preferably 0.50 to 17.00, and still more preferably 2.00 to 15.00.

In a case of the aspect (I-2), in General Formula (I), A₁⁻ is preferably a group represented by Formulae (B-28) to (B-35), or (B-37), more preferably the group represented by (B-28). (B-29), or (B-37), and still more preferably the group represented by (B-28) or (B-29).

In a case of the aspect (I-2), in General Formula (I), A₂⁻ is preferably the group represented by Formula (B-3), (B-4), (B-7), (B-8), (B-25), (B-26), or (B-36), more preferably the group represented by (B-3), (B-4), (B-7), (B-8), (B-25), or (B-26), and still more preferably the group represented by (B-7), (B-8), (B-25), or (B-26).

In a case of the aspect (I-2), in General Formula (I), the combination of A₁⁻ and A₂⁻ is more preferably a combination of preferred groups as each of A₁⁻ and A₂⁻.

The compound (B) is preferably a compound represented by General Formula (I), preferably the compound having an acid-decomposable group, and more preferably the compound having an acid-decomposable group in the anion in General Formula (I) (the anion represented by General Formula (I-a)). The acid-decomposable group is as described above, and a preferred range thereof is the same as that of A in General Formula (b1) as described earlier.

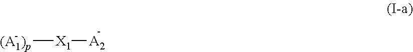

In General Formula (I-a), A₁⁻, A₂⁻, p, and X₁ each represent the same definitions as those in General Formula (I).

Preferred examples of the anion in the compound represented by General Formula (I) (the anion represented by General Formula (I-a)) are shown below, but are not limited thereto. Me represents a methyl group.

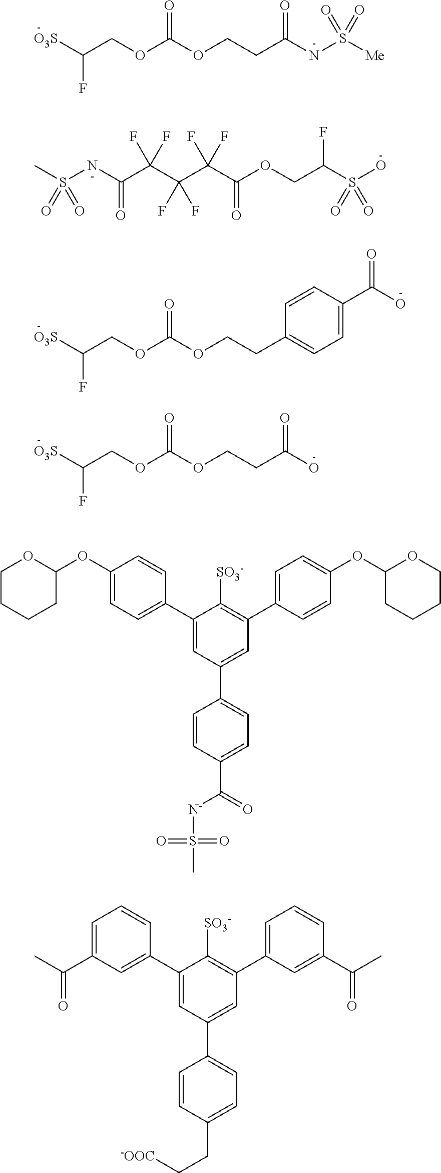

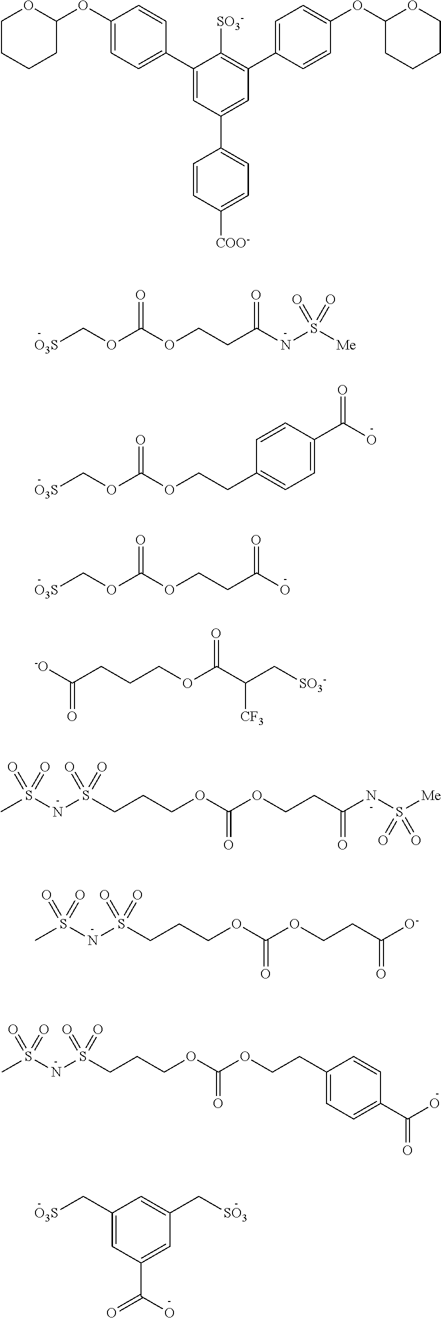

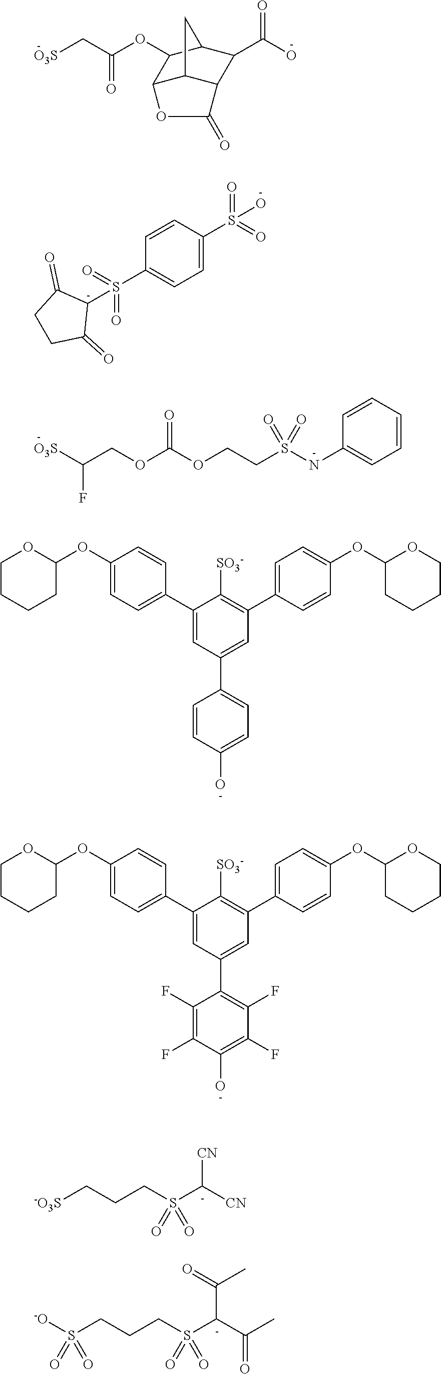

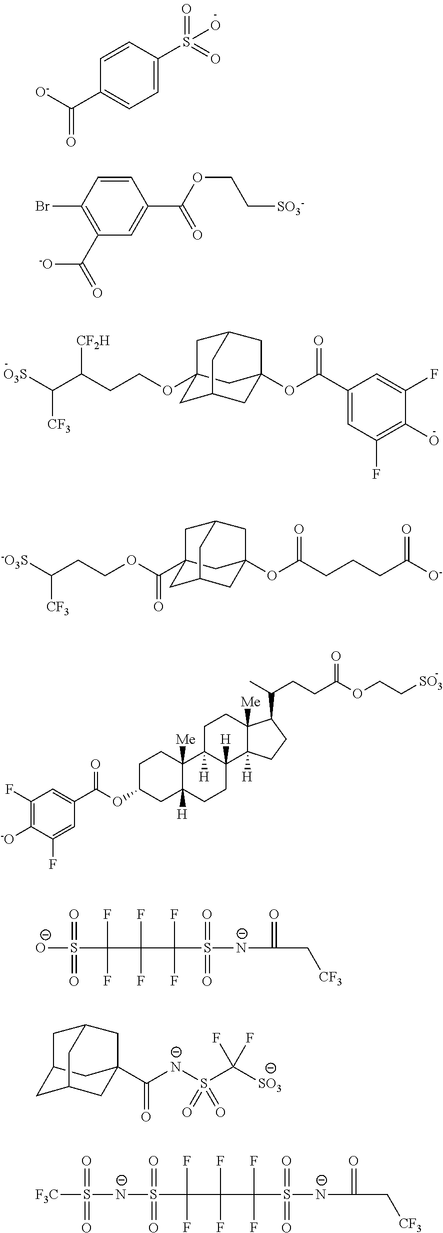

Preferred specific examples of a case where the compound (B) is a compound represented by General Formula (I) are shown below, but are not limited thereto. Me represents a methyl group.

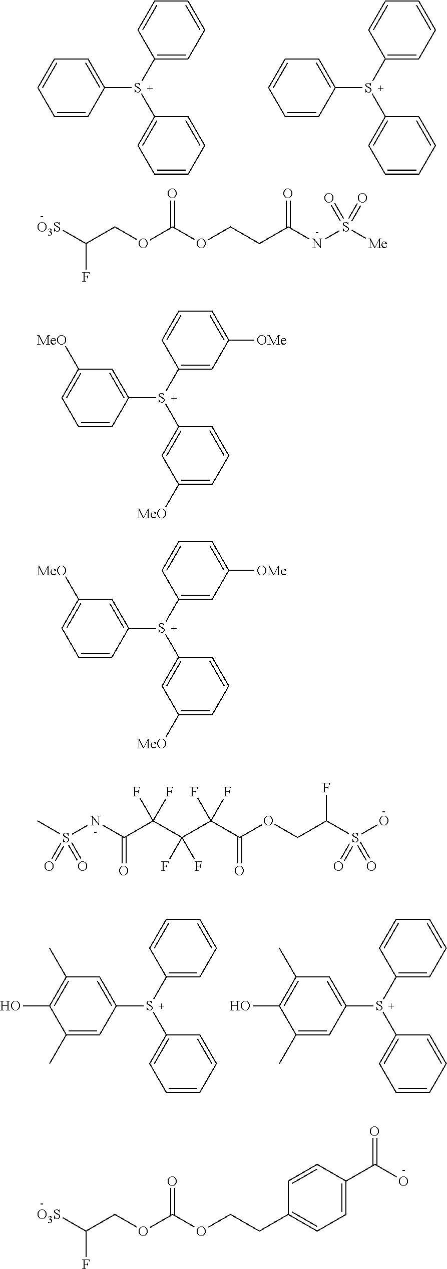

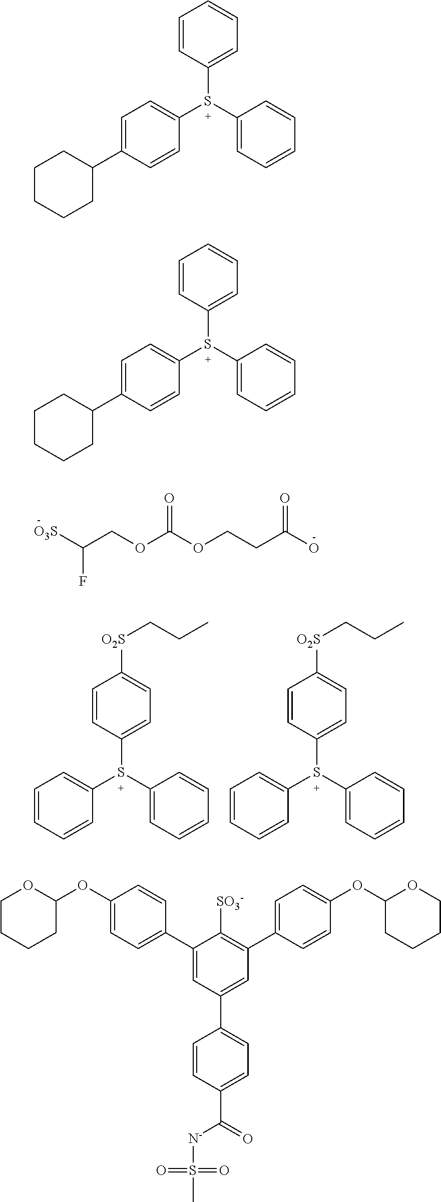

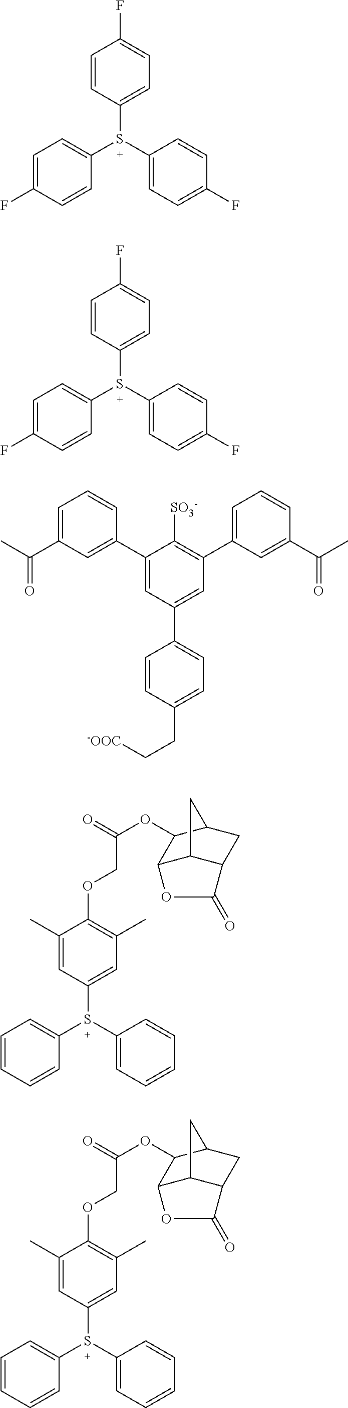

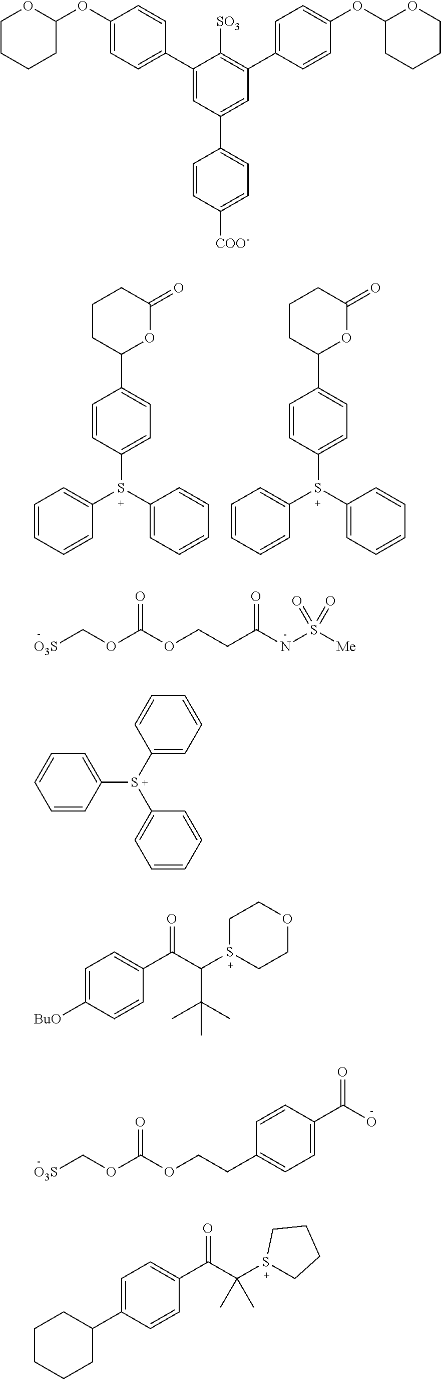

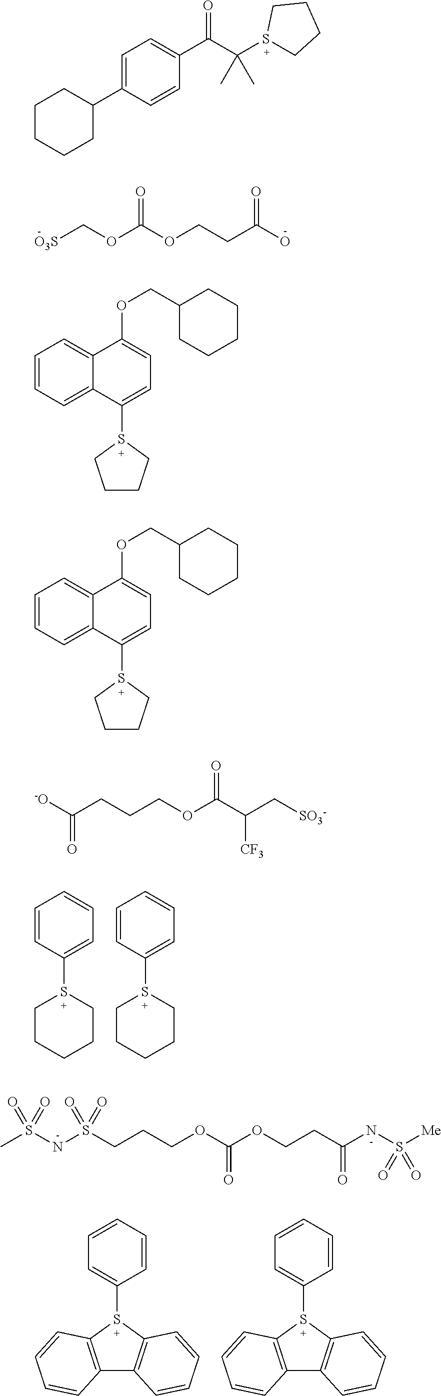

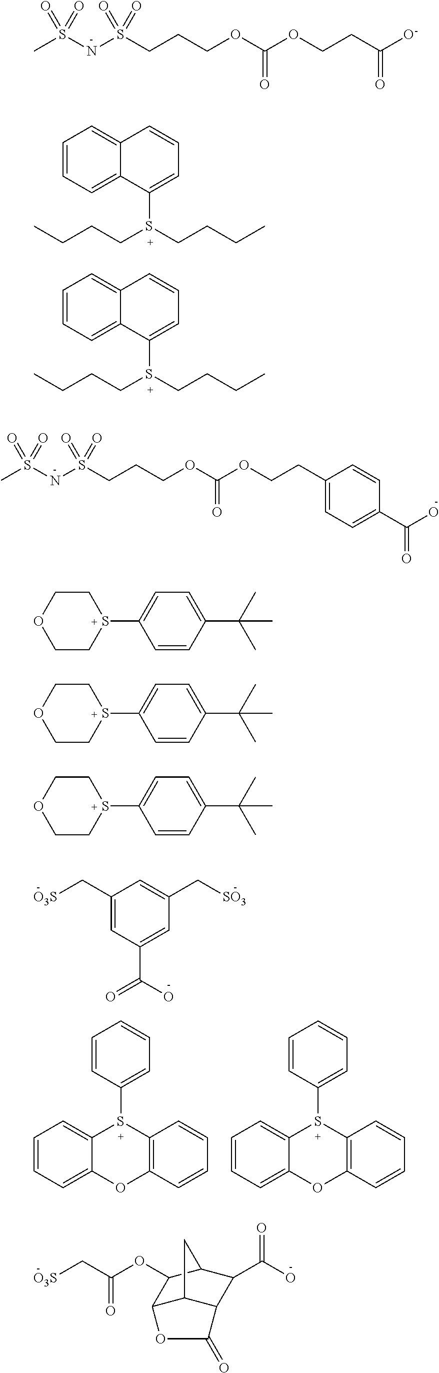

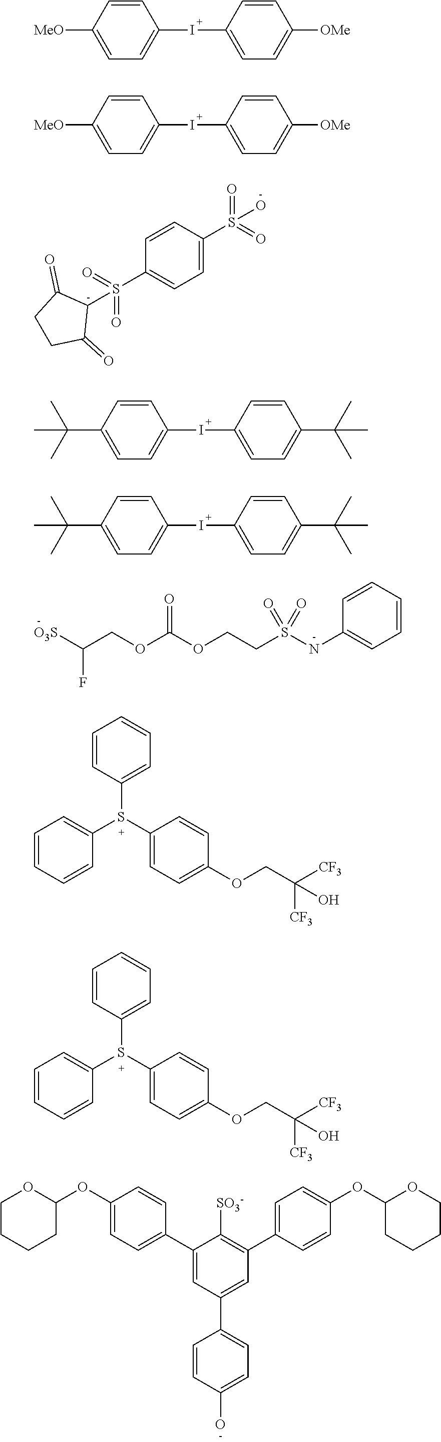

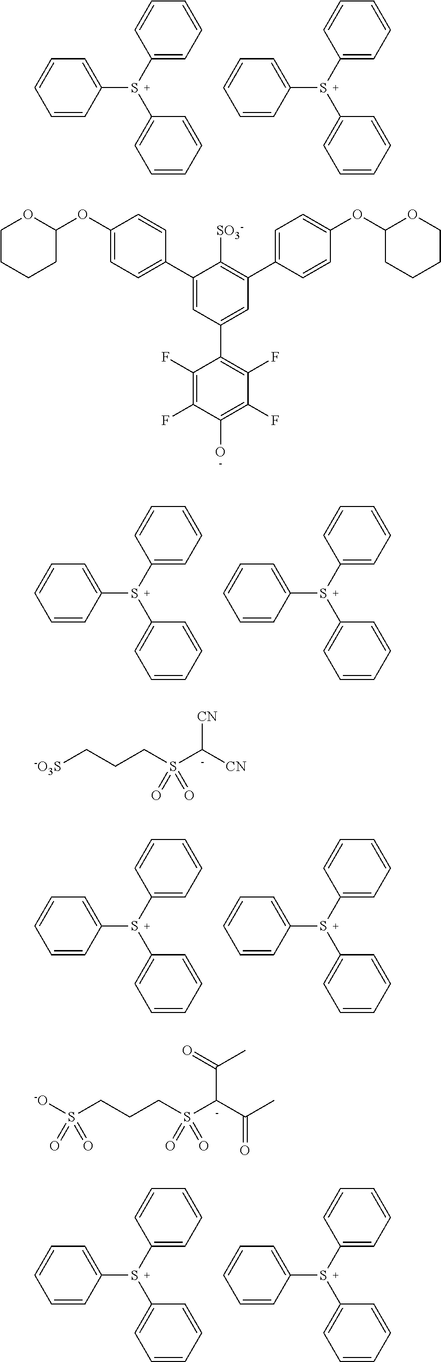

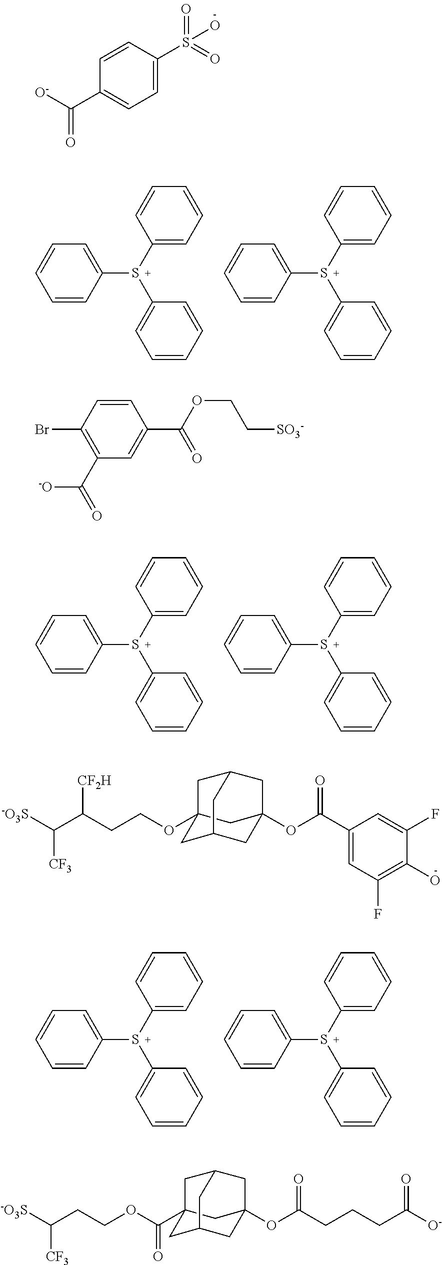

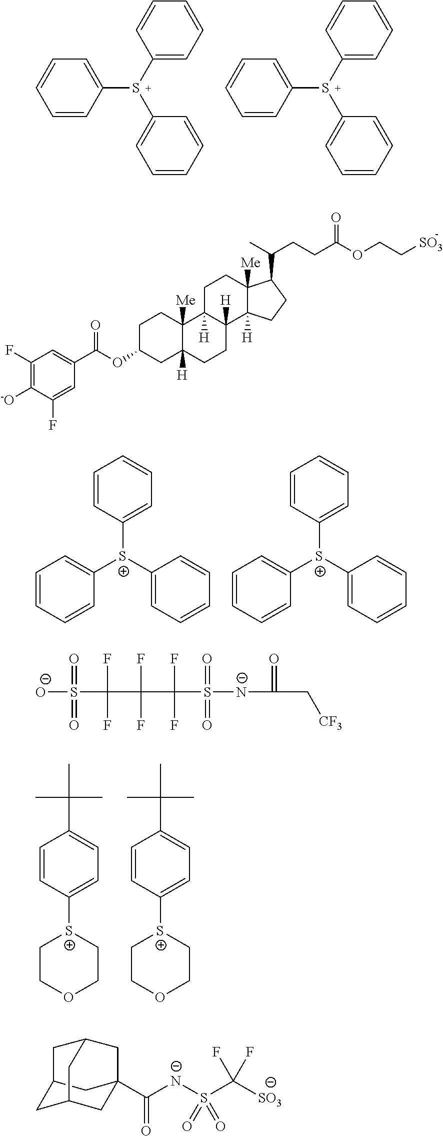

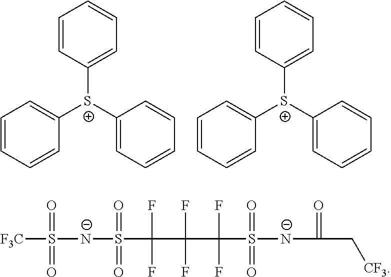

<Compound Represented by General Formula (II)>

The compound (B) may be a compound represented by General Formula (II).

X₂-A₃⁻M₃⁺ (II)

In General Formula (II), M₃⁻ represents a cation. A₃⁻ represents an anionic group. X₂ represents an organic group.

X₂ in General Formula (II) represents an organic group, and the number of carbon atoms in the organic group is not particularly limited, but is preferably 1 to 30, and more preferably 1 to 20. Examples of the organic group include an alkyl group (which preferably has 1 to 8 carbon atoms, and may be linear or branched), a cycloalkyl group (preferably having 3 to 15 carbon atoms), an alkenyl group (preferably having 2 to 6 carbon atoms), an aliphatic heterocyclic group (preferably having a 5- to 10-membered ring, more preferably having a 5- to 7-membered ring, and still more preferably having a 5- or 6-membered ring, each having at least one of a nitrogen atom, an oxygen atom, a sulfur atom, or a selenium atom in the ring structure), an aromatic heterocyclic group (preferably having a 5- to 10-membered ring, more preferably having a 5- to 7-membered ring, and still more preferably having a 5- or 6-membered ring, each having at least one of a nitrogen atom, an oxygen atom, a sulfur atom, or a selenium atom in the ring structure), an aromatic hydrocarbon ring group (preferably having a 6- to 10-membered ring, and more preferably having a 6-membered ring), and a group formed by combination of these groups. In addition, the organic group may include a linking group selected from the group consisting of —NR—, —COO—, —CO—, —O—, —S—, —SO—, and —SO₂— between carbon-carbon bonds. R represents a hydrogen atom or a monovalent organic group, and the monovalent organic group is not particularly limited, but is preferably, for example, an alkyl group (preferably having 1 to 6 carbon atoms).

In addition, the alkyl group, the cycloalkyl group, the alkenyl group, the aliphatic heterocyclic group, the aromatic heterocyclic group, and the aromatic hydrocarbon ring group may have a substituent. The substituent is not particularly limited, and examples thereof include the above-mentioned substituent T.

M₃⁺ in General Formula (II) represents a cation.

The cation represented by M₃⁺ is not particularly limited, but is preferably a sulfonium ion or an iodonium ion. Specific examples and the preferred ranges of M₃⁺ in General Formula (II) are the same as the specific examples and the preferred ranges of M⁺ in General Formula (b1) as described earlier.

Specific examples and preferred ranges of the anionic group represented by A₃⁻ in General Formula (II) are the same as those of A₁⁻ and A₂⁻ in General Formula (I) as described earlier.

In the composition of the embodiment of the present invention, the compound (B) may be used alone or in combination of two or more kinds thereof.

The content of the compound (B) (in a case where a plurality of the compounds (B) are present, a total content thereof) in the composition of the embodiment of the present invention is preferably 0.1% to 35% by mass, more preferably 0.5% to 30% by mass, still more preferably 1% to 25% by mass, and particularly preferably 5% to 25% by mass, with respect to a total solid content of the composition of the embodiment of the present invention.

[Acid Diffusion Control Agent]

The composition of the embodiment of the present invention preferably contains an acid diffusion control agent. The acid diffusion control agent acts as a quencher that suppresses a reaction of the resin (A) in the unexposed portion by excessive generated acids by trapping the acids generated from a photoacid generator and the like upon exposure.

For example, a basic compound (DA), a basic compound (DB) having basicity reduced or lost upon irradiation with actinic rays or radiation, an onium salt (DC) generating an acid which is a relatively weak acid with respect to an acid generated from a photoacid generator (B), a low-molecular-weight compound (DD) having a nitrogen atom and a group that leaves by the action of an acid, an onium salt compound (DE) having a nitrogen atom in a cationic moiety, can be used as the acid diffusion control agent. In the composition of the embodiment of the present invention, a known acid diffusion control agent can be appropriately used. For example, the known compounds disclosed in paragraphs [0627] to [0664] of US2016/0070167A1, paragraphs [0095] to [0187] of US2015/0004544A1, paragraphs [0403] to [0423] of US2016/0237190A1, and paragraphs [0259] to [0328] of US2016/0274458A1 can be suitably used as the acid diffusion control agent.

As the basic compound (DA), compounds having structures represented by General Formulae (A) to (E) are preferable.

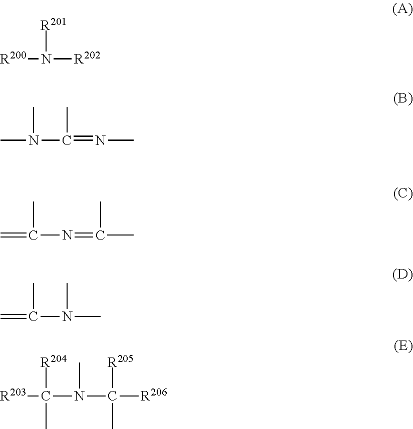

In General Formulae (A) and (E),

R²⁰⁰, R²⁰¹, and R²⁰² may be the same as or different from each other, and each independently represent a hydrogen atom, an alkyl group (preferably having 1 to 20 carbon atoms), a cycloalkyl group (preferably having 3 to 20 carbon atoms), or an aryl group (having 6 to 20 carbon atoms). R²⁰¹ and R²⁰² may be bonded to each other to form a ring.

R²⁰³, R²⁰⁴, R²⁰⁵, and R²⁰⁶ may be the same as or different from each other and each independently represent an alkyl group having 1 to 20 carbon atoms.

The alkyl group in each of General Formulae (A) and (E) may have a substituent or may be unsubstituted.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl group in each of General Formulae (A) and (E) are more preferably unsubstituted.

As the basic compound (DA), thiazole, benzothiazole, oxazole, benzoxazole, guanidine, aminopyrrolidine, pyrazole, pyrazoline, piperazine, aminomorpholine, aminoalkylmorpholine, piperidine, or compounds having these structures are preferable; and a compound having a thiazole structure, a benzothiazole structure, an oxazole structure, a benzoxazole structure, an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond, or the like is more preferable.

The basic compound (DB) having basicity reduced or lost upon irradiation with actinic rays or radiation (hereinafter also referred to as a “compound (DB)”) is a compound which has a proton-accepting functional group, and decomposes under irradiation with actinic rays or radiation to exhibit reduced or lost proton-accepting properties, or a change from the proton-accepting properties to acidic properties.

The proton-accepting functional group refers to a functional group having a group or an electron which is capable of electrostatically interacting with a proton, and for example, means a functional group with a macrocyclic structure, such as a cyclic polyether, or a functional group having a nitrogen atom having an unshared electron pair not contributing to n-conjugation. The nitrogen atom having an unshared electron pair not contributing to n-conjugation is, for example, a nitrogen atom having a partial structure represented by the following formula.

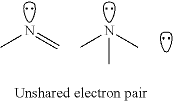

Preferred examples of the partial structure of the proton-accepting functional group include a crown ether structure, an azacrown ether structure, primary to tertiary amine structures, a pyridine structure, an imidazole structure, and a pyrazine structure.

The compound (DB) decomposes upon irradiation with actinic rays or radiation to generate a compound exhibiting reduced or lost proton-accepting properties, or a change from the proton-accepting properties to acidic properties. Here, exhibiting reduced or lost proton-accepting properties, or a change from the proton-accepting properties to acidic properties means a change of proton-accepting properties due to the proton being added to the proton-accepting functional group, and specifically a decrease in the equilibrium constant at chemical equilibrium in a case where a proton adduct is generated from the compound (DB) having the proton-accepting functional group and the proton.

The proton-accepting properties can be confirmed by performing pH measurement.

The acid dissociation constant pKa of the compound generated by decomposition of the compound (DB) upon irradiation with actinic rays or radiation preferably satisfies pKa<−1, and more preferably satisfies −13<pKa<−1, and still more preferably satisfies −13<pKa<−3.

In a case where the photoacid generator (B) and the onium salt (DC) generating an acid which serves as a relatively weak acid with respect to an acid generated from the photoacid generator (B) are mixed and used, an acid generated from the photoacid generator (B) upon irradiation with actinic rays or radiation produces an onium salt having a strong acid anion by discharging the weak acid through salt exchange in a case where the acid collides with an onium salt (DC) having an unreacted weak acid anion. In this process, the strong acid is exchanged with a weak acid having a lower catalytic activity, and thus, the acid is apparently deactivated and the acid diffusion can be controlled.

As the onium salt (DC), compounds represented by General Formulae (d1-1) to (d1-3) are preferable.

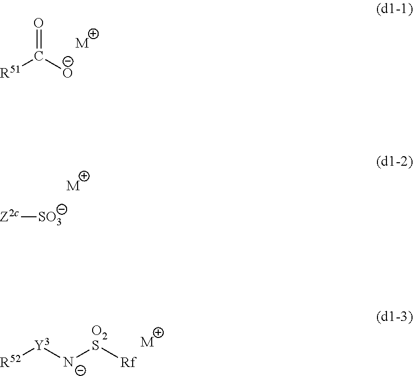

In the formula, R⁵¹ is a hydrocarbon group which may have a substituent. Z^{2c} is a hydrocarbon group having 1 to 30 carbon atoms, which may have a substituent (provided that carbon adjacent to S is not substituted with a fluorine atom), R⁵² is an organic group, Y³ is a linear, branched, or cyclic alkylene group or an arylene group, Rf is a hydrocarbon group including a fluorine atom, and M⁺'s are each independently an ammonium cation, a sulfonium cation, or an iodonium cation.

Preferred examples of the sulfonium cation or iodonium cation represented by M⁺ include the sulfonium cation exemplified for General Formula (ZI) and the iodonium cation exemplified for General Formula (ZII).

The onium salt (DC) which is a relatively weak acid with respect to a photoacid generator may be a compound having a cationic moiety and an anionic moiety in the same molecule, in which the cationic moiety and the anionic moiety are linked by a covalent bond (hereinafter also referred to as a “compound (DCA)”).

The compound (DCA) is preferably a compound represented by any of General Formulae (C-1) to (C-3).

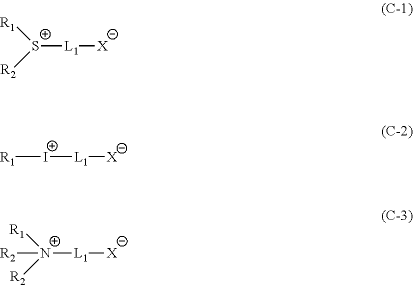

In General Formulae (C-1) to (C-3),

R₁, R₂, and R₃ each independently represent a substituent having 1 or more carbon atoms.

L₁ represents a divalent linking group that links a cationic moiety with an anionic moiety, or a single bond.

—X⁻ represents an anionic moiety selected from —COO—, —SO₃—, —SO₂—, and —N⁻—R₄. R₄ represents at least one of a monovalent substituent having a carbonyl group: —C(═O)—, a sulfonyl group: —S(═O)₂—, or a sulfinyl group: —S(═O)— at a site for linking to an adjacent N atom.

R₁, R₂, R₃, R₄, and L₁ may be bonded to each other to form a ring structure. In addition, in General Formula (C-3), two of R₁ to R₃ are combined with each other to represent one divalent substituent, and may be bonded to an N atom through a double bond.

Examples of the substituent having 1 or more carbon atoms in each of R₁ to R₃ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group. The alkyl group, a cycloalkyl group, or the aryl group is preferable.

Examples of L₁ as a divalent linking group include a linear or branched alkylene group, a cycloalkylene group, an arylene group, a carbonyl group, an ether bond, an ester bond, an amide bond, a urethane bond, a urea bond, and a group formed by combination of two or more of these groups. L₁ is preferably the alkylene group, the arylene group, the ether bond, the ester bond, and the group formed by combination of two or more of these groups.

The low-molecular-weight compound (DD) having a nitrogen atom and having a group that leaves by the action of an acid (hereinafter also referred to as a “compound (DD)”) is preferably an amine derivative having a group that leaves by the action of an acid on the nitrogen atom.

As the group that leaves by the action of an acid, an acetal group, a carbonate group, a carbamate group, a tertiary ester group, a tertiary hydroxyl group, or a hemiaminal ether group is preferable, and the carbamate group or the hemiaminal ether group is more preferable.

The molecular weight of the compound (DD) is preferably 100 to 1,000, more preferably 100 to 700, and still more preferably 100 to 500.

The compound (DD) may have a carbamate group having a protective group on the nitrogen atom. The protective group constituting the carbamate group is represented by General Formula (d-1).

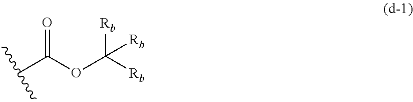

In General Formula (d-1),

R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be bonded to each other to form a ring.

The alkyl group, the cycloalkyl group, the aryl group, or the aralkyl group represented by R_{b} may be each independently substituted with a functional group such as a hydroxyl group, a cyano group, an amino group, a pyrrolidino group, a piperidino group, a morpholino group, and an oxo group, an alkoxy group, or a halogen atom. The same applies to the alkoxyalkyl group represented by R_{b}.

As R_{b}, a linear or branched alkyl group, a cycloalkyl group, or an aryl group is preferable, and the linear or branched alkyl group, or the cycloalkyl group is more preferable.

Examples of the ring formed by the mutual linkage of two R_{b}'s include an alicyclic hydrocarbon, an aromatic hydrocarbon, a heterocyclic hydrocarbon, and derivatives thereof.

Examples of the specific structure of the group represented by General Formula (d-1) include, but are not limited to, the structures disclosed in paragraph [0466] of US2012/0135348A₁.

The compound (DD) preferably has a structure represented by General Formula (6).

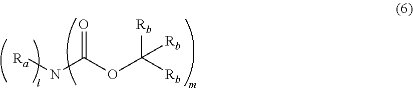

In General Formula (6),

l represents an integer of 0 to 2, m represents an integer of 1 to 3, and these satisfy l+m=3.

Rₐ represents a hydrogen atom, an alkyl group, a cycloalkyl group, an aryl group, or an aralkyl group. In a case where 1 is 2, two Rₐ's may be the same as or different from each other, and the two Rₐ's may be linked to each other to form a heterocyclic ring with the nitrogen atom in the formula. This heterocyclic ring may include a heteroatom other than the nitrogen atom in the formula.

R_{b} has the same definition as R_{b} in General Formula (d-1), and preferred examples are also the same.

In General Formula (6), the alkyl group, the cycloalkyl group, the aryl group, and the aralkyl group as Rₐ may be each independently substituted with the same groups as the group mentioned above as a group which may be substituted in the alkyl group, the cycloalkyl group, the aryl group, and the aralkyl group as R_{b}.

Specific examples of the alkyl group, the cycloalkyl group, the aryl group, and the aralkyl group (these groups may be substituted with the groups) of Rₐ include the same groups as the specific examples described above with respect to R_{b}.

Specific examples of the particularly preferred compound (DD) in the present invention include, but are not limited to, the compounds disclosed in paragraph [0475] of US2012/0135348A₁.

The onium salt compound (DE) having a nitrogen atom in a cationic moiety (hereinafter also referred to as a “compound (DE)”) is preferably a compound having a basic moiety including a nitrogen atom in the cationic moiety. The basic moiety is preferably an amino group, and more preferably an aliphatic amino group. All of the atoms adjacent to the nitrogen atom in the basic moiety are still more preferably hydrogen atoms or carbon atoms. In addition, from the viewpoint of improving basicity, it is preferable that an electron-withdrawing functional group (such as a carbonyl group, a sulfonyl group, a cyano group, and a halogen atom) is not directly linked to the nitrogen atom.

Preferred specific examples of the compound (DE) include, but are not limited to, the compounds disclosed in paragraph [0203] of US2015/0309408A₁.

With regard to specific examples of the acid diffusion control agent, reference can be made to the description in paragraphs [0204] to [0206] of WO2018/193954A, the contents of which are incorporated herein by reference. It should be noted that the acid diffusion control agent which can be used in the present invention is not limited thereto.

The acid diffusion control agents may be used alone or in combination of two or more kinds thereof.

The content of the acid diffusion control agent (in a case where a plurality of kinds of the acid diffusion control agents are present, a total content thereof) in the composition of the embodiment of the present invention is preferably 0.001% to 20% by mass, and more preferably 0.01% to 15% by mass with respect to the total solid content of the composition of the embodiment of the present invention.

[Solvent]

The composition of the embodiment of the present invention preferably contains a solvent.

In the composition of the embodiment of the present invention, a known resist solvent can be appropriately used as the solvent.

Examples of the solvent include organic solvents such as alkylene glycol monoalkyl ether carboxylate, alkylene glycol monoalkyl ether, alkyl lactate ester, alkyl alkoxypropionate, a cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

With regard to the solvent, reference can be made to the description in paragraphs [0187] to [0197] of WO2019/058890A, the contents of which are incorporated herein by reference.

[Surfactant]

The composition of the embodiment of the present invention may further include a surfactant. By containing the surfactant, in a case where an exposure light source at a wavelength of 250 nm or less, in particular, 220 nm or less is used, it is possible to form a pattern with good sensitivity and resolution, adhesiveness, and fewer development defects.

It is particularly preferable to use a fluorine-based and/or silicon-based surfactant as the surfactant.

With regard to the surfactant, reference can be made to the description in paragraphs [0183] and [0184] of WO2019/058890A, the contents of which are incorporated herein by reference.

In a case where the composition of the embodiment of the present invention includes a surfactant, a content thereof is preferably more than 0% to 2% by mass, more preferably 0.0001% to 2% by mass, and still more preferably 0.0005% to 1% by mass with respect to the total solid content of the composition.

[Other Additives]

The composition of the embodiment of the present invention can contain, in addition to the components described above, a carboxylic acid, an onium carboxylate salt, a dissolution inhibiting compound having a molecular weight of 3,000 or less described in Proceeding of SPIE, 2724.355 (1996) and the like, a dye, a plasticizer, a photosensitizer, a light absorber, an antioxidant, and the like as appropriate.

In particular, the carboxylic acid can be suitably used for improving the performance. The carboxylic acid is preferably an aromatic carboxylic acid such as benzoic acid or naphthoic acid.

In a case where the composition of the embodiment of the present invention includes a carboxylic acid, the content of the carboxylic acid is preferably 0.01% to 10% by mass, more preferably 0.01% to 5% by mass, and still more preferably 0.01% to 3% by mass with respect to the total solid content of the composition.

The concentration of solid contents of the actinic ray-sensitive or radiation-sensitive resin composition of the embodiment of the present invention is usually 1.0% to 10% by mass, preferably 1.5% to 5.7% by mass, and more preferably 1.8% to 5.3% by mass. By setting the concentration of solid contents within the range, the resist solution can be uniformly applied onto a substrate, and further, it is possible to form a resist pattern having excellent line width roughness.

The concentration of solid contents is a mass percentage of the mass of other components excluding the solvent with respect to the total mass of the actinic ray-sensitive or radiation-sensitive resin composition.

[Use]

The composition of the embodiment of the present invention relates to an actinic ray-sensitive or radiation-sensitive resin composition having properties which change by undergoing a reaction upon irradiation with actinic rays or radiation. More specifically, the composition of the embodiment of the present invention relates to an actinic ray-sensitive or radiation-sensitive resin composition which is used in a step of manufacturing a semiconductor such as an integrated circuit (IC), for the manufacture of a circuit board for a liquid crystal, a thermal head, or the like, the manufacture of a mold structure for imprinting, other photofabrication steps, or production of a planographic printing plate or an acid-curable composition. A pattern formed in the present invention can be used in an etching step, an ion implantation step, a bump electrode forming step, a rewiring forming step, microelectromechanical systems (MEMS), or the like.

[Actinic Ray-Sensitive or Radiation-Sensitive Film]

The present invention also relates to an actinic ray-sensitive or radiation-sensitive film (preferably a resist film) formed with the above-described actinic ray-sensitive or radiation-sensitive composition of the embodiment of the present invention. Such a film is formed, for example, by applying the composition of the embodiment of the present invention onto a support such as a substrate. The thickness of the actinic ray-sensitive or radiation-sensitive film is not particularly limited, but is preferably 0.02 to 0.1 μm. As a method for applying the composition on the substrate, a suitable application method such as spin coating, roll coating, flow coating, dip coating, spray coating, and doctor coating is used to apply the composition onto a substrate, but the spin coating is preferable and the rotation speed is preferably 1,000 to 3,000 rotations per minute (rpm). The coating film is prebaked at 60° C. to 150° C. for 1 to 20 minutes, and preferably at 80° C. to 120° C. for 1 to 10 minutes to form a thin film.

With regard to the topcoat which may be provided on the substrate and the actinic ray-sensitive or radiation-sensitive film, reference can be made to the description in paragraphs [0342] to [0358] of WO2017/056832A, the contents of which are incorporated herein by reference.

[Pattern Forming Method]

The present invention also relates to a pattern forming method including a resist film forming step of forming a resist film using the actinic ray-sensitive or radiation-sensitive resin composition of the embodiment of the present invention, an exposing step of exposing the resist film, and a developing step of developing the exposed resist film, using a developer.

In the present invention, the exposure is preferably carried out using electron beams (EB), an ArF excimer laser, or extreme ultraviolet rays (EUV), and more preferably electron beams or extreme ultraviolet rays.

For exposure (pattern forming step) on a resist film in the production of a precision integrated circuit element, first, irradiation with an ArF excimer laser, electron beams, or extreme ultraviolet rays (EUV) is preferably performed patternwise on the resist film of the present invention. In a case of the ArF excimer laser, the exposure amount is approximately 1 to 100 mi/cm², preferably approximately 20 to 60 mJ/cm²; in a case of the electron beams, the exposure amount is approximately 0.1 to 20 μC/cm², and preferably approximately 3 to 10 μC/cm²; and in a case of the extreme ultraviolet rays, the exposure amount is approximately 0.1 to 20 mJ/cm², and preferably approximately 3 to 15 mJ/cm².

Subsequently, post-exposure baking is performed on a hot plate, preferably at 60° C. to 150° C. for 5 seconds to 20 minutes, more preferably at 80° C. to 120° C. for 15 seconds to 10 minutes, and still more preferably at 80° C. to 120° C. for 1 to 10 minutes, and then development, rinsing, and drying are performed to form a pattern. Here, the post-exposure baking is appropriately adjusted depending on the acid decomposability of the repeating unit having an acid-decomposable group in the resin (A). In a case where the acid decomposability is low, it is also preferable that the temperature for post-exposure baking is 110° C. or higher and the heating time is 45 seconds or longer.

The developer is appropriately selected, but an alkali developer (typically an aqueous alkali solution) or a developer containing an organic solvent (also referred to as an organic developer) is preferably used. In a case where the developer is an aqueous alkali solution, development is performed with an aqueous alkali solution of tetramethylammonium hydroxide (TMAH), tetrabutylammonium hydroxide (TBAH), or the like at 0.1% to 5% by mass, and preferably 2% to 3% by mass for 0.1 to 3 minutes, and preferably 0.5 to 2 minutes by an ordinary method such as a dip method, a puddle method, a spray method, or the like. An appropriate amount of an alcohol and/or a surfactant may be added to the alkali developer. Thus, in the formation of a negative tone pattern, the film in the unexposed portion is dissolved and the exposed portion is hardly dissolved in the developer; and in the formation of a positive tone pattern, the film in the exposed portion is dissolved and the film in the unexposed portion is hardly dissolved in the developer, such that a desired pattern is formed on the substrate.

The alkali concentration of the alkali developer is usually 0.1% to 20% by mass.

The pH of the alkali developer is usually 10.0 to 15.0.

In particular, a 2.38%-by-mass aqueous tetramethylammonium hydroxide solution is desirable.

Pure water may be used as the rinsing liquid in the rinse treatment performed after the alkali development, and an appropriate amount of a surfactant may be added to the pure water.

In addition, after the developing treatment or the rinsing treatment, a treatment of removing the developer or the rinsing liquid adhering to a pattern with a supercritical fluid can be performed.

In a case where the pattern forming method of the embodiment of the present invention has a step of performing development using a developer containing an organic solvent, as the developer in the step (hereinafter also referred to as an organic developer), a polar solvent such as a ketone-based solvent, an ester-based solvent, an alcohol-based solvent, an amide-based solvent, and an ether-based solvent, or a hydrocarbon-based solvent can be used.

The concentration of the organic solvent (in a case of mixing a plurality of the organic solvents, a total thereof) in the organic developer is preferably 50% by mass or more, more preferably 50% to 100% by mass, still more preferably 85% to 100% by mass, even still more preferably 90% to 100% by mass, and particularly preferably 95% to 100% by mass. Most preferably, the organic solvent consists substantially only of an organic solvent. In addition, a case of consisting substantially only of an organic solvent includes a case of containing a trace amount of a surfactant, an antioxidant, a stabilizer, an antifoaming agent, or the like.

In particular, the organic developer is preferably a developer containing at least one organic solvent selected from the group consisting of a ketone-based solvent, an ester-based solvent, an alcohol-based solvent, an amide-based solvent, and an ether-based solvent.

With regard to the pattern forming method, reference can be made to the description in paragraphs [0359] to [0383] of WO2017/056832A, the contents of which are incorporated herein by reference.

It is preferable that various materials (for example, a resist solvent, a developer, a rinsing liquid, a composition for forming an antireflection film, and a composition for forming a topcoat) used in the actinic ray-sensitive or radiation-sensitive composition in the embodiment of the present invention, and the pattern forming method of the embodiment of the present invention include no impurities such as metals, metal salts including halogen, acids, alkalis, and components including a sulfur atom or a phosphorus atom. Here, examples of the impurities including a metal atom include Na, K, Ca, Fe, Cu, Mn, Mg, Al, Cr, Ni, Zn, Ag, Sn, Pb, Li, and salts thereof.

The content of the impurities included in these materials is preferably 1 part per million (ppm) or less, more preferably 1 part per billion (ppb) or less, still more preferably 100 parts per trillion (ppt) or less, and particularly preferably 10 ppt or less, and it is the most preferable that the impurities are not substantially included (no higher than a detection limit of a measuring device).

With regard to a method for removing impurities such as metals from various materials, reference can be made to the description of paragraphs [0384] to [0402] of WO2017/056832A, the contents of which are incorporated herein by reference.

[Method for Manufacturing Electronic Device]

In addition, the present invention further relates to a method for manufacturing an electronic device, including the above-described pattern forming method. The electronic device manufactured by the method for manufacturing an electronic device of an embodiment of the present invention is suitably mounted on electric and electronic equipment (for example, home appliances, office automation (OA)-related equipment, media-related equipment, optical equipment, and telecommunication equipment).

### EXAMPLES

Hereinbelow, the present invention will be described in more detail with reference to Examples. The materials, the amounts of materials used, the proportions, the treatment details, the treatment procedure, and the like shown in Examples below may be appropriately modified as long as the modifications do not depart from the spirit of the present invention. Therefore, the scope of the present invention should not be construed as being limited to Examples shown below.

<Resin (A)>

The structures of the repeating units and contents (molar ratios) thereof, the weight-average molecular weights (Mw), and the dispersities (Mw/Mn) of the resin (A) used are shown below.

Furthermore, the resins (RA-1) to (RA-5) are not the resin (A), but will be described below for convenience. The same applies to Tables 1 and 3.

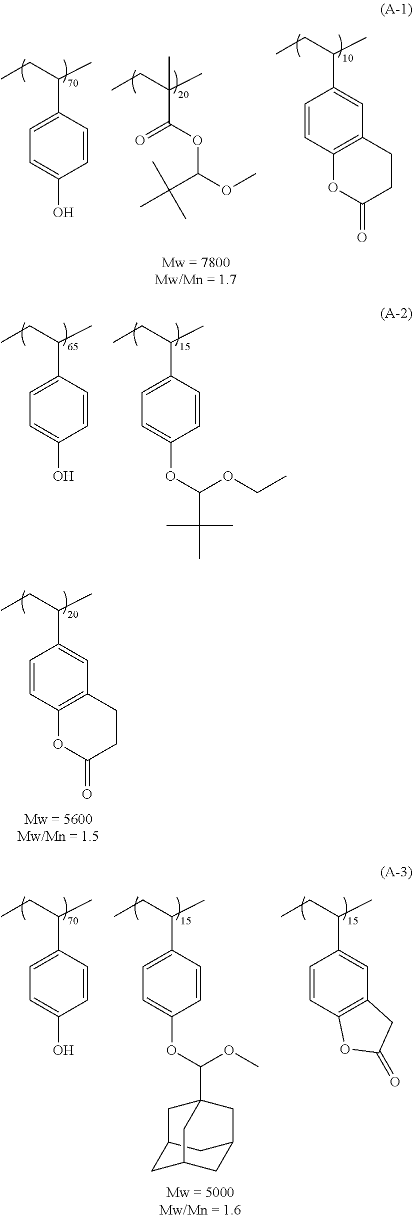

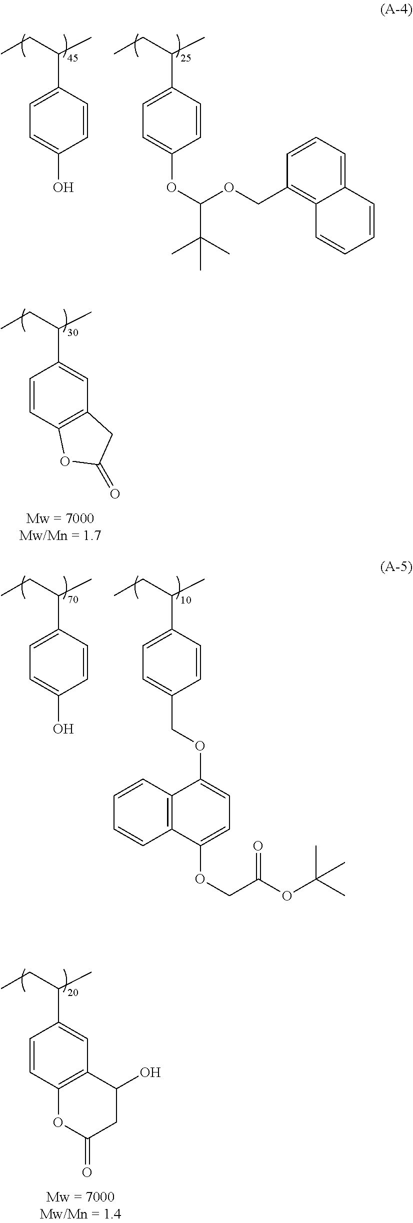

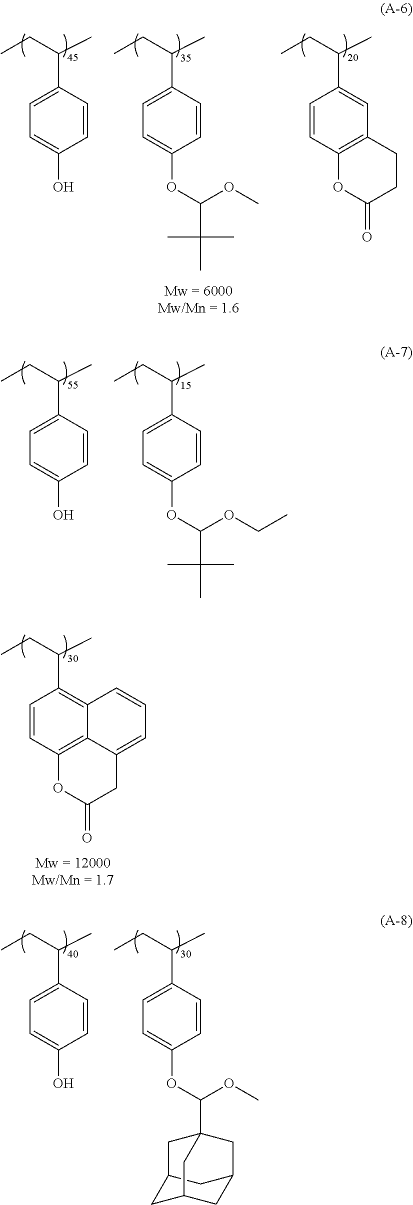

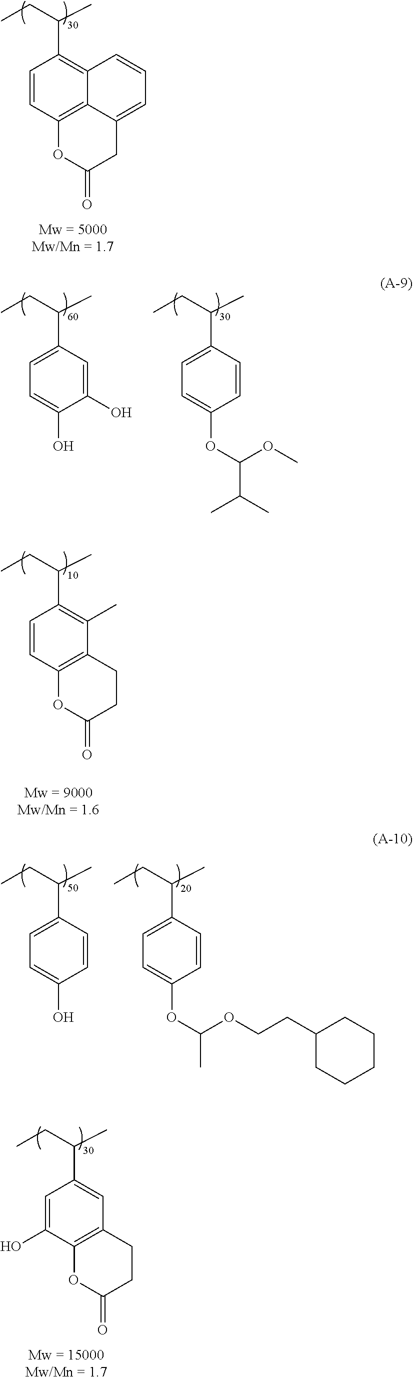

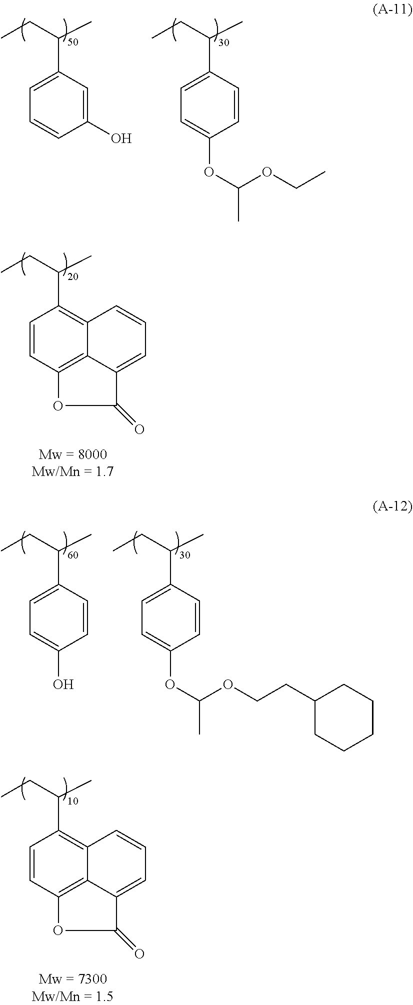

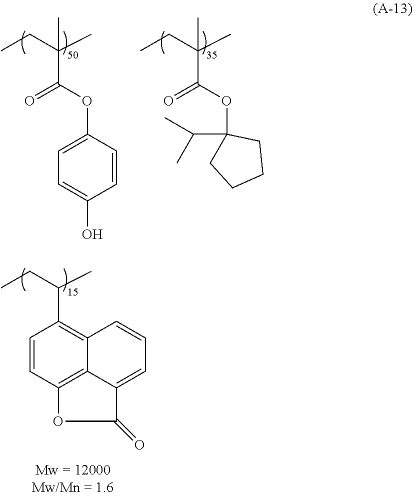

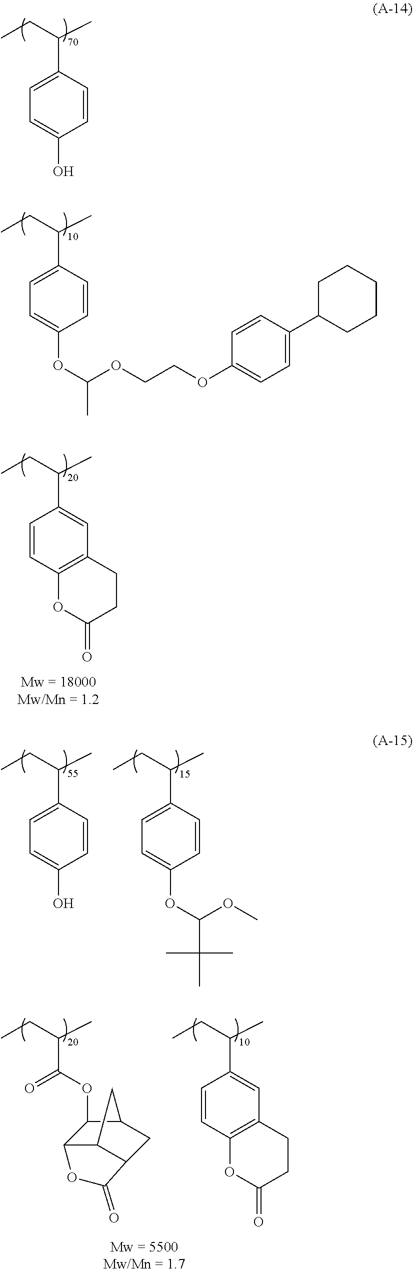

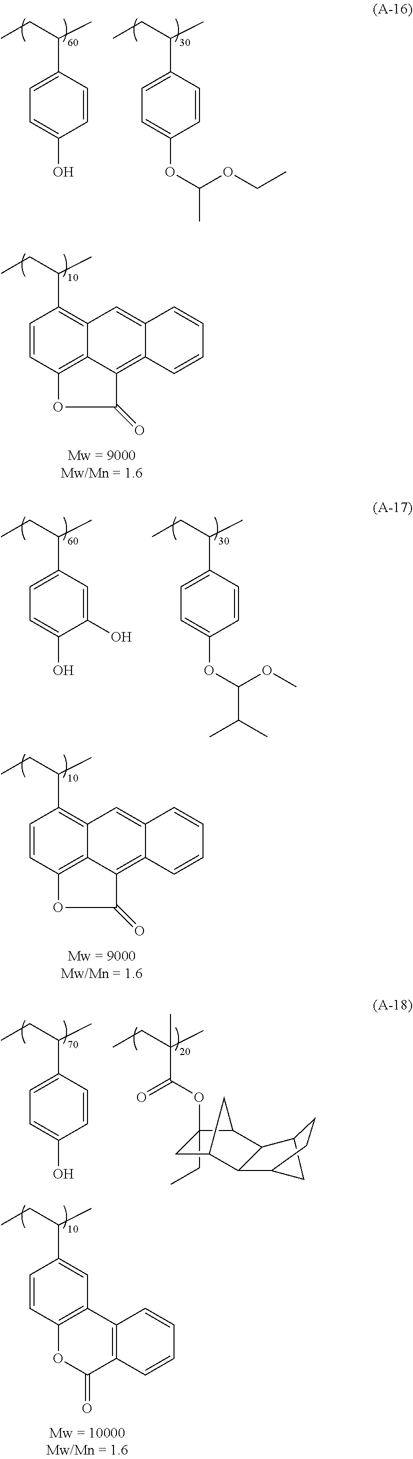

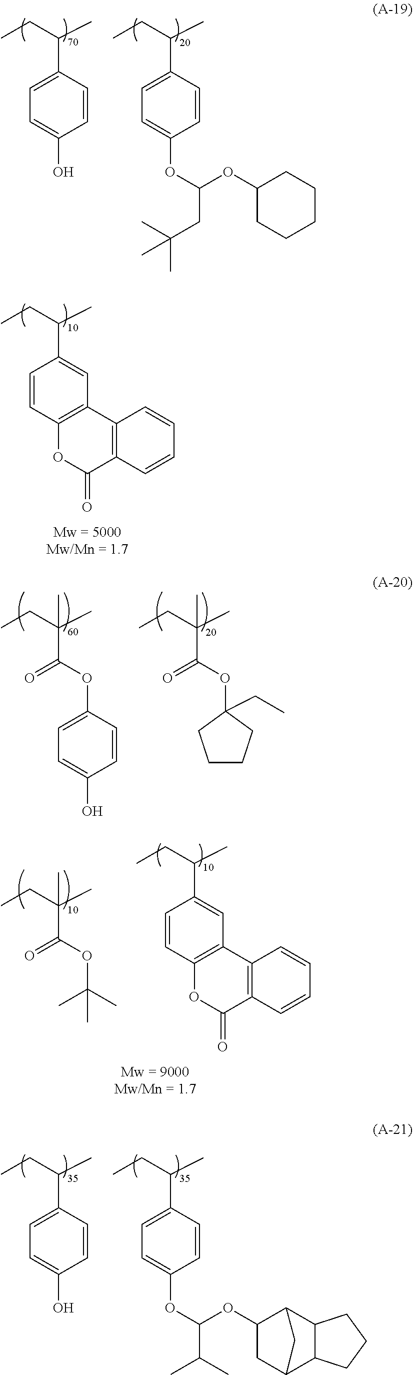

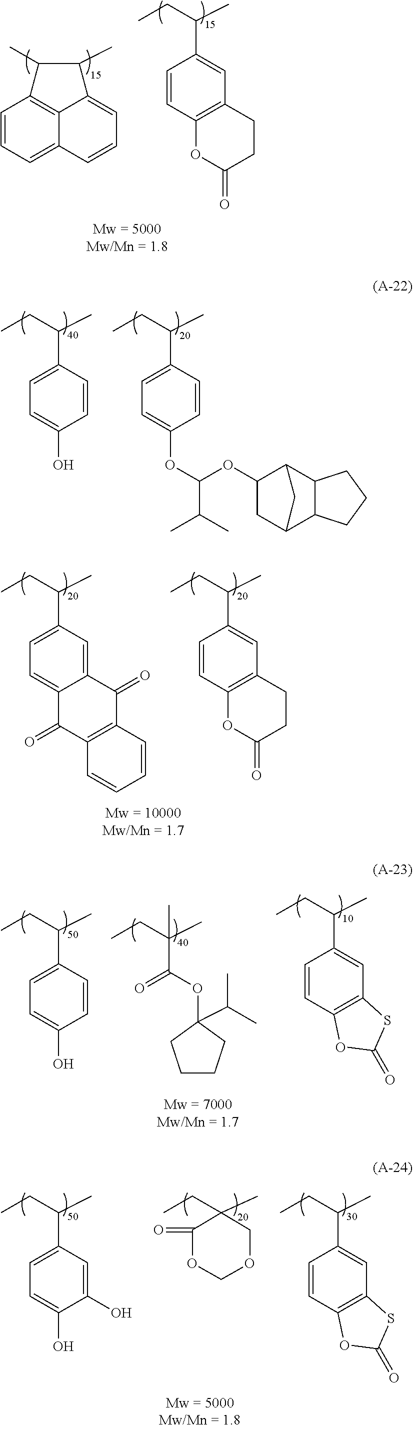

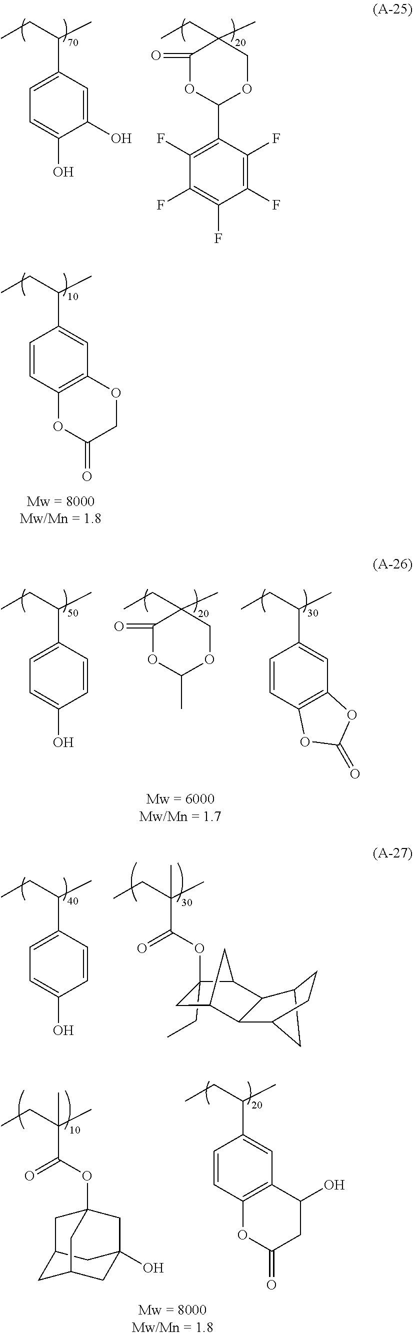

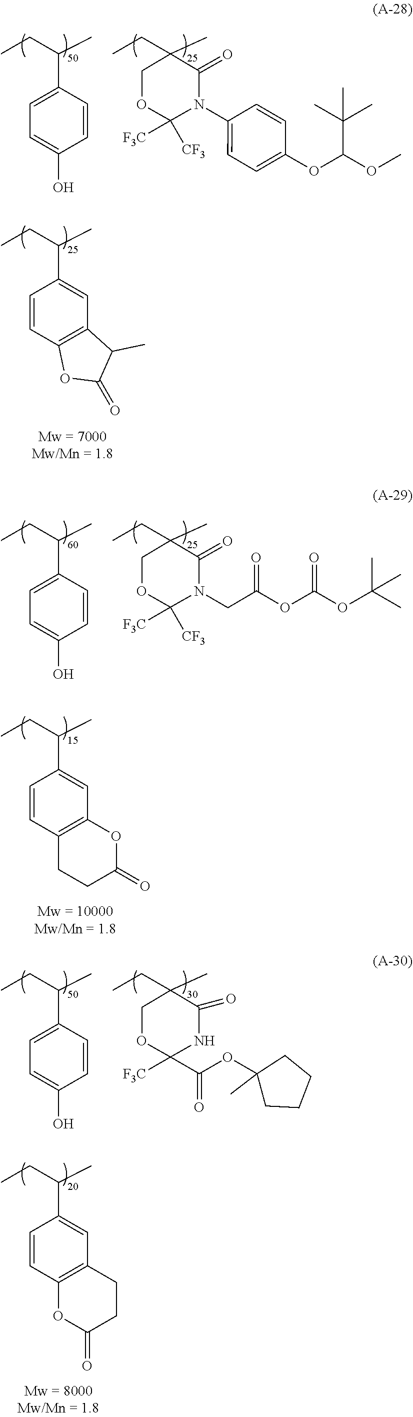

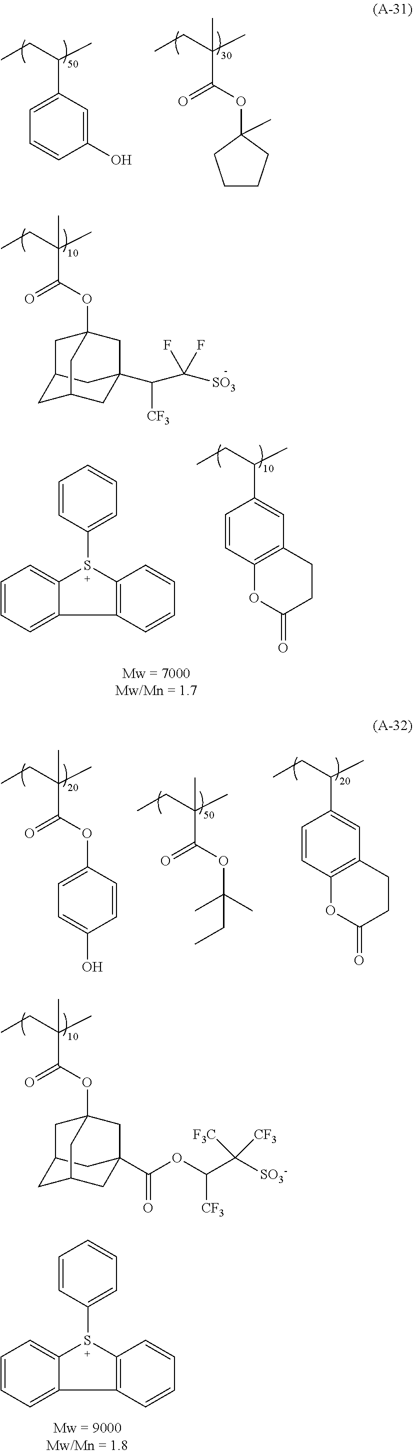

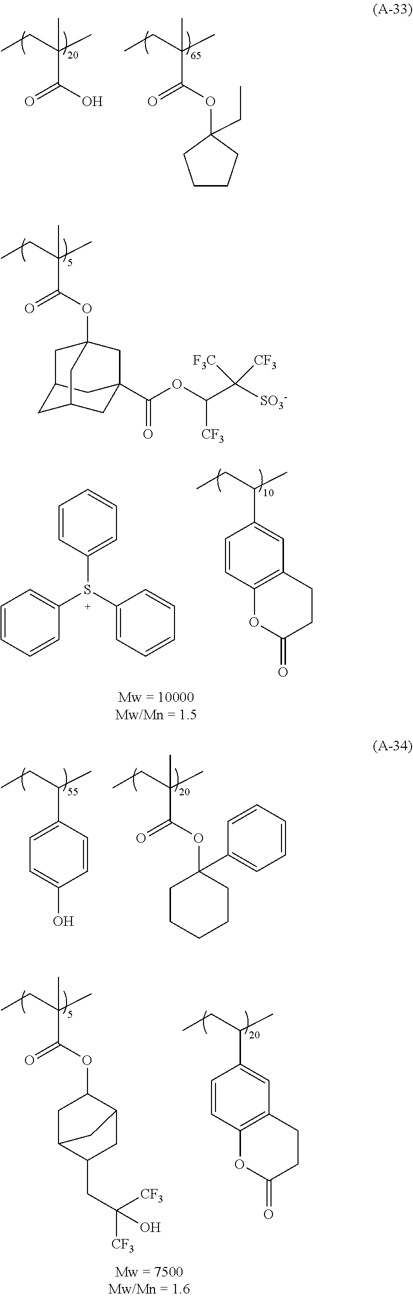

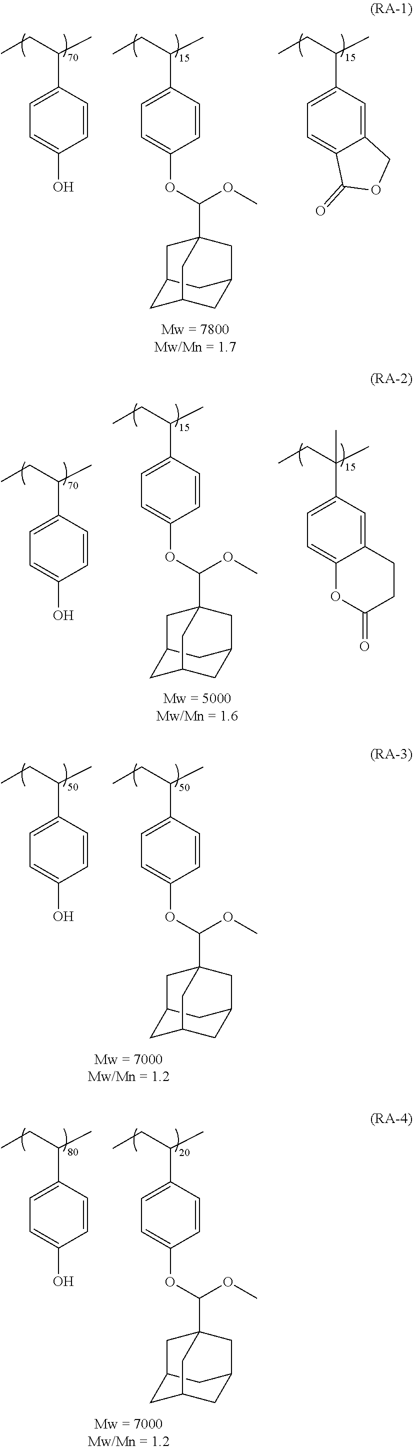

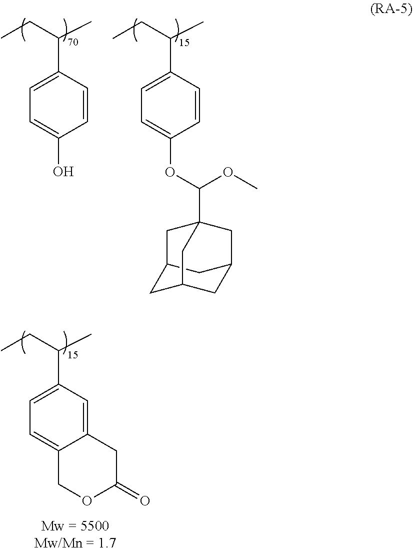

### Synthesis Example 1: Synthesis of Resin (A-1)

(Synthesis of Monomer M-3)

50.0 g of 3,4-dihydrocoumarin was dissolved in 350 mL of methylene chloride, and iodine monochloride dissolved in 350 mL of methylene chloride was added dropwise thereto. After performing a reaction at room temperature for 24 hours, 500 mL of a 0.1 mol/L aqueous sodium hydrogen sulfite solution was added dropwise, and the mixture was further stirred for 30 minutes. 500 mL of methylene chloride was added thereto. The organic layer was washed with water, dried, and concentrated to obtain a crude product. Recrystallization was performed with acetone/hexane to obtain 66.9 g of (M-3a).

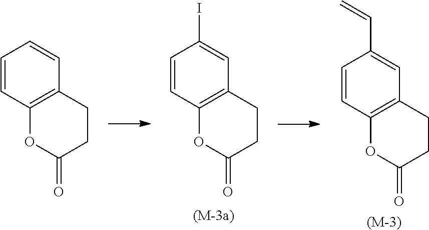

60.0 g of (M-3a) was dissolved in 300 mL of diglyme, 255 g of N,N-diisopropylethylamine, 59.8 g of potassium vinyltrifluoroborate, and 0.600 g of dibutylhydroxytoluene were added thereto, and the mixture was stirred under a nitrogen stream for 30 minutes. Next, 9.39 g of 2-di-tert-butylphosphino-2′,4′,6′-triisopropyl-1,1′-biphenyl and 2.46 g of palladium acetate were added thereto, and the mixture was reacted at 90° C. for 3 hours. After cooling to room temperature, the mixture was filtered through Celite, and the solvent was distilled off under reduced pressure. 600 mL of ethyl acetate was added thereto, and the mixture was washed with water, dried, and concentrated to obtain a crude product. By performing distillation under reduced pressure, 10.0 g of (M-3) was obtained.

(Synthesis of Resin (A-1))

7.60 g of cyclohexanone was heated to 85° C. under a nitrogen stream. While stirring this liquid, a mixed solution of 6.78 g of a monomer represented by Formula (M-1), 2.92 g of a monomer represented by Formula (M-2), 1.17 g of (M-3), 11.0 g of cyclohexanone, and 2.02 g of dimethyl 2,2′-azobisisobutyrate [V-601, manufactured by FUJIFILM Wako Pure Chemical Corporation] was added dropwise thereto over 4 hours to obtain a reaction solution. After completion of the dropwise addition, the reaction solution was further stirred at 85° C. for 2 hours. The obtained reaction solution was left to be cooled, 35.0 mL of ethyl acetate was added thereto, the mixture was reprecipitated with a large amount of heptane and filtered, and the obtained solid was vacuum-dried to obtain 8.60 g of a resin (A-1). The weight-average molecular weight and the dispersity (Mw/Mn) of the obtained resin were 7,800 and 1.70, respectively. The ratio of the following repeating units is on a molar basis.

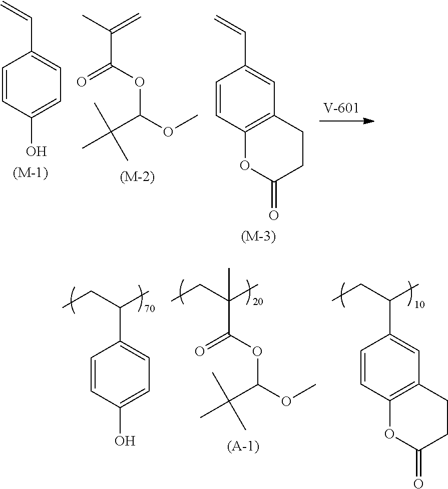

Such other resins were also synthesized in the same manner.

(pKa of Acid Group Generated by Hydrolysis of Alkali-Decomposable Cyclic Structure of Resin (A))

The pKa of an acid group generated by hydrolysis of the alkali-decomposable cyclic structure of the resin (A) is shown in Table 1. Since there exist two acid groups generated by hydrolysis of the alkali-decomposable cyclic structure of the resin (A), the acid dissociation constant in the first stage and the acid dissociation constant in the second stage are described as “pKa1” and “pKa2”, respectively

TABLE 1

| Resin (A) | pKa1 | pKa2 |
|---|---|---|
| (A-1) | 4.75 | 10.25 |
| (A-2) | 4.75 | 10.25 |
| (A-3) | 4.13 | 10.26 |
| (A-4) | 4.13 | 10.26 |
| (A-5) | 4.35 | 9.77 |
| (A-6) | 4.75 | 10.25 |
| (A-7) | 4.22 | 9.85 |
| (A-8) | 4.22 | 9.85 |
| (A-9) | 4.62 | 6.84 |
| (A-10) | 4.79 | 10.34 |
| (A-11) | 3.55 | 9.77 |
| (A-12) | 3.55 | 9.77 |
| (A-13) | 3.55 | 9.77 |
| (A-14) | 4.75 | 10.25 |
| (A-15) | 4.75 | 10.25 |
| (A-16) | 3.56 | 9.79 |
| (A-17) | 3.56 | 9.79 |
| (A-18) | 3.85 | 9.89 |
| (A-19) | 3.85 | 9.89 |
| (A-20) | 3.85 | 9.89 |
| (A-21) | 4.75 | 10.25 |
| (A-22) | 4.75 | 10.25 |
| (A-23) | 6.65 | 11.79 |
| (A-24) | 6.65 | 11.79 |
| (A-25) | 3.23 | 9.59 |
| (A-26) | 9.62 | 12.57 |
| (A-27) | 4.75 | 10.25 |
| (A-28) | 4.18 | 10.80 |
| (A-29) | 4.76 | 10.05 |
| (A-30) | 4.75 | 10.25 |
| (A-31) | 4.75 | 10.25 |
| (A-32) | 4.75 | 10.25 |
| (A-33) | 4.75 | 10.25 |
| (A-34) | 4.75 | 10.25 |
| (RA-1) | 3.88 | 14.73 |
| (RA-2) | 4.07 | 15.01 |
| (RA-3) | — | — |
| (RA-4) | — | — |
| (RA-5) | 4.20 | 14.38 |

<Photoacid Generator (B)>

The photoacid generators (B) used are shown below.

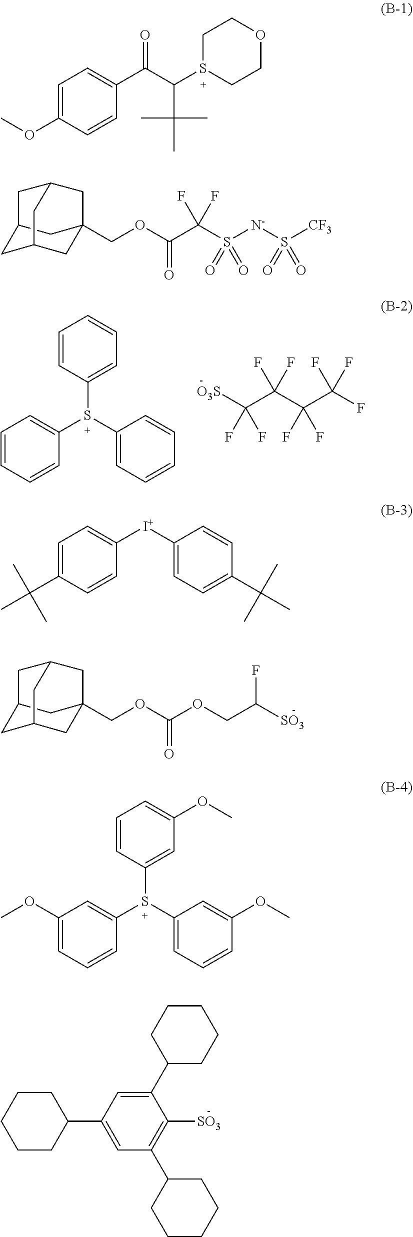

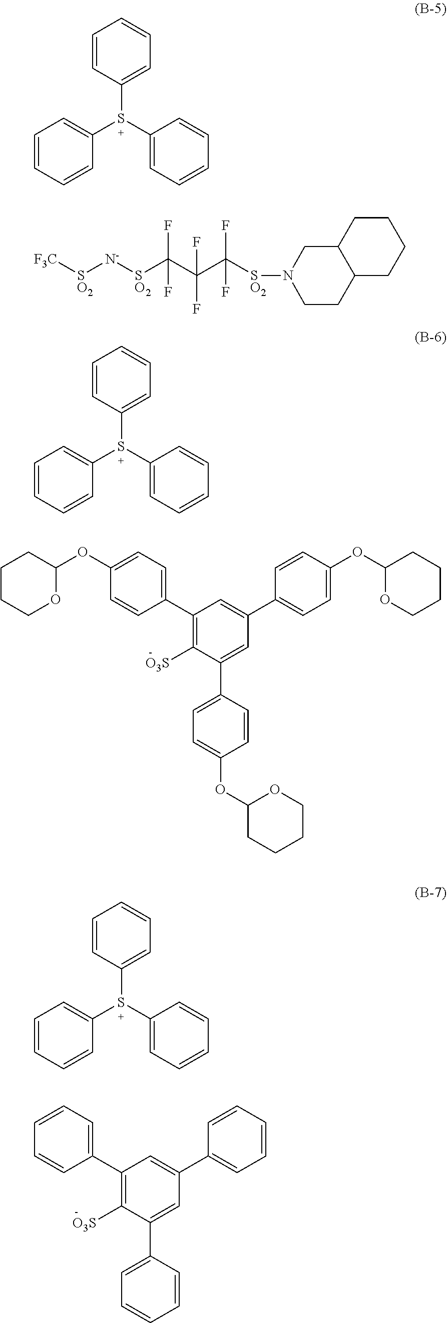

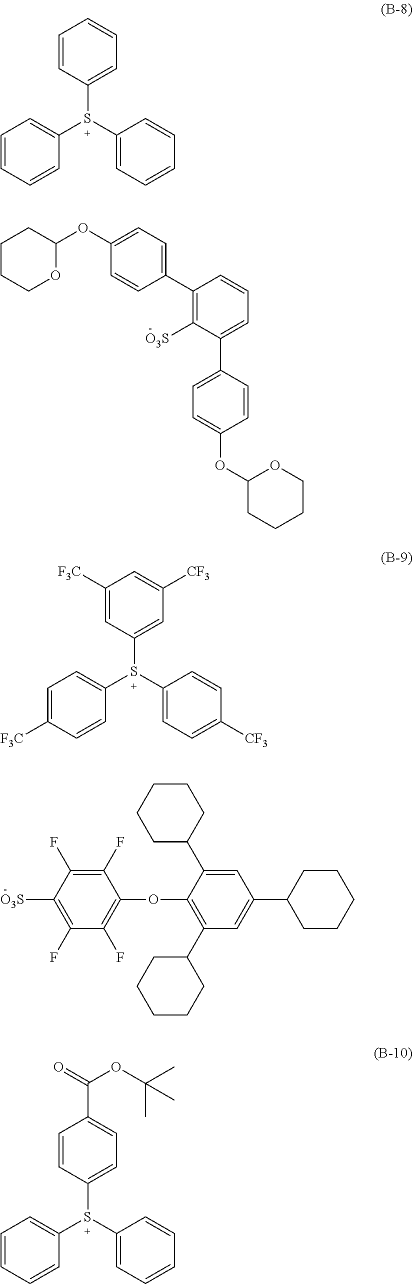

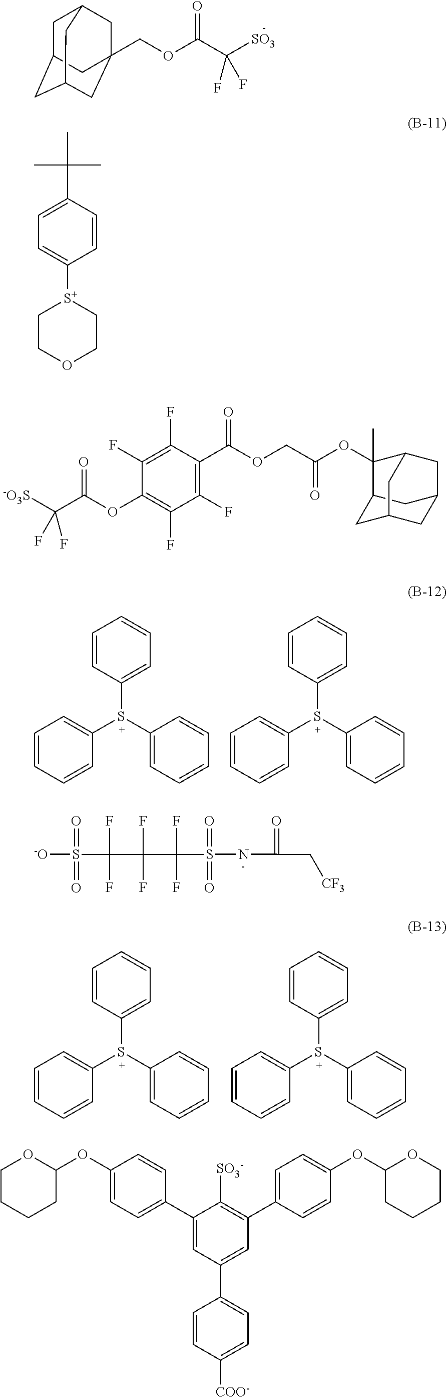

<Acid Diffusion Control Agent>

The structures of the acid diffusion control agents used are shown below.

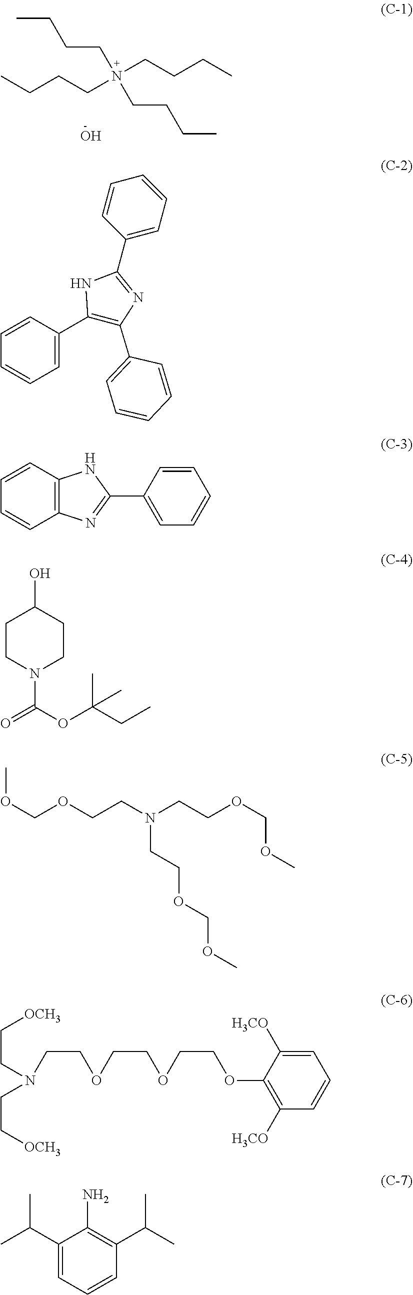

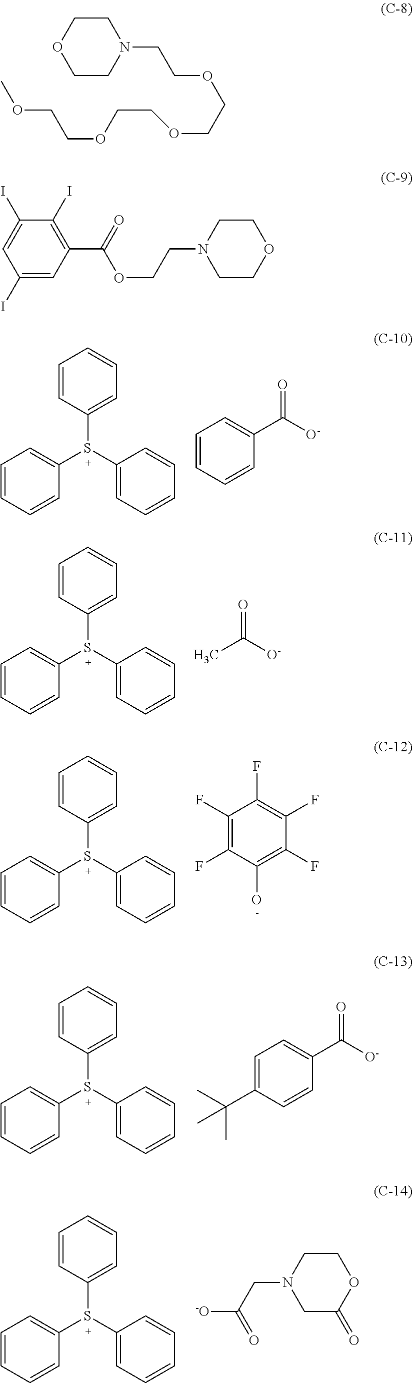

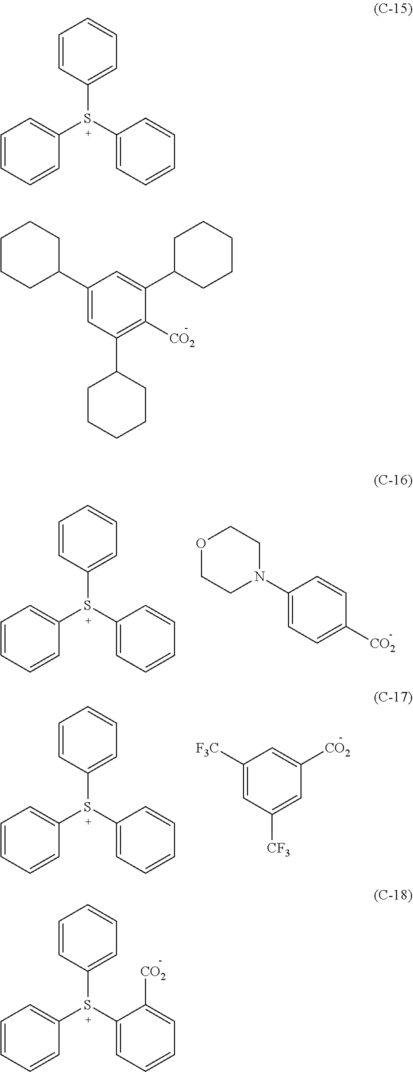

<Surfactant>

The following W-1 to W-4 were used as a surfactant.

W-1: MEGAFACE R08 (manufactured by Dainippon Ink and Chemicals Inc.; fluorine- and silicon-based)

W-2: Polysiloxane Polymer KP-341 (manufactured by Shin-Etsu Chemical Co., Ltd.; silicon-based)

W-3: TROYSOL S-366 (manufactured by Troy Chemical Corporation; fluorine-based)

W-4: PF6320 (manufactured by OMNOVA Solutions Inc.; fluorine-based)

<Solvent>

The solvents used are shown below.

S-1: Propylene glycol monomethyl ether acetate (PGMEA)

S-2: Propylene glycol monomethyl ether (PGME)

S-3: Ethyl lactate (EL)

S-4: Ethyl 3-ethoxypropionate (EEP)

S-5: 2-Heptanone (MAK)

S-6: Methyl 3-methoxypropionate (MMP)

S-7: 3-Methoxybutyl acetate

[Preparation and Coating of Coating Liquid of Resist Composition]

(1) Preparation of Support

An 8-inch wafer on which Cr oxynitride had been vapor-deposited (a product for which a shielding film treatment used for an ordinary photomask blank had been carried out) was prepared.

(2) Preparation of Resist Composition

The components shown in Tables 2 and 3 were dissolved in the solvents shown in the same tables to prepare solutions, which were filtered through a polyethylene filter having a pore size of 0.03 μm to prepare resist compositions.

(3) Manufacture of Resist Film

A resist composition was applied onto the 8-inch wafer using a spin coater Mark8 manufactured by Tokyo Electron Limited, and dried on a hot plate at 120° C. for 600 seconds to obtain a resist film having a film thickness of 90 nm. That is, a resist-coated wafer was obtained.

Furthermore, in Tables 2 and 3 below, the content (% by mass) of each component other than the solvent means a content ratio (% by mass) with respect to the total solid content. In addition, a content ratio (% by mass) with respect to the total solvent of the respective solvents used is described in Tables 2 and 3 below. Moreover, in Examples in which a surfactant was used, the content of the surfactant was set to 0.01% by mass with respect to the total solid content.

TABLE 2

| | | | Photoacid | | Acid diffusion control agent | | | | Surfactant |
|---|---|---|---|---|---|---|---|---|---|
| | Resin (A) | | generator (B) | | | Content of | | Content of | Type |
| Resist | | Content | | Content | | type 1 | | type 2 | (0.01% |
| composition | Type | (% by mass) | Type | (% by mass) | Type 1 | (% by mass) | Type 2 | (% by mass) | by mass) |
| R-1 | (A-1) | 89.79 | (B-1) | 10.00 | (C-1) | 0.20 | — | — | W-1 |
| R-2 | (A-2) | 79.90 | (B-2) | 20.00 | (C-2) | 0.10 | — | — | — |
| R-3 | (A-3) | 84.69 | (B-3) | 15.00 | (C-3) | 0.30 | — | — | W-1 |
| R-4 | (A-4) | 74.80 | (B-4) | 15.00 | (C-4) | 0.20 | (C-11) | 10.00 | — |
| R-5 | (A-5) | 69.89 | (B-5) | 30.00 | (C-5) | 0.10 | — | — | W-2 |
| R-6 | (A-6) | 69.80 | (B-6) | 20.00 | (C-6) | 0.20 | (C-17) | 10.00 | — |
| R-7 | (A-7) | 84.90 | (B-7) | 15.00 | (C-7) | 0.10 | — | — | — |
| R-8 | (A-8) | 89.70 | (B-8) | 10.00 | (C-8) | 0.30 | — | — | — |
| R-9 | (A-9) | 84.79 | (B-9) | 15.00 | (C-9) | 0.20 | — | — | W-1 |
| R-10 | (A-10) | 84.70 | (B-10) | 15.00 | (C-10) | 0.30 | — | — | — |
| R-11 | (A-11) | 84.80 | (B-11) | 15.00 | (C-11) | 0.20 | — | — | — |
| R-12 | (A-12) | 84.80 | (B-12) | 15.00 | (C-12) | 0.20 | — | — | — |
| R-13 | (A-13) | 84.89 | (B-13) | 15.00 | (C-13) | 0.10 | — | — | W-3 |
| R-14 | (A-14) | 79.90 | (B-1) | 20.00 | (C-14) | 0.10 | — | — | — |
| R-15 | (A-15) | 89.90 | (B-2) | 10.00 | (C-15) | 0.10 | — | — | — |
| R-16 | (A-16) | 84.69 | (B-3) | 15.00 | (C-16) | 0.30 | — | — | W-4 |
| R-17 | (A-17) | 79.79 | (B-4) | 20.00 | (C-17) | 0.20 | — | — | W-1 |
| R-18 | (A-18) | 89.90 | (B-5) | 10.00 | (C-1) | 0.10 | — | — | — |
| R-19 | (A-19) | 74.90 | (B-6) | 15.00 | (C-2) | 0.10 | (C-10) | 10.00 | — |
| R-20 | (A-20) | 79.80 | (B-7) | 20.00 | (C-3) | 0.20 | — | — | — |

| | Solvent | | | | | | |
|---|---|---|---|---|---|---|---|
| | | Content | | Content | | Content | Concentration |
| | | ratio of | | ratio of | | ratio of | of solid |
| Resist | | solvent 1 | | solvent 2 | | solvent 3 | contents |
| composition | Solvent 1 | (% by mass) | Solvent 2 | (% by mass) | Solvent 3 | (% by mass) | (% by mass) |
| R-1 | S-1 | 70 | S-2 | 30 | — | — | 2.5 |
| R-2 | S-1 | 80 | S-2 | 10 | S-3 | 10 | 3.0 |
| R-3 | S-1 | 70 | S-2 | 20 | S-3 | 10 | 3.0 |
| R-4 | S-1 | 60 | S-2 | 20 | S-3 | 20 | 2.5 |
| R-5 | S-1 | 80 | S-2 | 10 | S-3 | 10 | 3.0 |
| R-6 | S-1 | 50 | S-2 | 20 | S-4 | 30 | 3.0 |
| R-7 | S-1 | 60 | S-4 | 20 | S-5 | 20 | 3.0 |
| R-8 | S-1 | 70 | S-2 | 20 | S-4 | 10 | 2.5 |
| R-9 | S-1 | 60 | S-4 | 20 | S-5 | 20 | 3.0 |
| R-10 | S-1 | 70 | S-2 | 30 | — | — | 3.0 |
| R-11 | S-1 | 60 | S-4 | 20 | S-5 | 20 | 3.0 |
| R-12 | S-1 | 60 | S-2 | 20 | S-3 | 20 | 2.5 |
| R-13 | S-1 | 70 | S-2 | 30 | — | — | 3.0 |
| R-14 | S-1 | 60 | S-4 | 20 | S-5 | 20 | 3.0 |
| R-15 | S-1 | 60 | S-2 | 20 | S-3 | 20 | 2.5 |
| R-16 | S-1 | 70 | S-2 | 30 | — | — | 3.0 |
| R-17 | S-1 | 60 | S-2 | 20 | S-3 | 20 | 2.5 |
| R-18 | S-1 | 60 | S-2 | 20 | S-3 | 20 | 2.5 |
| R-19 | S-1 | 70 | S-2 | 30 | — | — | 3.0 |
| R-20 | S-1 | 60 | S-2 | 20 | S-3 | 20 | 2.5 |

TABLE 3

| | | | Photoacid | | Acid diffusion control agent | | | | Surfactant |
|---|---|---|---|---|---|---|---|---|---|
| | Resin (A) | | generator (B) | | | Content of | | Content of | Type |
| Resist | | Content | | Content | | type 1 | | type 2 | (0.01% |
| composition | Type | (% by mass) | Type | (% by mass) | Type 1 | (% by mass) | Type 2 | (% by mass) | by mass) |
| R-21 | (A-21) | 84.80 | (B-8) | 15.00 | (C-4) | 0.20 | — | — | — |
| R-22 | (A-22) | 79.90 | (B-9) | 20.00 | (C-5) | 0.10 | — | — | — |
| R-23 | (A-23) | 89.89 | (B-10) | 10.00 | (C-6) | 0.10 | — | — | W-3 |
| R-24 | (A-24) | 74.80 | (B-11) | 15.00 | (C-7) | 0.20 | (C-18) | 10.00 | — |
| R-25 | (A-25) | 89.89 | (B-12) | 10.00 | (C-8) | 0.10 | — | — | W-1 |
| R-26 | (A-26) | 89.70 | (B-13) | 10.00 | (C-9) | 0.30 | — | — | — |
| R-27 | (A-27) | 89.80 | (B-1) | 10.00 | (C-10) | 0.20 | — | — | — |
| R-28 | (A-28) | 79.69 | (B-2) | 20.00 | (C-11) | 0.30 | — | — | W-1 |
| R-29 | (A-29) | 89.79 | (B-3) | 10.00 | (C-12) | 0.20 | — | — | W-1 |
| R-30 | (A-30) | 79.70 | (B-4) | 20.00 | (C-13) | 0.30 | — | — | — |
| R-31 | (A-31) | 89.90 | (B-5) | 10.00 | (C-14) | 0.10 | — | — | — |
| R-32 | (A-32) | 79.90 | (B-6) | 20.00 | (C-15) | 0.10 | — | — | — |
| R-33 | (A-33) | 79.89 | (B-7) | 20.00 | (C-16) | 0.10 | — | — | W-1 |
| R-34 | (A-34) | 89.90 | (B-8) | 10.00 | (C-17) | 0.10 | — | — | — |
| R-X1 | (RA-1) | 89.80 | (B-1) | 10.00 | (C-1) | 0.20 | — | — | — |
| R-X2 | (RA-2) | 89.80 | (B-1) | 10.00 | (C-1) | 0.20 | — | — | — |
| R-X3 | (RA-3) | 89.80 | (B-1) | 10.00 | (C-1) | 0.20 | — | — | — |
| R-X4 | (RA-4) | 89.80 | (B-1) | 10.00 | (C-1) | 0.20 | — | — | — |
| R-X5 | (RA-5) | 89.80 | (B-1) | 10.00 | (C-1) | 0.20 | — | — | — |

| | Solvent | | | | | | |
|---|---|---|---|---|---|---|---|
| | | Content | | Content | | Content | Concentration |
| | | ratio of | | ratio of | | ratio of | of solid |
| Resist | | solvent 1 | | solvent 2 | | solvent 3 | contents |
| composition | Solvent 1 | (% by mass) | Solvent 2 | (% by mass) | Solvent 3 | (% by mass) | (% by mass) |
| R-21 | S-1 | 70 | S-2 | 30 | — | — | 3.0 |
| R-22 | S-1 | 60 | S-2 | 20 | S-3 | 20 | 2.5 |
| R-23 | S-1 | 70 | S-2 | 30 | — | — | 3.0 |
| R-24 | S-1 | 70 | S-2 | 30 | — | — | 3.0 |
| R-25 | S-1 | 60 | S-2 | 20 | S-6 | 20 | 2.5 |
| R-26 | S-1 | 70 | S-2 | 30 | — | — | 3.0 |
| R-27 | S-1 | 70 | S-2 | 30 | — | — | 3.0 |
| R-28 | S-1 | 60 | S-2 | 20 | S-3 | 20 | 2.5 |
| R-29 | S-1 | 70 | S-2 | 30 | — | — | 3.0 |
| R-30 | S-1 | 60 | S-2 | 20 | S-3 | 20 | 2.5 |
| R-31 | S-1 | 60 | S-2 | 20 | S-3 | 20 | 2.5 |
| R-32 | S-1 | 60 | S-2 | 20 | S-3 | 20 | 2.5 |
| R-33 | S-1 | 70 | S-7 | 30 | — | — | 3.0 |
| R-34 | S-1 | 70 | S-2 | 30 | — | — | 3.0 |
| R-X1 | S-1 | 60 | S-2 | 20 | S-3 | 20 | 2.5 |
| R-X2 | S-1 | 60 | S-2 | 20 | S-3 | 20 | 2.5 |
| R-X3 | S-1 | 60 | S-2 | 20 | S-3 | 20 | 2.5 |
| R-X4 | S-1 | 60 | S-2 | 20 | S-3 | 20 | 2.5 |
| R-X5 | S-1 | 60 | S-2 | 20 | S-3 | 20 | 2.5 |

[Electron Beams (EB) Exposure and Development]

(4) Manufacture of Resist Pattern (Examples 1a to 34a and Comparative Examples 1a to 5a)

The resist film obtained in (3) above was subjected to patternwise irradiation using an electron beam drawing apparatus (manufactured by Advantest Corporation; F7000S, accelerating voltage: 50 keV). After the irradiation, the film was heated on a hot plate at 100° C. for 600 seconds, dipped using a 2.38%-by-mass aqueous tetramethylammonium hydroxide (TMAH) solution for 60 seconds, then rinsed with water for 30 seconds, and dried.

[Evaluation]

(5) Evaluation of Resist Pattern

The obtained pattern was evaluated on a resolution, development defects, and a pattern film thickness by the following methods. The results are shown in Table 4 later.

The irradiation energy upon resolution of a 1:1 line-and-space pattern with a line width of 50 nm was defined as a sensitivity (Eop).

<L/S Resolution>

A marginal resolving power (a minimum line width at which lines and spaces (line:space=1:1) are separated and resolved) at an exposure amount showing the sensitivity (Eop) was taken as a resolving power (nm). A smaller value thereof indicates better performance.

<Development Defects>

Using a defect inspection apparatus, KLA 2360 (trade name), manufactured by KLA Tencor Ltd., a 1:1 line-and-space pattern with a line width of 50 nm formed at an exposure amount exhibiting the sensitivity (Eop) was measured by setting a pixel size of the defect inspection apparatus to 0.16 μm and a threshold value to 20 to detect defects (defects/cm²) extracted from a difference produced at the time of superposing pixel units on a reference image, and the number of the defects per unit area (defects/cm²) was calculated. Then, by performing a defect review, the development defects were classified and extracted from all the defects, and the number of development defects per unit area (defects/cm²) was computed. The value of less than 0.5 was designated as A, the value of 0.5 or more and less than 1.0 was designated as B, the value of 1.0 or more and less than 5.0 was designated as C, and a value of 5.0 or more was designated as D. A smaller value thereof indicates better performance.

<Pattern Film Thickness>

The cross-sectional shape of a 1:1 line-and-space pattern formed at an exposure amount exhibiting the sensitivity (Eop) was observed using a scanning electron microscope (S-4800 manufactured by Hitachi, Ltd.). For the remaining part of the resist film in the line-and-space pattern, the film thickness of the pattern (the height of the pattern) was measured. The larger the value, the less the film loss and the better.

TABLE 4

| | Resist | L/S | | Film |
|---|---|---|---|---|
| | com- | resolution | Development | thickness of |
| | position | [nm] | defects | pattern [nm] |
| Example 1a | R-1 | 25 | A | 88 |
| Example 2a | R-2 | 24 | A | 89 |
| Example 3a | R-3 | 24 | A | 88 |
| Example 4a | R-4 | 25 | A | 89 |
| Example 5a | R-5 | 26 | A | 88 |
| Example 6a | R-6 | 21 | A | 89 |
| Example 7a | R-7 | 27 | B | 90 |
| Example 8a | R-8 | 22 | B | 90 |
| Example 9a | R-9 | 29 | A | 88 |
| Example 10a | R-10 | 30 | A | 87 |
| Example 11a | R-11 | 24 | B | 90 |
| Example 12a | R-12 | 26 | B | 90 |
| Example 13a | R-13 | 25 | B | 90 |
| Example 14a | R-14 | 22 | A | 87 |
| Example 15a | R-15 | 23 | A | 89 |
| Example 16a | R-16 | 26 | B | 90 |
| Example 17a | R-17 | 27 | B | 90 |
| Example 18a | R-18 | 29 | A | 88 |
| Example 19a | R-19 | 25 | A | 89 |
| Example 20a | R-20 | 28 | A | 88 |
| Example 21a | R-21 | 21 | A | 88 |
| Example 22a | R-22 | 23 | A | 88 |
| Example 23a | R-23 | 29 | A | 88 |
| Example 24a | R-24 | 28 | A | 89 |
| Example 25a | R-25 | 28 | A | 86 |
| Example 26a | R-26 | 24 | A | 87 |
| Example 27a | R-27 | 26 | A | 87 |
| Example 28a | R-28 | 27 | A | 88 |
| Example 29a | R-29 | 26 | A | 87 |
| Example 30a | R-30 | 26 | A | 89 |
| Example 31a | R-31 | 27 | A | 88 |
| Example 32a | R-32 | 23 | A | 87 |
| Example 33a | R-33 | 28 | A | 85 |
| Example 34a | R-34 | 22 | A | 87 |
| Comparative | R-X1 | 40 | A | 80 |
| Example 1a | | | | |
| Comparative | R-X2 | 45 | A | 80 |
| Example 2a | | | | |
| Comparative | R-X3 | 40 | C | 90 |
| Example 3a | | | | |
| Comparative | R-X4 | 50 | A | 60 |
| Example 4a | | | | |
| Comparative | R-X5 | 40 | B | 80 |
| Example 5a | | | | |

[Extreme Ultraviolet Ray (EUV) Exposure and Development]

(4) Manufacture of Resist Pattern (Examples 1b to 34b and Comparative Examples 1b to 5b)

A wafer on which the resist obtained in (3) above had been applied was subjected to pattern exposure through an exposure mask (line/space=1/1) using an EUV exposure device (Micro Exposure Tool, manufactured by Exitech Ltd., numerical aperture (NA): 0.3, Quadrupole, outer sigma: 0.68, inner sigma: 0.36).

After the exposure, the film was heated on a hot plate at 100° C. for 90 seconds, dipped using a 2.38%-by-mass aqueous tetramethylammonium hydroxide (TMAH) solution for 60 seconds, and then rinsed with water for 30 seconds. Then, the wafer was rotated at a rotation speed of 4,000 rpm for 30 seconds, baked at 95° C. for 60 seconds, and dried.

[Evaluation]

(5) Evaluation of Resist Pattern

The obtained pattern was evaluated on a resolution, development defects, and a pattern film thickness by the same method as the method described earlier. The results are shown in Table 5 below.

TABLE 5

| | Resist | L/S | | Film |
|---|---|---|---|---|
| | com- | resolution | Development | thickness of |
| | position | [nm] | defects | pattern [nm] |
| Example 1b | R-1 | 24 | A | 88 |
| Example 2b | R-2 | 24 | A | 88 |
| Example 3b | R-3 | 24 | A | 87 |
| Example 4b | R-4 | 25 | A | 88 |
| Example 5b | R-5 | 27 | A | 88 |
| Example 6b | R-6 | 20 | A | 89 |
| Example 7b | R-7 | 26 | B | 90 |
| Example 8b | R-8 | 23 | B | 90 |
| Example 9b | R-9 | 28 | A | 86 |
| Example 10b | R-10 | 30 | A | 89 |
| Example 11b | R-11 | 24 | B | 90 |
| Example 12b | R-12 | 27 | B | 90 |
| Example 13b | R-13 | 24 | B | 88 |
| Example 14b | R-14 | 22 | A | 88 |
| Example 15b | R-15 | 23 | A | 89 |
| Example 16b | R-16 | 27 | A | 90 |
| Example 17b | R-17 | 26 | B | 90 |
| Example 18b | R-18 | 29 | A | 88 |
| Example 19b | R-19 | 24 | A | 88 |
| Example 20b | R-20 | 28 | A | 89 |
| Example 21b | R-21 | 20 | A | 88 |
| Example 22b | R-22 | 22 | A | 88 |
| Example 23b | R-23 | 28 | A | 89 |
| Example 24b | R-24 | 29 | A | 87 |
| Example 25b | R-25 | 29 | A | 88 |
| Example 26b | R-26 | 25 | A | 88 |
| Example 27b | R-27 | 27 | A | 89 |
| Example 28b | R-28 | 26 | A | 87 |
| Example 29b | R-29 | 27 | A | 89 |
| Example 30b | R-30 | 27 | A | 88 |
| Example 31b | R-31 | 26 | A | 89 |
| Example 32b | R-32 | 23 | A | 87 |
| Example 33b | R-33 | 29 | A | 85 |
| Example 34b | R-34 | 22 | A | 87 |
| Comparative | R-X1 | 40 | A | 80 |
| Example 1b | | | | |
| Comparative | R-X2 | 50 | A | 80 |
| Example 2b | | | | |
| Comparative | R-X3 | 45 | D | 90 |
| Example 3b | | | | |
| Comparative | R-X4 | 45 | A | 65 |
| Example 4b | | | | |
| Comparative | R-X5 | 45 | B | 80 |
| Example 5b | | | | |

From the results shown in Tables 4 and 5, it can be seen that the resist compositions of Examples can reduce the development residue defects while suppressing the film thickness reduction of the pattern, and further provide a high resolution.

According to the present invention, it is possible to provide an actinic ray-sensitive or radiation-sensitive resin composition which can reduce development residue defects while suppressing film thickness reduction of a pattern, and has a high resolution; and an actinic ray-sensitive or radiation-sensitive film, a pattern forming method, and a method for manufacturing an electronic device, each using the actinic ray-sensitive or radiation-sensitive resin composition.

Although the present invention has been described in detail with reference to specific embodiments, it will be apparent to those skilled in the art that various changes and modifications can be made without departing from the spirit and the scope of the present invention.

What is claimed is:

1. An actinic ray-sensitive or radiation-sensitive resin composition comprising:
a resin (A) of which polarity increases by an action of an acid, the resin (A) having a repeating unit represented by General Formula (A1); and
a compound (B) that generates an acid upon irradiation with actinic rays or radiation, 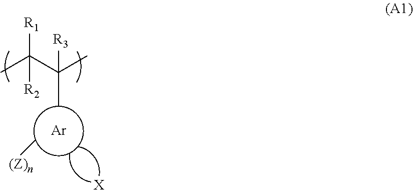
in General Formula (A1),
Ar represents an aromatic hydrocarbon group,
Z represents a substituent,
n represents an integer of 0 or more,
in a case where n represents an integer of 2 or more, a plurality of Z's may be the same as or different from each other,
R₁, R₂, and R₃ each independently represent a hydrogen atom, an alkyl group, a hydroxyl group, an alkoxy group, a halogen atom, a cyano group, a nitro group, an acyl group, an acyloxy group, a cycloalkyl group, an aryl group, a carboxy group, an alkyloxycarbonyl group, an alkylcarbonyloxy group, or an aralkyl group, and
X represents an atomic group that forms an alkali-decomposable cyclic structure together with a carbon atom in Ar, provided that the alkali-decomposable cyclic structure generates an acid group having a pKa of 6 to 12 by hydrolysis.

2. An actinic ray-sensitive or radiation-sensitive resin composition comprising:
a resin (A) of which polarity increases by an action of an acid, the resin (A) having a repeating unit represented by General Formula (A1); and
a compound (B) that generates an acid upon irradiation with actinic rays or radiation, 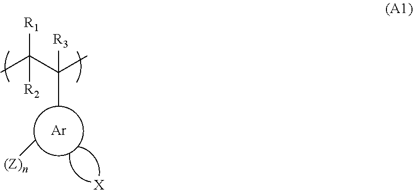
in General Formula (A1),
Ar represents an aromatic hydrocarbon group,
Z represents a substituent,
n represents an integer of 0 or more,
in a case where n represents an integer of 2 or more, a plurality of Z's may be the same as or different from each other,
R₁, R₂, and R₃ each independently represent a hydrogen atom, an alkyl group, a hydroxyl group, an alkoxy group, a halogen atom, a cyano group, a nitro group, an acyl group, an acyloxy group, a cycloalkyl group, an aryl group, a carboxy group, an alkyloxycarbonyl group, an alkylcarbonyloxy group, or an aralkyl group.
X represents an atomic group that forms an alkali-decomposable cyclic structure together with two carbon atoms in Ar, provided that the alkali-decomposable cyclic structure generates an acid group having a pKa of 6 to 12 by hydrolysis.

3. The actinic ray-sensitive or radiation-sensitive resin composition according to claim 1,
wherein the repeating unit represented by General Formula (A1) is a repeating unit represented by General Formula (A1-2), 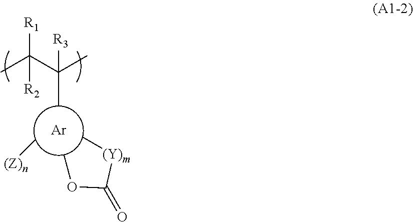
in General Formula (A1-2), Ar, Z, n, R₁, R₂, and R₃ each have the same definitions as those in General Formula (A1),
Y represents a methanediyl group, an oxygen atom, or a sulfur atom,
m represents an integer of 0 to 10, and
in a case where m represents an integer of 2 or more, a plurality of Y's may be the same as or different from each other.

4. The actinic ray-sensitive or radiation-sensitive resin composition according to claim 3,
wherein all of m pieces of Y's represent a methanediyl group or an oxygen atom.

5. The actinic ray-sensitive or radiation-sensitive resin composition according to claim 3,
wherein all of m pieces of Y's represent a methanediyl group.

6. The actinic ray-sensitive or radiation-sensitive resin composition according to claim 3,
wherein m represents an integer of 1 to 3.

7. The actinic ray-sensitive or radiation-sensitive resin composition according to claim 1,
wherein Ar represents an aromatic hydrocarbon group having 6 to 12 carbon atoms.

8. The actinic ray-sensitive or radiation-sensitive resin composition according to claim 1,
wherein Ar represents an aromatic hydrocarbon group having 6 carbon atoms.

9. The actinic ray-sensitive or radiation-sensitive resin composition according to claim 3,
wherein the repeating unit represented by General Formula (A1-2) is a repeating unit represented by any one of General Formula (A1-3), (A1-4), or (A1-5), 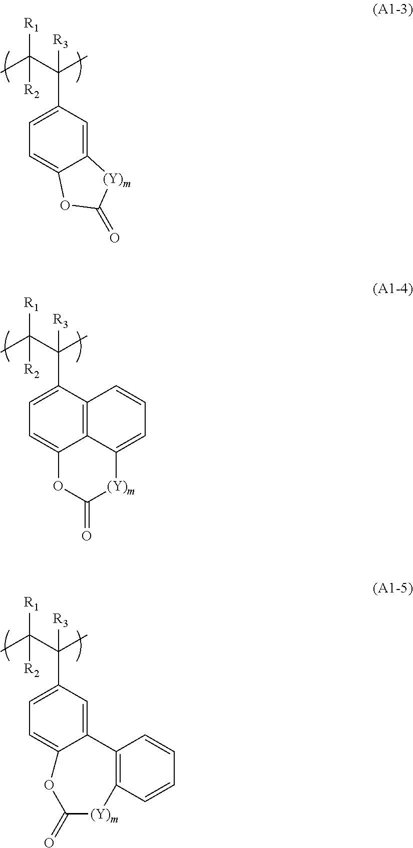
in General Formulae (A1-3) to (A1-5), R₁, R₂, R₃, Y, and m each have the same definitions as those in General Formula (A1-2).

10. The actinic ray-sensitive or radiation-sensitive resin composition according to claim 1,
wherein the compound (B) is a compound having an acid-decomposable group.

11. The actinic ray-sensitive or radiation-sensitive resin composition according to claim 1,
wherein the compound (B) is an ionic compound including an anion and a cation, and is a compound having an acid-decomposable group in the anion.

12. The actinic ray-sensitive or radiation-sensitive resin composition according to claim 1,
wherein the resin (A) has a repeating unit represented by General Formula (A2), 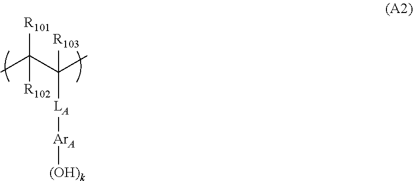
in General Formula (A2),
R₁₀₁, R₁₀₂, and R₁₀₃ each independently represent a hydrogen atom, an alkyl group, a cycloalkyl group, a halogen atom, a cyano group, or an alkyloxycarbonyl group, provided that R₁₀₂ may be bonded to Ar_{A} to form a ring, in which case R₁₀₂ represents a single bond or an alkylene group,
L_{A} represents a single bond or a divalent linking group,
Ar_{A} represents an aromatic ring group, and
k represents an integer of 1 to 5.

13. The actinic ray-sensitive or radiation-sensitive resin composition according to claim 1,
wherein the resin (A) has a repeating unit having at least one acid-decomposable group selected from the group consisting of a group that decomposes by an action of an acid to generate a carboxy group and a group that decomposes by an action of an acid to generate a phenolic hydroxyl group.

14. The actinic ray-sensitive or radiation-sensitive resin composition according to claim 13,
wherein the repeating unit having an acid-decomposable group is a repeating unit represented by any one of General Formula (3), (4), (5), (6), or (7), 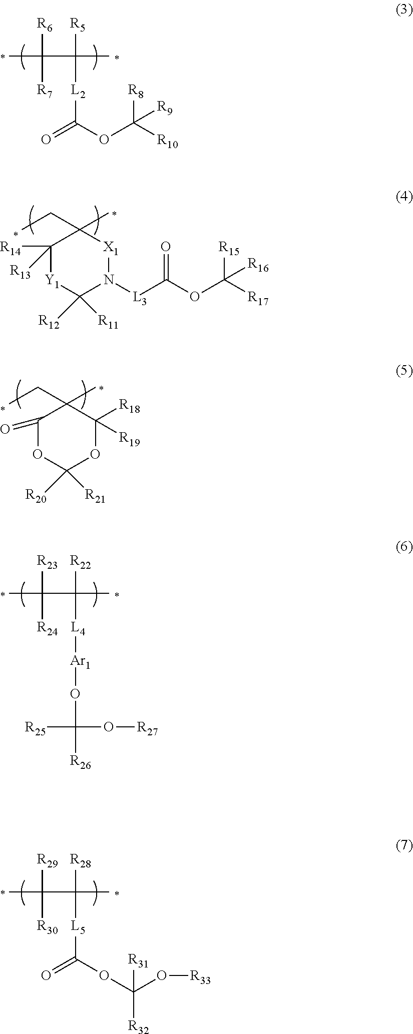
in General Formula (3), R₅, R₆, and R₇ each independently represent a hydrogen atom, an alkyl group, a cycloalkyl group, a halogen atom, a cyano group, or an alkoxycarbonyl group, L₂ represents a single bond or a divalent linking group, R₈ to R₁₀ each independently represent an alkyl group, a cycloalkyl group, an aryl group, an aralkyl group, or an alkenyl group, and two of R₈ to R₁₀ may be bonded to each other to form a ring,
in General Formula (4), R₁₁ to R₁₄ each independently represent a hydrogen atom or an organic group, provided that at least one of R₁₁ or R₁₂ represents an organic group, X₁ represents —CO—, —SO—, or —SO₂—, Y₁ represents —O—, —S—, —SO—, —SO₂—, or —NR₄—, R₃₄ represents a hydrogen atom or an organic group, L₃ represents a single bond or a divalent linking group, R₁₅ to R₁₇ each independently represent an alkyl group, a cycloalkyl group, an aryl group, an aralkyl group, or an alkenyl group, and two of R₁₅ to R₁₇ may be bonded to each other to form a ring,
in General Formula (5), R₁₈ and R₁₉ each independently represent a hydrogen atom or an organic group, R₂₀ and R₂₁ each independently represent a hydrogen atom, an alkyl group, a cycloalkyl group, an aryl group, an aralkyl group, or an alkenyl group, and R₂₀ and R₂₁ may be bonded to each other to form a ring,
in General Formula (6), R₂₂, R₂₃, and R₂₄ each independently represent a hydrogen atom, an alkyl group, a cycloalkyl group, a halogen atom, a cyano group, or an alkoxycarbonyl group, L₄ represents a single bond or a divalent linking group, Ar₁ represents an aromatic ring group, R₂₅ to R₂₇ each independently represent a hydrogen atom, an alkyl group, a cycloalkyl group, an aryl group, an aralkyl group, or an alkenyl group, R₂₆ and R₂₇ may be bonded to each other to form a ring, and Ar₁ may be bonded to R₂₄ or R₂₅ to form a ring, and
in General Formula (7), R₂₈, R₂₉, and R₃₀ each independently represent a hydrogen atom, an alkyl group, a cycloalkyl group, a halogen atom, a cyano group, or an alkoxycarbonyl group, L₅ represents a single bond or a divalent linking group, R₃₁ and R₃₂ each independently represent a hydrogen atom, an alkyl group, a cycloalkyl group, an aryl group, an aralkyl group, or an alkenyl group, R₃₃ represents an alkyl group, a cycloalkyl group, an aryl group, an aralkyl group, or an alkenyl group, and R₃₂ and R₃₃ may be bonded to each other to form a ring.

15. The actinic ray-sensitive or radiation-sensitive resin composition according to claim 14,
wherein the repeating unit having an acid-decomposable group is the repeating unit represented by General Formula (6) or the repeating unit represented by General Formula (7).

16. An actinic ray-sensitive or radiation-sensitive film formed of the actinic ray-sensitive or radiation-sensitive resin composition according to claim 1.

17. A pattern forming method comprising:
forming a resist film using the actinic ray-sensitive or radiation-sensitive resin composition according to claim 1;
exposing the resist film; and
developing the exposed resist film, using a developer.

18. A method for manufacturing an electronic device, comprising the pattern forming method according to claim 17.
